(19) United States
(12) Patent Application Publication
(10) Pub. No.: US 2012/0240975 A1
(43) Pub. Date: Sep. 27, 2012

(54) PHOTOELECTRIC CONVERSION DEVICE, PHOTOELECTRIC CONVERSION DEVICE ARRAY, FABRICATION METHOD FOR PHOTOELECTRIC CONVERSION DEVICE AND ELECTRONIC APPARATUS

(75) Inventor: Akira Ono, Kanagawa (JP)

(73) Assignee: Sony Corporation, Tokyo (JP)

(21) Appl. No.: 13/417,460

(22) Filed: Mar. 12, 2012

(30) Foreign Application Priority Data
Mar. 25, 2011 (JP) 2011-068511

(51) Int. Cl. H01L 31/0232; H01L 27/142; H01L 31/18; H01L 31/04

(52) U.S. Cl. 136/246; 257/432; 136/256; 438/69; 257/E31.127; 257/E27.124

(57) ABSTRACT

A photoelectric conversion device includes: a porous electrode and a counter electrode provided on a substrate; an electrolyte layer provided between the porous electrode and the counter electrode; a collecting wiring line provided on a face of the substrate on which the porous electrode is provided; and a light guiding structure provided on the light incidence side of the substrate.

### BACKGROUND

The present technology relates to a photoelectric conversion device, a fabrication method for a photoelectric conversion device and an electronic apparatus, and particularly to a photoelectric conversion device suitable for use, for example, with a dye-sensitized solar cell, a fabrication method for the photoelectric conversion device and an electronic apparatus for which the photoelectric conversion device is used.

Since a solar cell which is a photoelectric conversion device for converting sunlight into electric energy operates using sunlight as its energy source, the influence of the same on the terrestrial environment is very slight. Therefore, further propagation of the solar cell is anticipated.

As a related-art solar cell, a crystal silicon based solar cell and an amorphous silicon based solar cell for which single crystalline or polycrystalline silicon is used are mainly used.

On the other hand, a dye-sensitized solar cell proposed by Grätzel in 1991 can achieve a high photoelectric conversion efficiency, and, different from a silicon based solar cell in the past, a large-scale apparatus is not required for fabrication of the dye-sensitized solar cell and the dye-sensitized solar cell can be fabricated at a low cost. From the reason just described, attention is paid to the dye-sensitized solar cell.

Generally, the dye-sensitized solar cell has a structure wherein a porous electrode formed from titanium oxide (TiO₂) to which a photosensitizing dye is coupled and a counter electrode formed from platinum (Pt) or the like are opposed to each other and an electrolyte layer formed from electrolytic solution or the like is filled between the electrodes. As the electrolytic solution, liquid solution in which electrolyte containing oxidation and reduction species such as iodine (I), iodide ion (I⁺) or the like is dissolved in a solvent is widely used.

In the past, the porous electrode of the dye-sensitized solar cell was formed by laminating semiconductor fine particles on a transparent electrode of an indium-tin composite oxide (ITO), tin oxide (IV) SnO₂ (FTO) doped with fluorine or the like provided in lamination on a transparent substrate of glass or the like.

However, in the dye-sensitized solar cell, it is necessary to form the transparent electrode in a very thin layer having high optical transparency from a point of view of a light capture efficiency, and this increases the sheet resistance of the transparent electrode. This gives rise to a problem of increase of the resistance loss when power generated by light irradiation is extracted to the outside.

In order to solve the problem described above, in recent years, a structure wherein wires made of a metal are laid like a grid on the surface of the transparent electrode and another structure wherein a collecting wiring line is disposed on the transparent electrode to decrease the resistance loss have been proposed (refer to, for example, Japanese Patent Laid-Open Nos. 2006-286434 and 2005-11609 (Patent Documents 1 and 2)). As a result, the problem of the resistance loss of the transparent electrode in the dye-sensitized solar cell is being solved.

### SUMMARY

However, since the dye-sensitized solar cells proposed in Patent Documents 1 and 2 are configured by disposing collecting wiring lines made of a metal such as silver (Ag) or aluminum (Al) on the porous electrode, the collecting wiring lines block incidence light to the porous electrode. As a result, the numerical aperture of the light incidence face of the porous electrode decreases and the incidence light to the porous electrode cannot be utilized effectively. This actually decreases the photoelectric conversion efficiency of the dye-sensitized solar cell.

Therefore, it is desirable to provide a photoelectric conversion device such as a dye-sensitized solar cell in which the resistance loss when power generated by light irradiation is extracted to the outside is low and the numerical aperture of the light incidence face is high so that incidence light can be utilized effectively and besides an excellent photoelectric conversion characteristic can be achieved, and a fabrication method for the photoelectric conversion device.

Also it is desirable to provide a high-performance electronic apparatus for which such an excellent photoelectric conversion device as described above is used.

According to an embodiment of the technology disclosed herein, there is provided a photoelectric conversion device including a porous electrode and a counter electrode provided on a substrate, an electrolyte layer provided between the porous electrode and the counter electrode, a collecting wiring line provided on a face of the substrate on which the porous electrode is provided, and a light guiding structure provided on the light incidence side of the substrate.

According to another embodiment of the disclosed technology, there is provided a photoelectric conversion device array including a plurality of photoelectric conversion devices connected at collecting wiring lines thereof to each other by a tiling wiring line so as to be integrated, at least one of the photoelectric conversion devices including a porous electrode and a counter electrode provided on a substrate and an electrolyte layer provided between the porous electrode and the counter electrode, a collecting wiring line provided on a face of the substrate on which the porous electrode is provided, a light guiding structure provided on the light incidence side of the substrate, and a light guiding structure provided on the light incidence side of the tiling wiring line.

According to a further embodiment of the disclosed technology, there is provided a fabrication method for a photoelectric conversion device including providing a light guiding structure on a face of a substrate on the light incidence side, forming a collecting wiring line on a face opposite to the light incidence side face of the substrate and further forming a porous electrode in lamination on the collecting wiring line, and forming a structure in which an electrolyte layer is filled between the porous electrode and a counter electrode.

According to a still further embodiment of the disclosed technology, there is provided an electronic apparatus including at least one photoelectric conversion device including a porous electrode and a counter electrode provided on a substrate and an electrolyte layer provided between the porous electrode and the counter electrode, a collecting wiring line provided on a face of the substrate on which the porous electrode is provided, and a light guiding structure provided on the light incidence side of the substrate.

In the disclosed technology, the “substrate” may basically be any substrate only if a part can be disposed thereon and at least part of the substrate can transmit light therethrough. The substrate typically is a transparent substrate and is configured from a transparent material particularly of a planar shape so that it can easily transmit light therethrough. Preferably, the substrate is shaped such that it can guide light into the porous electrode. However, the material and the shape of the substrate are not limited to those described above. In other words, the substrate may be configured from a translucent material, an opaque material or a combined material of a translucent material or an opaque material and a transparent material or otherwise may be configured in a shape having a curved face or a combined shape of a planar face and a curved face.

In the disclosed technology, the “light guiding structure” may be a light guiding structure which is a light path changing element configured at least at part thereof from a transparent material and provided on a face of a substrate of a photoelectric conversion device on the light incidence side or above the light incidence side of the substrate. The light guiding structure may further be a light path changing element wherein the substrate itself is worked so that the transparent substrate itself configures a light guiding structure. Preferably, the light guiding structure is particularly configured such that it is formed from a transparent material so that it can easily transmit light therethrough and refracts or reflects light incident to the photoelectric conversion device thereby to eliminate blocking of the light guide path by the collecting wiring line to guide the light into the porous electrode. However, the light guiding structure is not limited to them but may be formed from a translucent material.

As regards the material of the light guiding structure, basically any material may be used only if it can transmit light therethrough. However, the light guiding structure is configured from a material which can easily transmit light therethrough. Meanwhile, as regards the shape of the light guiding structure, the light guiding structure is shaped such that it refracts or reflects light incident to the photoelectric conversion device so that it comes to the porous electrode while preventing blocking of the light guide path by the collecting wiring line thereby to guide the light into the porous electrode. Preferably, the light guiding structure is shaped and made of a material such that the transmission factor is high particularly in a visible ray range and blocking of the light guide path by the collecting wiring line is prevented thereby to allow the light to be introduced into the porous electrode. Typically, a prism, a lens or the like is available for the light guiding structure. However, the light guiding structure is not limited to them. Further, the light guiding structure may be formed using a solid body or using liquid. Particularly in the case where the light guiding structure is formed using liquid, also it is possible to use a liquid lens which is an optical device which utilizes an electrowetting or electrocapillarity effect.

As a particular shape of the light guiding structure, it has a convex shape, a concave shape or a three-dimensional shape of a combination of such convex and concave shapes. Particularly, a post-like shape, a conical shape, a twin conical shape, a frustum shape, a polyhedral shape, a spherical shape and a partial spherical shape are applicable. Particularly, if the light guiding structure has a post-like shape, then it preferably has a convex face post-like shape having a convex bottom face or a concave face post-like shape having a concave bottom face. As the shape of the bottom face, one or a combination of two or more of a polygon, a circle, an ellipsis, a partial circle or partially missing circle, a partial ellipsis and so forth is selected. However, the shape of the light guiding structure is not limited to them.

As a particular material for the light guiding structure, basically any material may be used only if it transmits light therethrough, and especially, a material which is transparent and therefore transmits light well therethrough and has a refractive index is used preferably. In particular, transparent inorganic materials, transparent plastics and like materials are applicable. As the transparent inorganic materials, for example, quartz glass, borosilicate glass, phosphate glass and soda glass are applicable, and as the transparent plastics, for example, polyethylene terephthalate (PET), polyethylene naphthalate (PEN), polybutylene terephthalate (PBT), acetyl cellulose (AC), tetraacetyl cellulose (TAC), polyphenylene sulfide (PPS), polycarbonate (PC), polyethylene, polypropylene, polyvinylidene fluoride, brominated phenoxy, aramids, polyimides, polystylenes, polyallylates, polysulfones and polyolefins are available. However, the material for the light guiding structure is not limited to the substances specified above.

Also it is possible to form part of the light guiding structures as a mirror face or a half mirror face. Further, also it is possible to form a multilayer film or a nanosized structure on the surface of the light guiding structure 11 so as to serve as an anti-reflection layer. The size of the light guiding structures is not limited particularly but can be designed and selected suitably taking the transmission factor of light, the size of the collecting wiring lines and so forth into consideration.

The light guiding structure is provided in a corresponding relationship to the installation form of the collecting wiring line in the photoelectric conversion device, typically along the collecting wiring line provided on the opposite side with respect to the substrate in order that the light guide path of incidence light may not be blocked by the collecting wiring line. However, also in a photoelectric conversion device array configured by aggregating photoelectric conversion devices by tiling or the like, it is possible to install the light guiding structure in a corresponding relationship to the installation form similarly with regard to a light guide path which is blocked by an aggregation wiring line which connects a plurality of collecting wiring lines to each other. However, the installation of the light guiding structure is not limited to them.

The photoelectric conversion device is configured most typically as a solar cell. However, the photoelectric conversion device may be some other element from a solar cell and may be, for example, an optical sensor.

The electronic apparatus may basically be any electronic apparatus and may be formed as an electronic apparatus of the portable type or of the stand alone type. In particular, the electronic apparatus may be a portable telephone set, a mobile apparatus, a robot, a personal computer, a vehicle-carried apparatus, an electric appliance for home use or the like. In this instance, the photoelectric conversion device is, for example, a solar cell which is used as the power supply for the electronic apparatus.

In the disclosed technology configured in such a manner as described above, the light guiding structure is further provided on the light incidence side of the substrate in the photoelectric conversion device in which the collecting wiring line is provided on the face of the substrate on which the porous electrode is provided. Therefore, the resistance loss when electrons generated in the collecting wiring line by light radiation are to be extracted to the outside can be suppressed. Further, since the optical conversion device refracts or reflects the incidence light, it is possible to prevent blocking of the light guide path by the collecting wiring line thereby to allow the light to be introduced into the porous electrode.

In summary, with the photoelectric conversion device of the disclosed technique, since light can be introduced efficiently to the porous electrode without being blocked by the collecting wiring line by the simple and easy configuration, the resistance loss when power generated by light radiation is to be taken out to the outside is low. Further, the numerical aperture of the light incidence face is high and the incidence light can be utilized effectively. Besides, a superior photoelectric conversion characteristic can be achieved. Further, by utilizing this superior photoelectric conversion device, an electronic apparatus having high performances can be implemented.

The above and other features and advantages of the disclosed technology will become apparent from the following description and the appended claims, taken in conjunction with the accompanying drawings in which like parts or elements denoted by like reference symbols.

### BRIEF DESCRIPTION OF THE DRAWINGS

FIG. 1 is a sectional view showing a dye-sensitized photoelectric conversion device according to a first embodiment of the disclosed technology;

FIGS. 2 and 3 are sectional views showing an example of a design of a light guiding structure of the dye-sensitized photoelectric conversion device according to a working example 1-1 of the disclosed technology;

FIG. 4 is a sectional view showing an example of a design of a light guiding structure of the dye-sensitized photoelectric conversion device according to a working example 1-2 of the disclosed technology;

FIG. 5 is a sectional view showing an example of a design of a light guiding structure of the dye-sensitized photoelectric conversion device according to a working example 1-3 of the disclosed technology;

FIG. 6 is a sectional view showing an example of a design of a light guiding structure of the dye-sensitized photoelectric conversion device according to a working example 1-4 of the disclosed technology;

FIG. 7 is a sectional view showing an example of a design of a light guiding structure of the dye-sensitized photoelectric conversion device according to a working example 1-5 of the disclosed technology;

FIG. 8 is a diagrammatic view illustrating a current-voltage characteristic of the dye-sensitized photoelectric conversion device;

FIG. 9 is a sectional view showing a dye-sensitized photoelectric conversion device according to a modification to the first embodiment;

FIG. 10 is a sectional view showing an example of a design of a light guiding structure of the dye-sensitized photoelectric conversion device according to a working example 1-6 of the disclosed technology;

FIG. 11 is a sectional view showing an example of a design of a light guiding structure of the dye-sensitized photoelectric conversion device according to a working example 1-7 of the disclosed technology;

FIG. 12 is a sectional view showing a dye-sensitized photoelectric conversion device according to a second embodiment of the disclosed technology;

FIGS. 13 and 14 are sectional views showing an example of a design of a light guiding structure of the dye-sensitized photoelectric conversion device according to a working example 2-1 of the disclosed technology;

FIG. 15 is a sectional view showing a dye-sensitized photoelectric conversion device according to a modification to the second embodiment;

FIG. 16 is a sectional view showing an example of a design of a light guiding structure of the dye-sensitized photoelectric conversion device according to a working example 2-2 of the disclosed technology;

FIG. 17 is a sectional view showing an example of a design of a light guiding structure of the dye-sensitized photoelectric conversion device according to a working example 2-3 of the disclosed technology;

FIG. 18 is a sectional view showing a dye-sensitized photoelectric conversion device according to a third embodiment of the disclosed technology;

FIG. 19 is a sectional view showing an example of a design of a light guiding structure of the dye-sensitized photoelectric conversion device according to a working example 3-1 of the disclosed technology;

FIG. 20 is a sectional view showing a dye-sensitized photoelectric conversion device according to a fourth embodiment of the disclosed technology;

FIG. 21 is a sectional view showing a dye-sensitized photoelectric conversion device according to a fifth embodiment of the disclosed technology;

FIGS. 22A to 22C are sectional views showing an example of design of a light guiding structure of a dye-sensitized photoelectric conversion device according to a working example 6-1 of the disclosed technology;

FIGS. 23A to 23D are sectional views showing an example of design of a light guiding structure of a dye-sensitized photoelectric conversion device according to a working example 6-2 of the disclosed technology;

FIGS. 24A to 24C are sectional views showing a dye-sensitized photoelectric conversion device array according to a seventh embodiment of the disclosed technology; and

FIGS. 25 and 26 are sectional views showing a light guiding structure of a related-art dye-sensitized solar cell.

### DETAILED DESCRIPTION OF THE PREFERRED EMBODIMENTS

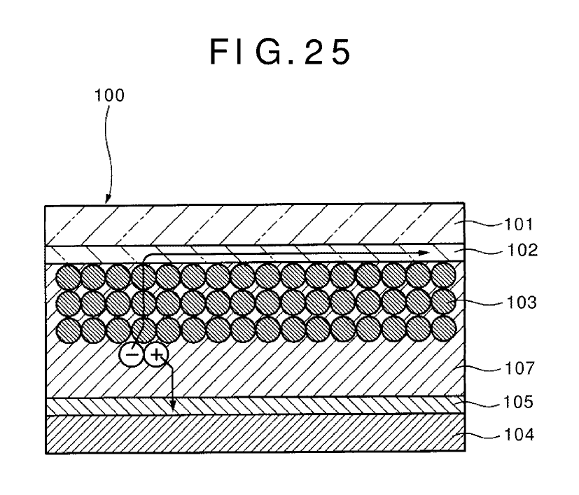

FIG. 25 shows a cross section of an essential part of a structure of a general dye-sensitized solar cell 100.

Referring to FIG. 25, in the dye-sensitized solar cell 100, a transparent electrode 102 of a FTO layer is provided on one principal surface of a transparent substrate 101, and a porous electrode 103 configured from a sintered body of TiO₂ is provided on the transparent electrode 102. One or plural kinds of photosensitizing dyes not shown are coupled to the porous electrode 103. On the other hand, a transparent conductive layer is provided on one principal surface of an opposed substrate 104, and a counter electrode 105 is provided on the transparent conductive layer. Further, an electrolyte layer 107 configured from electrolyte solution for which oxidation and reduction species of I⁻/I₃⁻ are used is filled as a redox couple between the porous electrode 103 on the transparent substrate 101 and the counter electrode 105 on the opposed substrate 104, and the outer periphery of the transparent substrate 101 and the opposed substrate 104 is sealed by a sealing member not shown.

If light is introduced into the porous electrode 103, then the dye-sensitized photoelectric conversion device 100 operates as a cell wherein the transparent electrode 102 and the counter electrode 105 serve as a negative electrode and a positive electrode, respectively. In particular, if photons passing through the transparent substrate 101 and the transparent electrode 102 and entering the porous electrode 103 are absorbed by the photosensitizing dye coupled to the porous electrode 103, then electrons in the photosensitizing dye are excited from a base state (HOMO) to an excited state (LUMO). The excited electrons are extracted to a conduction band of TiO₂ which configures the porous electrode 3 through electric coupling between the photosensitizing dye and the porous electrode 3, and reaches the transparent electrode 102 through the porous electrode 103.

On the other hand, the photosensitizing dye whose electrons are lost receives electrons by a reaction given below from a reducer in the electrolyte layer 7, for example, from I⁻, to produce an oxidizer, for example, I₃⁻ (aggregate of I₂ and I⁻), in the electrolyte layer 7.

2I⁻→I₂+2e⁻

I+I⁻→I₃⁻

The oxidizer produced in this manner is diffused to reach the counter electrode 105 and receives electrons from the counter electrode 105 by a reverse reaction to the reaction described above so that it is reduced to the original reducer.

I₃⁻→I₂+I⁻

I₂+2e⁻→2I⁻

The electron sent out from the transparent electrode 102 to an external circuit carries out an electric work in the external circuit and thereafter returns to the counter electrode 105. In this manner, light energy is converted into electric energy without causing any change in the photosensitizing dye and the electrolyte layer 107.

In this manner, since electrons generated by a light sensitization action reach the transparent electrode 102 through the porous 103 and then are sent out to the external circuit, in order to raise the photoelectric conversion efficiency of the dye-sensitized solar cell 100, it is significant to extract the energy of the generated electrons to the outside without loss. To this end, it is significant to reduce the internal resistance of the transparent electrode 102 which is an extraction path of the electrons as far as possible thereby to suppress the resistance loss.

However, since the transparent electrode 102 is exhibits significant transmission loss of light, in order to utilize the light inputted to the transparent substrate 101 in the maximum, it is significant to form the transparent electrode 102 very thin. Thus, the truth of the matter is that the electric resistance of the transparent electrode 102 is comparatively high.

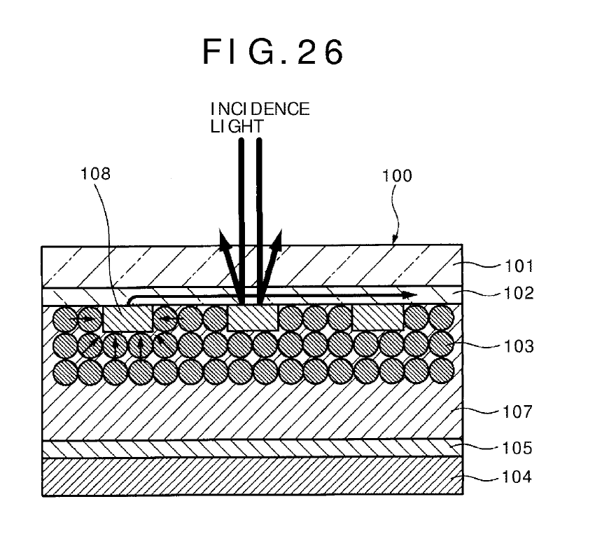

In order to suppress the energy loss when the generated electrons are extracted to the outside, as shown in FIG. 26, a belt-shaped groove is provided on a light reception face of the porous electrode 103 and a collecting wiring line 108 of silver (Ag) or the like having high conductivity is formed on the transparent electrode 102 so as to fit with the belt-shaped groove. Since the chemical resistance of the collecting wiring line 108 is generally low with regard to electrolyte solution which configures the electrolyte layer 107, a collecting wiring line protective layer 109 for protecting the collecting wiring line 108 from the electrolyte solution is provided. Since, by the provision of the collecting wiring line 108, the electrons reach the transparent electrode 102 from the porous electrode 103 through the collecting wiring line 108 having the high conductivity, the energy loss when the generated electrons are extracted to the outside is reduced.

However, since the collecting wiring line 108 is configured from a light blocking effect material such as a metal and is provided at an upper portion of the light reception face of the porous electrode 103 in a state in which it occupies a fixed area, as shown in FIG. 26, light incident to the transparent electrode 102 is blocked by the collecting wiring line 108 or the collecting wiring line protecting layer 109 and does not reach the porous electrode 103. Therefore, a region which cannot contribute to power generation appears in the porous electrode 103. In other words, the area of the photoelectric conversion region in the light reception face decreases.

For example, it is assumed that light which can be approximated as generally collimated parallel light is incident perpendicularly to the transparent substrate 101, and the width of the porous electrode 103 is set to 5 mm and the width of the collecting wiring line 108 is set to 1.5 mm and besides the collecting wiring line 108 is repetitively disposed on the transparent electrode 102. If it is assumed that the numerical aperture of the light incidence face in the case where the collecting wiring line 108 is not disposed is 100%, then in the case just described, then the numerical aperture decreases to 76.9% by the provision of the collecting wiring lines 108, and the decrease of the numerical aperture contributes as it is to decrease of the photoelectric conversion efficiency, and as a result, contributes to decrease of the power generation efficiency.

Therefore, the disclosure of the disclosed technology has proposed that the light guide path of incidence light which is blocked by the collecting wiring line 108 and cannot contribute to power generation is changed by the light guiding structure provided in the transparent substrate 101, on the transparent substrate 101 or above the transparent substrate 101 to avoid blocking of the incidence light by the collecting wiring line 108 so as to guide the incidence light into the porous electrode 103 which is the power generation section so that the numerical aperture of the light incidence face upon light taking in can be theoretically made 100%.

In the following, embodiments for carrying out the disclosed technology are described. It is to be noted that the embodiments are described in the following order.

1. First Embodiment (dye-sensitized photoelectric conversion device and fabrication method of the same)

Modifications to First Embodiment (dye-sensitized photoelectric conversion device and fabrication method of the same)

2. Second Embodiment (dye-sensitized photoelectric conversion device and fabrication method of the same)

Modifications to Second Embodiment (dye-sensitized photoelectric conversion device and fabrication method of the same)

3. Third Embodiment (dye-sensitized photoelectric conversion device and fabrication method of the same)
4. Fourth Embodiment (dye-sensitized photoelectric conversion device and fabrication method of the same)
5. Fifth Embodiment (dye-sensitized photoelectric conversion device and fabrication method of the same)
6. Sixth Embodiment (dye-sensitized photoelectric conversion device and fabrication method of the same)
7. Seventh Embodiment (dye-sensitized photoelectric conversion device and fabrication method of the same)

### 1. First Embodiment

### Dye-Sensitized Photoelectric Conversion Device

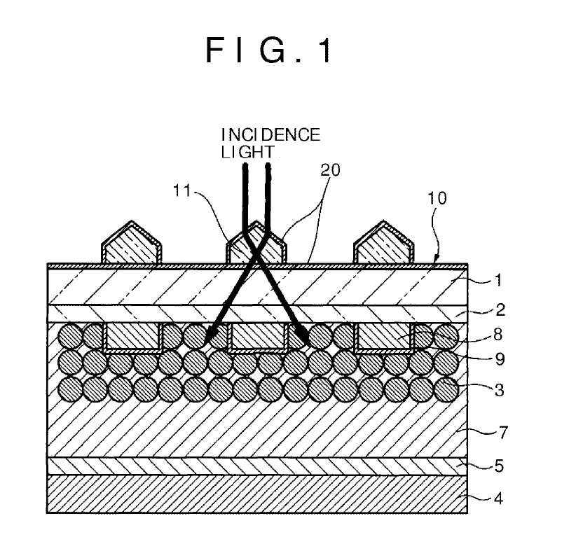

FIG. 1 shows a cross section of an essential part of a dye-sensitized photoelectric conversion device 10 according to a first embodiment.

Referring to FIG. 1, in the dye-sensitized photoelectric conversion device 10 shown, a transparent electrode 2 is provided on one principal surface of a transparent substrate 1, and a plurality of collecting wiring lines 8 having a collecting wiring line protective layer 9 provided thereon are provided in a predetermined spaced relationship from each other on the face of the transparent substrate 1 on which the transparent electrode 2 is provided. A porous electrode 3 is provided on a face of the transparent substrate 1 on which the collecting wiring lines 8 are provided. To the porous electrode 3, one or plural kinds of photosensitizing dyes not shown are coupled. Further, light guiding structures 11 having a convex three-dimensional shape are provided on a face of the transparent substrate 1 on the opposite side to the face on which the collecting wiring lines 8 are provided. Meanwhile, a transparent conductive layer is provided on one principal surface of a counter substrate 4, and a counter electrode 5 is provided on the transparent conductive layer. An electrolyte layer 7 formed from electrolyte is filled between the porous electrode 3 on the transparent substrate 1 and the counter electrode 5 on the counter substrate 4, and the transparent substrate 1 and the counter substrate 4 are sealed at an outer periphery thereof with a sealing material not shown.

As the porous electrode 3, typically a porous semiconductor layer in which semiconductor fine particles are sintered is used. The photosensitizing dye absorbs on the surface of the semiconductor fine particles. As the material for the semiconductor fine particles, element semiconductors represented by silicon, compound semiconductors, semiconductors having a provskite structure and so forth can be used. Preferably, the semiconductors are n-type semiconductors in which, in a state in which they are excited by light, conduction band electrons serve as a carrier to generate anode current. In particular, for example, such semiconductors as titanium oxide (TiO₂), zinc oxide (ZnO), tungstic oxide (WO₃), niobium oxide (Nb₂O₅), strontium titanate (SrTiO₃) and tin oxide (SnO₂) are used. Preferably, TiO₂, especially TiO₂ of the anatase type, is used preferably from among the semiconductors mentioned. However, the type of the semiconductor is not limited to them, but also it is possible to use two or more kinds of the semiconductors mentioned in a mixed or complexed form as occasion demands. Further, the shape of the semiconductor particles may be any of a granular shape, a tube-like shape, a bar-like shape and so forth.

Although there is no particular limitation to the particle size of the semiconductor fine particles, the particle size preferably is, in an average particle size of primary particles, 1 to 200 nm, and more particularly is 5 to 100 nm. Also it is possible to mix particles of a size greater than that of the semiconductor fine particles such that incidence light is scattered by the mixed particles to improve the quantum yield. In this instance, although the average size of the particles to be mixed preferably is 20 to 500 nm, it is not limited to this size.

Preferably, the porous electrode 3 has a large actual surface area including also fine particle surfaces which face vacancies in the inside of the porous semiconductor layer formed from semiconductor fine particles so that photosensitizing dye can be coupled as much as possible to the porous electrode 3. To this end, the actual surface area in a state in which the porous electrode 3 is formed on the transparent substrate 1 preferably is as great as 10 times or more of the area, that is, the projection area, of the outer side surface of the porous electrode 3, and more preferably is as great as 100 times or more. Although there is no upper limit to this ratio, usually the ratio is approximately 1,000 times.

Generally, as the thickness of the porous electrode 3 increases and the number of semiconductor fine particles included in unit projection area increases, the actual surface area increases and the amount of photosensitizing dye which can be held in a unit projection area increases, and consequently the optical absorptance increases. On the other hand, if the thickness of the porous electrode 3 increases, then the distance over which an electron which has migrated from the photosensitizing dye to the porous electrode 3 diffuses before it reaches a collecting wiring line 8 or the transparent electrode 2 increases. Therefore, also the loss of electrons by charge re-coupling in the porous electrode 3 increases. Accordingly, a preferable thickness exists with the porous electrode 3, and this thick generally is 0.1 to 100 μm, and more preferably is 1 to 50 μm and most preferably is 3 to 30 μm.

As the electrolyte which configures the electrolyte layer 7, solution containing an oxidation-reduction system or redox couple is available. As the oxidation-reduction system, a combination of iodine (I₂) and a metal or of an organic matter and an iodide salt, a combination of bromine (Br₂) and an organic bromide salt or an organic bromide salt and so forth are available. The cations which configure the metal salt may be, for example, lithium (Li⁺), sodium (Na⁺), potassium (K⁺), cesium (Cs⁺), Magnesium (Mg²⁺) or calcium (Ca²⁺). Meanwhile, for the cations which configure the organic salt, quaternary ammonium ions such as tetraalkylammonium ions, pyridinium ions or imidazolium ions are suitably used, and such ions may be used solely or as a mixture of two or more thereof.

For the electrolyte which configures the electrolyte layer 7, in addition to the ions specified as above, a metal complex such as a combination of a ferrocyanic acid salt and a ferricyanic acid salt or a combination of ferrocene and ferricynium ions, a sulfur compound such as polysulfide sodium or a combination of alkylthiol and alkyl disulfide, a viologen dye, a combination of hydrochinone and chinone or the like can be used.

As the electrolyte which configures the electrolyte layer 7, particularly from among the substances, an electrolyte configured from a combination of iodine (I₂) and a quaternary ammonium compound such as lithium iodide (LiI), sodium iodide (NaI) or imidazolium iodide is preferably used. Preferably, the concentration of the electrolytic salt is 0.05 M to 10 M with respect to the solvent, and more preferably is 0.2 M to 3 M. The concentration of iodine (I₂) or bromine (Br₂) preferably is 0.0005 M to 1 M, and more preferably is 0.001 M to 0.5 M.

The transparent substrate 1 is not limited particularly only if it is made of a material and has a shape with which light can be transmitted well therethrough, and various substrate materials can be used. However, particularly a substrate material having a high transmission factor with respect to the visible rays is used preferably. Further, the transparent substrate 1 is made of a material having a high blocking performance of blocking water or gas which tends to invade a dye-sensitized photoelectric conversion device and is superior in solvent resistance and weather resistance. More particularly, as a material for the transparent substrate 1, transparent inorganic materials such as quartz and glass and transparent plastics such as polyethylene terephthalate, polyethylene naphthalate, polycarbonate, polystyrene, polyethylene, polypropylene, polyphenylene sulfide, polyvinylidene fluoride, acetyl cellulose, brominated phenoxy, aramids, polyimides, polystylenes, polyallylates, polysulfones and polyolefins are used. The thickness of the transparent substrate 1 is not limited particularly but can be selected suitably taking the light transmission factor and a performance for isolating the photoelectric conversion device into consideration. Further, the thickness of the transparent substrate 1 preferably is 0.2 mm to 5 mm, and more preferably is 0.5 mm to 3 mm, and most preferably is 0.5 mm to 1.5 mm. However, the thickness of the transparent substrate 1 is not limited to those values.

The transparent electrode 2 provided on one main face of the transparent substrate 1 preferably has lower sheet resistance. Particularly, the transparent electrode 2 preferably has sheet resistance lower than 500Ω/□, and more preferably has sheet resistance lower than 100Ω/□. As a material for forming the transparent electrode 2, a known material can be used and is selected as occasion demands. The material for forming the transparent electrode 2 particularly may be indium-tin oxide composite (ITO), fluoride-doped tin oxide (IV) SnO₂ (FTO), tin oxide (IV) SnO₂, zinc oxide (II) ZnO, indium-zinc oxide component (IZO) or the like. However, the material for forming the transparent material 2 is not limited to them, but a combination of two or more of them may be used.

Each of the collecting wiring lines 8 preferably has a post-like shape and has a bottom face of a shape which may be one or a combinations of a plural ones of a triangular shape, a rectangular shape, a trapezoidal shape, a polygonal shape, a circular shape, an elliptical shape and part of any of the shapes. The shape and the area of the bottom face may be fixed or different among the collecting wiring lines 8. Further, although each of the collecting wiring lines 8 may be formed such that it extends in a normal direction to the bottom face thereof or the cross section thereof may extend in a direction of an arbitrary angle to form a curved post-like shape. However, the collecting wiring lines 8 are not limited to those of the configurations described above but may have such a planar shape or a curved face shape which covers at least part of the transparent substrate 1 or the transparent electrode 2.

Each of the collecting wiring lines 8 may be installed basically in any installation form only if it contacts with the porous electrode 3. Typically, each of the collecting wiring lines 8 is provided such that it contacts at least at one face thereof with at least part of the transparent substrate 1 or the transparent electrode 2 and contacts at the other faces thereof than the face, which contacts with the transparent substrate 1 or the transparent electrode 2, with the porous electrode 3. For example, if the collecting wiring line 8 provided on the transparent substrate 1 or the transparent electrode 2 is a post body, it is provided in such a form that the post body contacts at one side face thereof or at part of one side face thereof with the transparent substrate 1 or the transparent electrode 2. The collecting wiring line 8 is provided typically in such an installation form that it is installed in one or a combination of plural ones of a belt-like form, a linear form, a curved form and so forth parallel to a side of the transparent substrate 1 and is fitted in a groove provided on the porous electrode 3. However, the installation form of the collecting wiring line 8 is not limited to them.

Further, if the collecting wiring line 8 is formed as an electrode, then electrons can be extracted to the outside of the dye-sensitized photoelectric conversion device 10 using the collecting wiring line 8 as a negative electrode, preferably by connecting such collecting wiring lines 8 to each other without providing the transparent electrode 2 on the dye-sensitized photoelectric conversion device 10. In this instance, although the collecting wiring lines 8 are provided in contact with the porous electrode 3 on the face of the transparent substrate 1 on which the porous electrode 3 is provided, the installation of the collecting wiring lines 8 is not limited to this, but the collecting wiring lines 8 may otherwise be provided in the collecting wiring line 8.

Particularly, in the case where the collecting wiring lines 8 are post bodies and have a bottom face of a rectangular shape, they are installed preferably in an installation form in which they are provided in a belt-like form or a linear form in a predetermined spaced relationship from each other. The collecting wiring lines 8 are particularly dimensioned such that the length of the sides extending in the longitudinal direction of the bottom face (the direction is defined as a widthwise direction of the collecting wiring lines 8) preferably is within the range of 0.01 to 5 mm and more preferably is within the range of 0.05 to 1 mm. Further, the length of the sides extending in the lateral direction of the bottom face (the direction is defined as a thicknesswise direction of the collecting wiring lines 8) preferably is within the range of 1 to 30 μm and more preferably is within the range of 5 to 10 μm. In this instance, each of the collecting wiring lines 8 is provided in such a form that the side faces thereof corresponding to the sides in the widthwise direction of the bottom face contact with the transparent substrate 1 or the transparent electrode 2. Further, for example, if the bottom face has a trapezoidal shape, then the height of the sectional shape where the side of the bottom face which contacts with the transparent substrate 1 or the transparent electrode 2 is the base preferably is within the range of 1 to 30 μm and more preferably is within the range of 5 to 10 μm. Further, for example, if the sectional shape has a triangular shape, then the height of the sectional shape where the side of the sectional shape which contacts with the transparent substrate 1 or the transparent electrode 2 is the base preferably is within the range of 1 to 30 μm and more preferably is within the range of 5 to 10 μm. Further, the length of the collecting wiring line 8 in the extending direction of the bottom face, which is a depthwise direction of the collecting wiring line 8, in the particular example of the collecting wiring line 8 described above is determined suitably based on the shape of the transparent substrate 1, the shape of the transparent electrode 2, the arrangement of the collecting wiring lines 8 or the like and so forth. However, the length is determined not only based on them. For example, in the case where the collecting wiring lines 8 have a planar form such as a sheet form, also it is effective to adopt such a configuration that a cavity is provided in the collecting wiring lines 8 in order to allow transmission of incidence light therethrough, for example, to configure collecting wiring lines 8 of a houndstooth-like form while a plurality of cavities are provided on a face of each of the collecting wiring lines 8. The width, thickness and depthwise length of the collecting wiring lines 8 can be determined suitably preferably within the ranges described above. It is to be noted that the widthwise direction, thicknesswise direction and depthwise direction of the wiring lines 8 are common to those in the case where each of the transparent substrate 1, transparent electrode 2 and light guiding structures 11 is a straight post body and are hereinafter referred to as “widthwise direction,” “thicknesswise direction” and “depthwise direction,” respectively.

The material which configures the collecting wiring lines 8 is suitably selected from among materials having high conductivity, and particularly a metal material, a carbon material, a conductive polymeric material and so forth are used. As the metal material, gold (Au), silver (Ag), copper (Cu), zinc (Zn), iron (Fe), platinum (Pt), aluminum (Al) and so forth are available. However, the material for forming the collecting wiring lines 8 is not limited to them.

Since the faces of the collecting wiring lines 8 which contact with the porous electrode 3 normally contact with the electrolyte and so forth which configure the electrolyte layer 7, in the case where a material having a low electrolyte resisting property or a low solvent resisting property is selectively used as the material for the collecting wiring lines 8, a collecting wiring line protective layer 9 for protecting the collecting wiring lines 8 from the electrolyte and so forth can be provided on the above-mentioned faces of the collecting wiring lines 8. The collecting wiring line protective layer 9 is formed typically such that it covers the entire surface or those faces of the collecting wiring lines 8 which contact with the porous electrode 3. However, the form of the collecting wiring line protective layer 9 is not limited to this.

The material to be used for the collecting wiring line protective layer 9 is suitably selected from materials which are superior in electrolyte resisting property and solvent resisting property. In particular, a metal oxide material or a metal material can be applied. As the metal oxide material, aluminum oxide (Al₂O₃), titanium oxide (TiO₂), zinc oxide (ZnO), tungstic oxide (WO₃), niobium oxide (Nb₂O₅), strontium titanate (SrTiO₃), tin oxide (SnO₂) and so forth are available. Meanwhile, as the metal material, for example, titanium (Ti), nickel (Ni), niobium (Nb), tantalum (Ta), tungsten (W), stainless steel (SUS), an indium-tin composite oxide (ITO) and so forth are available. However, the material for use with the collecting wiring line protective layer 9 is not limited to those specified above.

Each of the light guiding structures 11 may basically be any structure only if it has a convex three-dimensional shape and can transmit light therethrough. The light guiding structure 11 is configured suitably selecting a material from among the materials listed above and has a shape of a post body having a bottom face of a symmetrical shape with respect to a line. However, the shape of the light guiding structure 11 is not limited to this but may be an unsymmetrical shape or may be a conical shape or a polygonal shape. Further, the light guiding structures 11 are provided on the light incidence side face of the transparent substrate 1 and preferably are provided along the collecting wiring lines 8 provided on the face of the transparent substrate 1 on the opposite side to the light incidence side face. If each of the light guiding structures 11 is a post body and has a bottom face of a shape symmetrical with respect to a line, most preferably it is provided such that the center axis of the bottom face of the collecting wiring line 8 in the widthwise direction and the center axis of the bottom face of the light guiding structure 11 in the widthwise direction are placed on the same straight line. However, the installation of the light guiding structures is not limited to this. Further, the transparent substrate 1 may be worked to provide convex faces or concave faces on the transparent substrate 1 such that the transparent substrate 1 itself serves as the light guiding structures 11. Particularly in the case where the vertical section of the convex portions or the concave portions has a shape symmetrical with respect to a line, the transparent substrate 1 is preferably configured such that the center axis of the bottom face of each collecting wiring line 8 in the widthwise direction and the axis of symmetry of each of the convex portions or the concave portions are placed on the same straight line.

Further, the shape of the light guiding structures 11 is suitably designed and selected depending upon the installation position of the light guiding structures 11, configuration of the transparent substrate 1, shape of the collecting wiring lines 8 and so forth in addition to those described above. In particular, a shape in which blocking of the light guide path of light incident to the light guiding structures 11 by the collecting wiring lines 8 can be avoided and the light can be guided most efficiently into the porous electrode 3 is selected. Particularly, it is preferable to make the width of the collecting wiring lines 8 equal to the width of the light guiding structures 11.

The light guiding structures 11 are dimensioned such that, in the case where they are prisms of a post-like shape, preferably the width of the bottom face is 0.1 to 5 mm, the thickness of the bottom face is 0.1 to 5 mm and the depth is 10 to 500 mm, and more preferably the width of the bottom face is 0.1 to 0.8 mm, the thickness of the bottom face is 0.1 to 1 mm and the depth is 100 to 500 mm. Most preferably, the width of the bottom face is 0.1 to 0.4 mm, the thickness of the bottom face is 0.1 to 0.5 mm, and the depth is 200 to 400 mm. On the other hand, in the case where the light guiding structures 11 are provided concave faces provided on the transparent substrate 1, preferably the width of the convex portion is 0.1 to 5 mm, the deepness of the convex portion is 0.1 to 5 mm and the depth is 10 to 500 mm, and more preferably the width of the convex portion is 0.1 to 0.8 mm, the deepness of the convex portion is 0.1 to 0.5 mm and the depth is 100 to 500 mm. Most preferably, the width of the convex portion is 0.1 to 0.4 mm, the deepness of the convex portion is 0.1 to 0.4 mm, and the depth is 200 to 400 mm. However, the shape and the size of the light guiding structure 11 are not limited to the shapes and dimensions listed above.

Also it is possible to provide, on a face of the transparent substrate 1 or the light guiding structure 11 on the side to which light is incident, an anti-reflection layer 20 by forming a multilayer film formed at least from one layer or a nanosized structure. In the case where the anti-reflection layer 20 is a multilayer film, although the anti-reflection layer 20 provided on the transparent substrate 1 and the light guiding structure 11 is preferably designed individually optimally, the anti-reflection layer 20 is not limited to them. On the other hand, in the case where the anti-reflection layer 20 is formed from a nanosized structure such as, for example, a moth-eye structure, the anti-reflection layer 20 provided on the transparent substrate 1 and the light guiding structure 11 can be configured by applying a nanosized structure of the same configuration without individually designing them optimally because the moth-eye structure exhibits low incidence angle dependency in principle. However, the anti-reflection layer 20 is not limited to them.

An example of the design of a light guiding structure 11 in the case where the light guiding structure 11 is configured from a prism particularly of a convex shape is described.

The light guiding structure 11 is provided on the opposite side to a collecting wiring line 8 with respect to the transparent substrate 1 on a face of the transparent substrate 1 on the light incidence side and can be designed in the following manner. Further, in this instance, although it is assumed that incidence light is incident in a direction perpendicular to the transparent substrate 1, the incidence light to the light guiding structure 11 is not limited to this, but the light guiding structure 11 can be designed similarly also with regard to incidence light from an oblique direction.

If the width and the thickness of the collecting wiring line 8 are represented by L₁ and L₂, respectively, the width and the thickness of the light guiding structure 11 by L₃ and L₄, respectively, the thickness of the transparent substrate 1 is represented by L₅, the refractive index of the air by nₐ, the refractive index of the light guiding structure 11 by nₚ, the incidence angle to an interface when the light is incident from the air to the light guiding structure 11 by θ₁, and the emergence angle from the interface by θ₂, then the following expression is satisfied from the Snell's law:

nₐ sin θ₁=nₚ sin θ₂ (1)

Further, if the refractive index of the transparent substrate 1 is represented by n_{g} and the incidence angle and the emergence angle of light to and from an interface when light is incident from the light guiding structure 11 to the transparent substrate 1 are represented by φ₁ and φ₂, respectively, then the following expression is satisfied from the Snell's law:

nₚ sin φ₁=n_{g} sin φ₂ (2)

Here,

φ₁=θ₁−θ₂ (3)

Here, in the case where the light guiding structure 11 is provided on the transparent substrate 1, if a widthwise direction component of a distance along a light path when light incident from an input end of the light guiding structure 11 in the widthwise direction is guided by and passes through the light guiding structure 11 is represented by Lₚ and a widthwise direction component of a distance along a light path when the light is guided by and passes through the transparent substrate 1 is represented by L_{g}, then in order to avoid blocking of the light guide path by the collecting wiring line 8, it is necessary to satisfy the following expression:

$${L}_{1} - \frac{{L}_{1} - {L}_{3}}{2} < {L}_{p} + {L}_{g} \qquad ( 4 )$$

Further, if incidence of parallel light to a top angle portion of the light guiding structure 11 is considered, then the incidence light passes along a light path which bypasses the collecting wiring line 8 by a greater amount because it becomes inversion radiation light. However, if the thickness L₄ of the light guiding structure 11 becomes excessively great, then light is reflected by a vertical plane in the inside of the light guiding structure 11 and cannot be guided efficiently to the porous electrode 3. In order to avoid this, the widthwise direction component Lₚ′ of the distance along the light path when the light passes through the light guiding structure 11 must satisfy the following expression:

$${L}_{p}^{′} = {L}_{4} tan ( {φ}_{1} ) < \frac{{L}_{3}}{2} \qquad ( 5 )$$

In the dye-sensitized photoelectric conversion device 10 in the present embodiment, the width L₁ and the thickness L₂ of the collecting wiring line 8, the width L₃ and the thickness L₄ of the light guiding structure 11, the thickness L₅ of the transparent substrate 1, the refractive index nₚ of the light guiding structure 11, the refractive index n_{g} of the transparent substrate 1, the incidence angle θ₁ at the interface at which the light is incident to the light guiding structure 11 and the installation position of the light guiding structure 11 are suitably determined so as to satisfies the expressions (4) and (5) given hereinabove. However, the designing method of the light guiding structure 11 is not limited to this.

Although the photosensitizing dye to be coupled to the porous electrode 3 is not limited particularly only if it exhibits a sensitization action, a photosensitizing dye having an acid functional group absorptive to the surface of the porous electrode 3 is preferably used. Generally, the photosensitizing dye preferably has a carboxyl group, a phosphate group or the like, and particularly preferably has a carboxyl group among them. As particular examples of the photosensitizing dye, xanthene dyes such as, for example, rhodamine B, rose Bengal, eosine and erythrosin, cyanine dies such as merocyanine, quinocyanine and cryptocyanine, basic dies such as phenosafranine, Capri blue, thiocin and methylene blue and porphyrin compounds such as chlorophyll, zinc porphyrin and magnesium porphyrin are used. As other examples of the photosensitizing dye, azo dye, phthalocyanine compound, coumarin compound, bipyridine complex compound, anthraquinone dye and polycyclic quinine dye are used. Among them, a dye of a complex of at least one kind of metal selected from the group consisting of Ru, Os, Ir, Pt, Co, Fe and Cu and having a ligand which includes a pyridine ring or an imidazolium ring is preferably used because it exhibits a high quantum yield. Specifically, a dye molecule having a basic skeleton of cis-bis(isothiocyanate)-N,N-bis(2,2′-dipyridine-4,4′-dicarboxlylic acid)-ruthenium(II) or tris(isothiocyanate)-ruthenium(II)-2,2′:6′,2″-terpyridine-4,4′,4″tricarboxilic acid has a wide absorption wave range and hence is preferably used. However, the photosensitizing dye is not limited to them.

As the photosensitizing dye, although typically one of the substances mentioned above is used, two or more of the substances may be used in mixture. Where two or more of the above-mentioned photosensitizing dyes are used in mixture, the photosensitizing dye preferably has an inorganic complex dye having a property of causing MLCT (Metal to Ligand Charge Transfer) and an organic molecule dye having another property of intramolecular CT (Charge Transfer), retained on the porous electrode 3. In this instance, the inorganic complex dye and the organic molecule dye absorb the porous electrode 3 in different conformations from each other. The inorganic complex dye preferably has a carboxyl group or a phosphono group as functional groups to couple to the porous electrode 3. The organic complex dye preferably has a carboxyl group or a phosphono group and a cyano group, an amino group, a thiol group or a thione group as functional groups to couple to the same carbon and to the porous electrode 3. The inorganic complex dye is, for example, polypyridine complexes, and the organic molecule dye is, for example, aromatic polycyclic conjugated molecules having both of an electron-donating group and an electron-accepting group and having an intramolecular CT property.

Although there is no limitation to the absorption method of the photosensitizing dye to the porous electrode 3, it is possible to dissolve any of the photosensitizing dye into solvent such as, for example, alcohols, nitriles, nitromethane, halogenated hydrocarbons, ethers, dimethyl sulfoxide, amides, N-methylpyrrolidone, 1,3-dimethyl imidazolidinone, 3-methyl oxazolidinone, esters, carbonate esters, ketones, hydrocarbons and water and dip the porous electrode 3 into the solution or apply solution containing a photosensitizing dye to the porous electrode 3. Further, deoxycholic acid or the like may be added in order to reduce the association of molecules of the photosensitizing dye. Also it is possible to additionally use an ultraviolet absorbing agent as occasion demands.

After the photosensitizing dye absorbs onto the porous electrode 3, in order to promote removal of excessively absorbing part of the photosensitizing dye, amines may be used to process the surface of the porous electrode 3. As the amines, pyridine, 4-tert-butylpyridine, polyvinylpiridine and so forth are available. In the case where they are in the form of liquid, they may be used as they are, or they may be dissolved into and used together with organic solvent.

Although the counter electrode 5 can be configured using an arbitrary material only if it is a conductive substance, if a conductive layer is formed on a side of an insulating material which faces the electrolyte layer 7, then also it is possible to use this. As the material for the counter electrode 5, it is preferable to use a material which is electrochemically stable, and particularly it is desirable to use platinum, gold, carbon, conductive polymer or the like.

Further, in order to improve the catalytic action for a reduction action on the counter electrode 5, the surface of the counter electrode 5 which contacts with the electrolyte layer 7 is configured such that fine structures are formed to increase the actual surface area. For example, the surface of the counter electrode 5 is preferably formed such that it is, if the counter electrode 5 is formed from platinum, in a platinum block state, but if the counter electrode 5 is formed from carbon, in a state of porous carbon. The platinum black can be formed by an anodic oxidation coating method of platinum, a chloroplatinic acid process or the like. Meanwhile, the porous carbon can be formed by such a method as sintering of carbon fine particles or baking of organic polymer.

Although the counter electrode 5 is formed on the transparent conductive layer formed on one principal surface of the counter substrate 4, the formation of the counter electrode 5 is not limited to this. As the material for the counter substrate 4, opaque glass, a plastic material, a ceramic material, a metal material or the like may be used, or a transparent material such as, for example, transparent glass, plastic or the like may be used. As the transparent conductive layer, a conductive layer similar to the transparent electrode 2 can be used.

As the material for the sealing medium, preferably a material having light resistance, insulating properties, moisture resistance and so forth is used. For the material for the sealing medium, an epoxy resin, an ultraviolet curing resin, an acrylic resin, a polyisobutylene resin, EVA (ethylene vinyl acetate), an ionomer resin, ceramics, various heat sealed films and so forth are available.

Further, when the electrolyte is to be injected, an inlet is required. However, the place of the inlet is not limited specifically only if it is not on the porous electrode 3 nor on the counter electrode 5 at a position corresponding to the porous electrode 3. Further, although there is no particular restriction to the injection method of the electrolyte, preferably a method of carrying out the injection under a reduced pressure into the inside of the photoelectric conversion device which is sealed at an outer periphery thereof in advance and in which the inlet for solution is perforated is used. In this instance, a method of dripping the solution by several drops into the inlet such that the liquid is injected by a capillarity is simple and convenient. Further, as occasion demands, also it is possible to carry out a liquid injection operation in a decompressed or heated state. After the solution is injected fully, the solution remaining at the inlet is removed and the inlet is sealed. Although there is no particular limitation to the sealing method in this instance, if necessary, a glass plate or a plastic substrate is adhered by a sealant for sealing. Also it is possible to drop the electrolyte onto the substrate to adhere the glass plate or the plastic substrate under a decompressed condition to carry out sealing like a liquid crystal dropping filling (ODF: One Drop Filling) step of a liquid crystal panel. After the sealing is carried out, also it is possible to carry out heating and/or pressurizing operations as occasion demands in order to impregnate the electrolyte fully into the porous electrode 3.

### Fabrication Method of the Dye-Sensitized Photoelectric Conversion Device

Now, a fabrication method of the dye-sensitized photoelectric conversion device 10 is described.

First, a glass material is worked and molded into a desired convex three-dimensional shape to form light guiding structures 11. For the formation of the light guiding structures 11, one of known techniques can be selectively used suitably. For example, casting, cutting, molding and injection molding are available. Although the light guiding structures 11 are preferably formed by a flow method by transparent or photocuring resin dispense or a nanoimprint method, the formation method of the light guiding structures 11 is not limited to them.

Then, the glass plate is cut out in a desired size to obtain a transparent substrate 1.

Then, the light guiding structures 11 are joined to one principal surface of the transparent substrate 1. As the joining method, a suitable one of known methods can be selectively used. For example, although adhesion, fusion and optical welding are available, the joining method of the light guiding structures 11 is not limited to them. The joining of the light guiding structures 11 can be carried out at a later step or after the dye-sensitized photoelectric conversion device 10 is completed unless a special environment such as a high temperature or a high pressure is required for the joining.

Also it is possible, in place of the step described above, to form the light guiding structures 11 by working the transparent substrate 1 to form convex three-dimensional shapes. The working method in the case where the transparent substrate 1 is worked to form the light guiding structures 11 is selected suitably from among known methods, and for example, cutting or molding is applicable. However, the working method of the transparent substrate 1 is not limited to them.

Then, a transparent conductive layer is formed on the face of the transparent substrate 1 opposite to the face on which the light guiding structures 11 are provided by sputtering or the like to form a transparent electrode 2. In the case where collecting wiring lines 8 are to be connected to each other to form an electrode, the step just described is omitted.

Thereafter, aluminum (Al) is vacuum evaporated in a desired pattern on the transparent substrate 1 or the transparent electrode 2 to form collecting wiring lines 8. Further, the surface of the collecting wiring lines 8 is oxidized by a thermal process, an electric process or a chemical process to form a collecting wiring line protective layer 9.

Then, a porous electrode 3 is formed on a face of the transparent substrate 1 on which the collecting wiring lines 8 are provided. Although there is no limitation particularly to the formation method of the porous electrode 3, in the case where physical properties, convenience, fabrication cost and so forth are taken into consideration, it is preferable to use a wet film-forming method. In the wet film-forming method, a method is preferable wherein powder or sol of semiconductor fine particles is dispersed uniformly into solvent such as water to prepare fluid dispersion in the form of paste and then the fluid dispersion is applied to or printed on the transparent substrate 1 or the transparent electrode 2. There is no particular limitation to the application method or the printing method of the fluid dispersion, but a known method can be used. In particular, as the application method, for example, a dipping method, a spraying method, a wire bar method, a spin coating method, a roller coating method, a blade coating method or a gravure coating method can be used. Meanwhile, as the printing method, a relief printing method, an offset printing method, a gravure printing method, an intaglio printing method, a rubber plate printing method or a screen printing method can be used.

In the case where anatase type TiO₂ is used as the material for semiconductor fine particles, a commercial item of anatase type TiO₂ in the form of powder, sol or slurry may be used, or anatase type TiO₂ of a predetermined particle size may be formed by a known method such as a method of hydrolyzing titanium oxide alkoxide. When powder on the market is used, preferably secondary aggregation of particles is eliminated, and upon preparation of paste-like fluid dispersion, preferably a mortar, a ball mill or the like is used to crush the particles. At this time, in order to prevent the particles, whose secondary aggregation is eliminated, from aggregating once again, acetylacetone, hydrochloric acid, nitric acid, detergent or chelating agent or the like can be added to the paste-like fluid dispersion. Further, in order to increase the viscosity of the paste-like fluid dispersion, also it is possible to add high polymer of polyethylene oxide or polyvinyl alcohol or various thickeners such as cellulose-based thickeners to the paste-like fluid dispersion.

Preferably, the semiconductor fine particles of the porous electrode 3 are electrically connected, after the semiconductor fine particles are applied to or printed on the transparent substrate 1 or the transparent electrode 2, to each other. Further, the porous electrode 3 is preferably baked in order to improve the mechanical strength of the porous electrode 3 and improve the adhesion properties thereof to the transparent substrate 1 or the transparent electrode 2. Although there is no particular limitation to the range of the baking temperature, in the case where the porous electrode 3 is formed on the transparent electrode 2, if the temperature is excessively raised, then the electric resistance of the transparent electrode 2 increases and the transparent electrode 2 may possibly be melted. Therefore, normally it is preferable for the temperature to be 40 to 700° C., and more preferable to be 40 to 650° C. Further, although there is no particular limitation to the baking time, usually it is approximately 10 minutes to 10 hours.

After the baking, a dipping process, for example, with aqueous solution of titanium tetrachloride or titanium oxide ultrafine particle sol of 10 nm or less in diameter may be carried out in order to increase the surface area of the semiconductor fine particle and raise the necking between the semiconductor fine particles. In the case where the transparent electrode 2 is formed, if a plastic substrate is used as the transparent substrate 1 for supporting the transparent electrode 2, then it is possible to form a film of the porous electrode 3 on the transparent electrode 2 using paste-like fluid dispersion which contains adhesive and contact bond the porous electrode 3 to the transparent electrode 2 by a heat press.

Thereafter, the transparent substrate 1 on which the porous electrode 3 is formed is immersed into solution containing photosensitizing dye dissolved in predetermined solvent to couple the photosensitizing dye to the porous electrode 3.

On the other hand, a transparent conductive layer and a counter electrode 5 are successively formed on a counter substrate 4 by sputtering or the like.

Then, the transparent substrate 1 and the counter substrate 4 are disposed such that the porous electrode 3 and the counter electrode 5 are opposed to each other in a spaced relationship by a predetermined distance, for example, by 1 to 100 μm, preferably by 1 to 50 μm, from each other. Then, a sealing material not shown is formed on an outer periphery of the transparent substrate 1 and the counter substrate 4 to produce a space in which an electrolyte layer 7 is to be filled. Then, electrolyte is injected into the space through an inlet not shown formed, for example, in advance in the transparent substrate 1 to form an electrolyte layer 7. Thereafter, the inlet is closed up.

In the case where the collecting wiring lines 8 are connected to each other to form an electrode, the collecting wiring lines 8 are suitably connected to each other by an aggregation wiring line or the like.

The intended dye-sensitizing photoelectric conversion device is fabricated by the process described above.

### Operation of the Dye-Sensitive Photoelectric Conversion Device

Now, operation of the dye-sensitizing photoelectric conversion device is described.

If light is incident to the dye-sensitizing photoelectric conversion device, then the dye-sensitizing photoelectric conversion device operates as a cell wherein the counter electrode 5 serves as the positive electrode and the transparent electrode 2 or a collecting wiring line 8 serves as the negative electrode. The principle in this instance is such as described below. It is to be noted here that it is assumed that aluminum (Al) is used as the material for the collecting wiring line 8; FTO as the material for the transparent electrode 2; TiO₂ as the material for the porous electrode 3; and oxidation and reduction species of I⁻/I₃⁻ are used as the redox couple. However, the materials are not limited to them. Further, it is assumed that one kind of photosensitizing dye is coupled to the porous electrode 3. Further, except a special case, it is assumed that, as light incident to the transparent substrate 1 or a light guiding structure 11, light generally approximated as collimated parallel light is introduced perpendicularly to the transparent substrate 1.

When photons of light transmitted through the transparent substrate 1 and partly introduced to the porous electrode 3 through a light guiding structure 11 are absorbed by the photosensitizing dye coupled to the porous electrode 3, electrons in the photosensitizing dye are excited from a base state (HOMO) to an excited state (LUMO). The electrons excited in this manner are extracted to the conduction band of TiO₂ which configures the porous electrode 3 through electric coupling between the photosensitizing dye and the porous electrode 3, pass through the porous electrode 3 and reach a collecting wiring line 8 or the transparent electrode 2.

On the other hand, the photosensitizing dye having lost the electrons receives electrodes from a reducer in the electrolyte layer 7, for example, from I⁻, by a reaction specified below to produce an oxidizer, for example, I₃⁻, which is an aggregate of I₂ and I⁻.

2I⁻→I₂+2e⁻

I₂+I⁻→I₃⁻

The oxidizer produced in this manner is diffused to reach the counter electrode 5 and receives electrons from the counter electrode 5 by a reverse reaction to the reaction described above so that it is reduced to the original reducer.

I₃⁻→I₂+I⁻

I₂+2e⁻→2I⁻

The electron sent out from the transparent electrode 2 or the collecting wiring line 8 to an external circuit carries out an electric work in the external circuit and thereafter returns to the counter electrode 5. In this manner, light energy is converted into electric energy without causing any change in the photosensitizing dye and the electrolyte layer 7.

### Working Example 1-1

The dye-sensitized photosensitive conversion device 10 was fabricated in the following manner.

First, a colorless and transparent glass plate is prepared and worked to form light guiding structures 11. Each of the light guiding structures 11 has such a shape that it is a straight post body having a pentagonal bottom face and extending perpendicularly from the bottom face. The bottom face of the light guiding structure 11 has a shape symmetrical with respect to a line wherein three of the five angles are 90 degrees and the remaining two angles are 135 degrees. The angle opposing to the side having the angle of 90 degrees at the opposite ends thereof is represented as the apex angle θₜ, and the width L₃ of the bottom face of the light guiding structure 11 is equal to the width L₁ of the collecting wiring lines 8. Further, where the depth of the collecting wiring line 8 is represented by L₆, in the light guiding structure 11 fabricated in the present working example, where L₃=0.4 mm, L₆=40 mm and θₜ=90°, the thickness L₄ is L₄=0.21 mm and the refractive index nₚ is nₚ=1.49. A detailed designing method of the light guiding structure 11 is hereinafter described.

Then, a colorless and transparent glass plate of 1.1 mm thick is cut out in a size of 40 mm in the longitudinal direction and 42.8 mm in the lateral direction to produce a transparent substrate 1.

Then, one principal surface of the transparent substrate 1 and a side face of the light guiding structure 11 opposing to the apex angle are joined together by fusion. Such seven light guiding structures 11 are provided at distances of 5 mm on the transparent substrate 1 such that the longitudinal direction of the light guiding structures 11 extends in parallel to the depthwise direction without protruding from the transparent substrate 1. It is to be noted that eight such distances of 5 mm are provided on the transparent substrate 1.

Then, a FTO layer which is a transparent conductive layer is formed by sputtering on a face of the transparent substrate 1 on the opposite side to the face on the light incidence side on which the light guiding structures 11 are provided to form a transparent electrode 2. Then, aluminum (Al) is vacuum deposited on the transparent electrode 2 to form collecting wiring lines 8. The collecting wiring lines have a pattern of straight post bodies having a rectangular bottom face of 0.4 mm wide and 10 μm thick and extending 40 mm in the depthwise direction. Seven such collecting wiring lines 8 are provided at distances of 5 mm on the transparent substrate 1 such that the center axes thereof in the widthwise direction coincide with the center axes of the light guiding structures 11. In the case where eight such collecting wiring lines 8 are provided at distances of 5 mm on the transparent substrate 1 and the light guiding structures 11 are not provided, the numerical aperture of the light incidence face of the dye-sensitized photosensitive conversion device 10 with respect to incidence light is 93.5%. Further, the surface of the collecting wiring lines 8 is oxidized by a thermal oxidization method or the like to form a collecting wiring line protective layer 9. The collecting wiring lines 8 are formed at such positions on the transparent electrode 2 on the opposite side to the light guiding structures 11 with respect to the transparent substrate 1 that the center axes of the bottom face of the collecting wiring lines 8 in the widthwise direction are positioned on the same straight lines with the symmetrical axes of the light guiding structures 11.

An example of a designing method of the light guiding structures 11 of the dye-sensitized photosensitive conversion device 10 according to the working example 1-1 is described below.

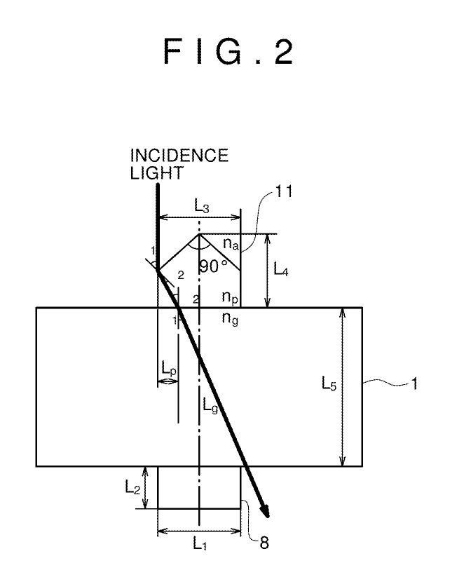

FIG. 2 shows a cross section of a light guide path when light is incident to one end portion of a light guiding structure 11 of the dye-sensitized photosensitive conversion device 10 according to the working example 1-1, and the light guide path of the incidence light is indicated by a thick line in FIG. 2.

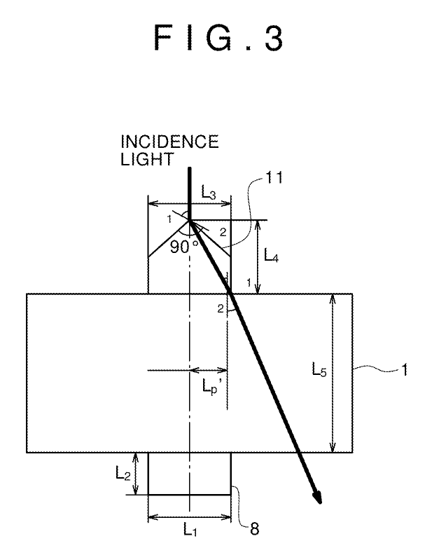

FIG. 3 illustrates a cross section of a light guide path when light is incident to the apex angle portion of a light guiding structure 11 of the dye-sensitized photosensitive conversion device 10 according to the working example 1-1, and the light guide path of the incidence line is indicated by a thick line in FIG. 3.

Referring first to FIG. 2, a light guiding structure 11 of the dye-sensitized photosensitive conversion device 10 in the present working example is a straight post body having a pentagonal bottom face and extending perpendicularly from the bottom face. The bottom face has a shape symmetrical with respect to a line wherein three of the five angles are 90° and the remaining two angles are 135°. The angle θ₁=90° sandwiched between the two angles of 135° is the apex angle.

Here, in the case where light approximated as generally collimated parallel light enters the transparent substrate 1 perpendicularly at one end portion of the light incidence side face of the light guiding structure 11 except the apex angle, if the width L₁ of the collecting wiring line 8 is L₁=0.4 mm, then in order to avoid blocking of the light guide path of light incident from the end portion of the light guiding structure 11 in the widthwise direction by the collecting wiring line 8, from the expression (4), the sum of the widthwise component Lₚ of the distance along the incidence light path in the light guiding structure 11 and the widthwise component L_{g} of the distance along the incidence light path in the transparent substrate 1 is made greater than 0.4 mm.

In particular, if light comes into one of the left and right end portions of the incidence face of the light guiding structure 11, then the incidence angle at an interface through which light enters the light guiding structure 11 from the air becomes θ₁=90°−(θₜ/2)=45°, and if the refractive index nₐ of the air is nₐ=1.00 and the refractive index nₚ of the light guiding structure 11 is nₚ=1.49, then the emergence angle θ₂ at an interface when light enters the light guiding structure 11 from the air becomes θ₂=28.3° from the expression (1) given hereinabove.

If the incidence angle at an interface when light enters the transparent substrate 1 from the light guiding structure 11 is represented by φ₁, the emergence angle by φ₂ and the refractive index n_{g} of the transparent substrate 1 is n_{g}=1.55, then the incidence angle φ₁=16.7° is obtained from the expression (3), and the emergence angle φ₂=16.0° is obtained from the expression (2).

Here, if the width and the thickness of the light guiding structure are represented by L₃ and L₄, respectively, and the thickness of the transparent substrate is represented by L₅, then the widthwise component Lₚ and the widthwise component L_{g} are represented by the following expressions (6) and (7), respectively:

$$\begin{matrix}{L}_{p} = ( {L}_{4} - \frac{{L}_{3}}{2} ) tan {φ}_{1} & ( 6 ) \\ {L}_{g} = {L}_{5} tan {φ}_{2} & ( 7 )\end{matrix}$$

From the expressions (6) and (7), the thickness L₄ and the thickness L₅ can be set, for example, to L₄=0.5 mm and L₅=1.1 mm, respectively. Consequently, since L₁=L₃=0.4 mm, Lₚ+L_{g}=0.41 mm, and this is greater than L₁=0.4 mm and the expression (4) is satisfied.

Further, in the present working example, if incidence of the parallel light to the apex angle portion of the light guiding structure 11 is considered, then since the incidence light becomes an inverted irradiation in the light guiding structure 11, it passes a light guide path which bypasses the collecting wiring line 8 by a greater amount. However, if the thickness L₄ of the light guiding structure 11 becomes excessively great, then the light is reflected by the vertical plan in the inside of the light guiding structure 11 and cannot be guided efficiently into the porous electrode 3. To avoid this, the expression (5) must be satisfied. In the design example of the present working example, the widthwise component Lₚ′ of the distance along the light path when the light passes the inside of the light guiding structure 11 becomes Lₚ′=L₄ tan φ₁=0.15 and satisfies Lₚ′=L₄ tan φ₁=0.15<0.2.

In this manner, if the value of the thickness L₄ of the light guiding structure 11 becomes high, then the problem of internal reflection in the light guiding structure 11 occurs. In order to cause this problem less likely to occur, the value of the widthwise component L_{g} of the distance along the light path when the light is guided by and passes the inside of the light guiding structure 11 must be made sufficiently high with respect to the value of the widthwise component Lₚ of the distance along the light path when the light is guided by and passes the inside of the light guiding structure 11.

Further, since the light guiding structure 11 in the present working example has a shape symmetrical with respect to a line and is installed on the transparent substrate 1 such that the center axis of the bottom face of the collecting wiring line 8 in the widthwise direction and the axis of the symmetry are positioned on the same straight line, blocking of the light guide path also of the light incident from the end portion on the opposite side to the end portion described above by the collecting wiring line 8 can be avoided similarly.

From the foregoing, in the light guiding structure 11 of the present working example, in the case where the apex angle θ₁ and the refractive index nₚ of the light guiding structure 11 are θₜ=90° and nₚ=1.49, respectively, and the refractive index n_{g} of the transparent substrate 1 is n_{g}=1.55, particularly in the case where the length of the width L₃ of the light guiding structure 11 is 0.4 mm equally to the width L₁ of the collecting wiring line 8, if the thickness L₄ of the light guiding structure 11 is L₄=0.5 mm and the thickness L₅ of the width L₁ is equal to or greater than 1.1 mm, then blocking of the light guide path of all of light incident to the incidence face of the light guiding structure 11 from a direction perpendicular to the transparent substrate 1 can be avoided.

In the present working example, the light guiding structure 11 is designed by setting, after the apex angle θₜ, the refractive index nₚ of the light guiding structure 11 and the refractive index n_{g} of the transparent substrate 1, the width L₃, thickness L₄ and thickness L₅ which satisfy the expressions (4) and (5) suitably. However, the design is not limited to this, but, for example, the light guiding structure 11 can be set by suitably setting the apex angle θₜ, refractive index nₚ and refractive index n_{g} after the width L₃, thickness L₄ and thickness L₅ are set.

On the other hand, when the thickness L₅ of the transparent substrate 1 is great such as, for example, when the thickness L₅ is equal to or greater than 1.4 mm, only by the widthwise component L_{g} of the distance along the light path when light is guided by and passes the inside of the transparent substrate 1, blocking of the light guide path by the collecting wiring line 8 can be avoided without depending upon the size of the light guiding structure 11. Therefore, the light guiding structure 11 is configured so as to contribute to change of the light guide path, and also it is possible to form the light guiding structure 11 in such a shape as, for example, a triangle pole which has a very low value of the thickness L₄. Further, in the case where the light guiding structure 11 in the present working example is designed, it is possible to set the thickness L₅ of the transparent substrate 1 in advance and then obtain a value φ₂ which satisfies the following expression:

$${φ}_{2} > {tan}^{- 1} \frac{{L}_{1} - \frac{{L}_{1} - {L}_{3}}{2} - {L}_{p}}{{L}_{5}} \qquad ( 8 )$$

to set the incidence angle θ1 and the apex angle θₜ with which blocking of the light guide path by the collecting wiring line 8 can be avoided without depending upon the size of the light guiding structure.

The paste-like fluid diffusion of TiO₂ which is a raw material when the porous electrode 3 is formed was prepared referring to Hironori ARAKAWA, “Latest Technology of Dye-Sensitized Solar Cells,” 2001, CMC. In particular, while titanium isopropoxide 125 ml was agitated at a room temperature, it was dripped gradually into nitric acid aqueous solution 750 ml of 0.1 M. After the dripping, the solution was transferred into a constant temperature oven of 80° C. and agitation was continued for 8 hours. As a result, clouded translucent sol solution was obtained. The sol solution was cooled to a room temperature and then filtrated by a glass filter, whereafter solvent was added to adjust the volume of the solution to 700 ml. The obtained sol solution was transferred to an autoclave and subjected to a hydrothermal reaction at 200° C. for 12 hours, whereafter an ultrasonic process was applied for one hour to carry out a decentralization process. Then, this solution was concentrated at 40° C. using an evaporator to adjust the solution so that the content of TiO₂ became 20 wt %. To this concentrated sol solution, polyethylene glycol (molar weight: 500,000) of a weight equal to 20% of the mass of TiO₂ and anatase type TiO₂ of a particle size of 200 nm of a weight equal to 30% of the mass of TiO₂ were added. Then, the sol solution was mixed uniformly by a stirring deforming machine thereby to obtain paste-like fluid diffusion of TiO₂ whose viscosity was increased.

The paste-like fluid diffusion of TiO₂ was applied to a FTO layer which forms the transparent electrode 2 and an aluminum oxide layer which forms the collecting wiring line protective layer 9 by blade coating to form a fine particle layer of a size of 5 mm×5 mm and a thickness of 200 μm. Thereafter, the TiO₂ fine particles were kept at 500° C. for 30 minutes so as to be sintered on the FTO layer. Titanium chloride (IV) TiC 14 aqueous solution of 0.1 M was dropped to the sintered TiO₂ film and then the resulting article was kept at a room temperature for 15 hours and then cleaned, whereafter it was subject to baking at 500° C. for 30 minutes again. Thereafter, an ultraviolet radiation irradiation apparatus was used to irradiate ultraviolet radiations on the TiO₂ sintered article for 30 minutes to carry out a process of oxidizing and decomposing impurities such as organic substances contained in the TiO₂ sintered article by a photocatalytic action of TiO₂ to remove the impurities thereby to raise the activity of the TiO₂ sintered article to obtain a porous electrode 3.

As the photosensitizing dye, sufficiently refined Z907 23.8 mg was dissolved into mixed solvent 50 ml obtained by mixing acetonitrile and tert-butanol at a volume ratio of 1:1 to a photosensitizing dye solution.

Thereafter, the porous electrode 3 was immersed for 24 hours at a room temperature in this photosensitizing dye solution so that the photosensitizing dye was held by the surface of the TiO₂ fine particles. Then, acetonitrile solution of 4-tert-butylpyridine and acetonitrile were successively used to clean the porous electrode 3, whereafter the solvent was evaporated at a dark place to dry the porous electrode 3.

The counter electrode 5 was formed by successively laminating a chromium layer of a thickness of 50 nm and a platinum layer of a thickness of 100 nm on the FTO layer in which an inlet of a diameter of 0.5 mm was formed in advance by sputtering, spray coating isopropyl alcohol (2-propanol) solution of chloroplatinic acid on the platinum layer and then heating the article at 85° C. for 15 minutes.

Then, the transparent substrate 1 and the counter substrate 4 were disposed such that the porous electrode 3 and the counter electrode 5 were opposed to each other, and the outer periphery of the transparent substrate 1 and the counter substrate 4 was sealed with an ionomer resin film of a thickness of 30 μm and an acrylic based ultraviolet curing resin.

Meanwhile, 1.0 g 1-propyl-3-methylimidazolium iodide, 0.10 g iodine and 0.054 g N-butyl benzimidazole (NBB) were dissolved in 2.0 g mixed solvent wherein EMImTCB and diglyme were mixed at a ratio by weight of 1:1.

This electrolyte was injected through the inlet of the dye-sensitized photoelectric conversion device prepared in advance using a feed pump and then decompressed to drive out air bulbs in the device. The electrolyte layer 7 is formed in this manner. Then, the inlet was sealed with an ionomer resin film, acrylic resin and a glass substrate thereby to complete a dye-sensitized photoelectric conversion device.

### Working Example 1-2

The light guiding structure 11 was formed as a post-like convex prism having an apex angle and having a bottom face symmetrical with respect to a line such that the width L₃ thereof is smaller than the width L₁ of the collecting wiring line 8, and the size of the light guiding structure 11 and the thickness of a transparent substrate 1 were determined based on the shape. Except the foregoing, the dye-sensitized photoelectric conversion device 10 in the present working example 1-2 was fabricated similarly to that of the working example 1-1.

An example of a designing method of the light guiding structure 11 of the dye-sensitized photoelectric conversion device 10 according to the working example 1-2 is described below.

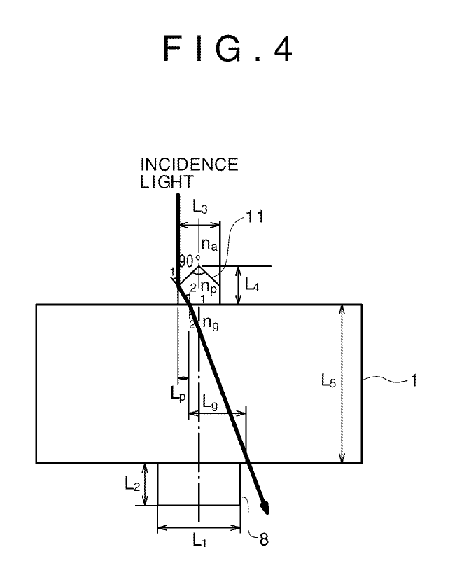

FIG. 4 shows a cross section of the light guiding structure 11 of the dye-sensitized photoelectric conversion device 10 according to the working example 1-2. A light guide path of incidence light is indicated by a thick line in FIG. 4.

Referring to FIG. 4, the light guiding structure 11 of the dye-sensitized photoelectric conversion device 10 according to the present working example is designed similarly as in the working example 1 such that it has a width L₃=0.2 mm and an apex angle θ₁=90°. The light path of light incident to the light guiding structure 11 is changed by refraction at an incidence interface between the air and the light guiding structure 11 and refraction at an incidence interface between the light guiding structure 11 and the transparent substrate 1, and the light is introduced into the porous electrode 3. At this time, the light guiding structure 11 is designed so that blocking of the light guide path by the collecting wiring line 8 provided on the transparent substrate 1 is avoided by the light path change by the refractions described above. As regards the installation position of the light guiding structure 11, since the bottom face of the light guiding structure 11 has a shape symmetrical with respect to a line, the light guiding structure 11 is installed on the face of the transparent substrate 1 on the light incidence side such that the axis of symmetry of the bottom face of the light guiding structure 11 is positioned on the same straight line as the center axis of the bottom face of the collecting wiring line 8 in the widthwise direction.

Here, if it is assumed that light is introduced into the light guiding structure 11 from a left end portion of the incidence face of the light guiding structure 11 and passes through the inside of the light guiding structure 11 and the transparent substrate 1, then, for example, if the thickness L₅ of the transparent substrate 1 is L₅=1.0 mm, then the widthwise component L_{g} of the distance along the light path when the light passes through the inside of the transparent substrate 1 is L_{g}=0.28 from the expression (7) and is smaller than L₁−(L₁−L₃)/2=0.3 mm derived from the expression (4). Therefore, the thickness L₄ or the light guiding structure 11 must be set. Therefore, from the expression (6), the thickness L₄ of the light guiding structure 11 which satisfies the expression (4) can be set to L₄=0.17+0.1=0.27 mm. Consequently, Lₚ+L_{g}=0.33 mm, which is greater than 0.3 mm, and the expression (4) is satisfied. Further, if reflection of the guided light in the light guiding structure 11 is studied, then the widthwise component Lₚ′ of the distance along the light path when the light passes through the inside of the light guiding structure 11 is Lₚ′=L₄ tan φ₁=0.08 mm<0.1, and the expression (5) is satisfied. Therefore, reflection on the vertical plane in the light guiding structure 11 never occurs.

Further, the light guiding structure 11 in the present working example has a shape symmetrical with respect to a line and is installed on the light incidence side face of the transparent substrate 1 such that the axis of symmetry of the bottom face is positioned on the same straight line as the center axis of the collecting wiring line 8 in the widthwise direction. Therefore, if the light guiding structure 11 is configured such that the width L₃ and the apex angle θₜ of the light guiding structure 11 are L₃=0.2 mm and θₜ=90°, respectively, the thickness L₄ of the light guiding structure 11 is L₄=0.17 mm and the refractive index nₚ of the light guiding structure 11 is nₚ=1.49, then also with regard to light incident from a right end portion of the incidence face, blocking of the light guide path by the collecting wiring line 8 can be avoided similarly.

From the foregoing, if, in the light guiding structure 11 of the dye-sensitized photoelectric conversion device 10 in the present working example, the thickness L₄ of the light guiding structure 11 is set to L₄=0.27 mm and the thickness L₅ of the transparent substrate 1 is set to L₅=1.0 mm, then with regard to all light incident in a perpendicular direction to the transparent substrate 1 to the incidence face of the light guiding structure 11, blocking of the light guide path by the collecting wiring line 8 can be avoided. Further, in the present working example, after the apex angle θₜ, refractive index nₚ of the light guiding structure 11 and refractive index n_{g} of the transparent substrate 1 are set, the light guiding structure 11 is designed by suitably setting the width L₃, thickness L₄ and thickness L₅ which satisfy the expressions (4) and (5). However, the designing method of the light guiding structure 11 is not limited to this. For example, also it is possible to design the light guiding structure 11 by suitably setting the apex angle θₜ, refractive index nₚ and refractive index n_{g} after the width L₃, thickness L₄ and thickness L₅ are set.

Further, in the case where the thickness L₅ of the transparent substrate 1 is great, for example, where L₅≧1.1 mm, since the expression (4) is satisfied only with the value of n_{g}, the light guiding structure 11 may contribute only to change of the light guide path, and blocking of the light guide path by the collecting wiring line 8 can be avoided without depending upon the thickness L₄ of the light guiding structure 11. Therefore, also it is possible to form the light guiding structure 11 in such a shape as, for example, a triangle pole which has a very low value of the thickness L₄. Further, in the case where the light guiding structure 11 in the present working example is designed, also it is possible to set, by setting the thickness L₅ in advance and then obtaining a value φ₂ which satisfies the following expression (8), the incidence angle θ₁ and the apex angle θₜ with which blocking of the light guide path by the collecting wiring line 8 can be avoided in accordance with the refractive index of each material and the thickness L₅ without depending upon the size of the light guiding structure.

### Working Example 1-3

The light guiding structure 11 was formed as a post-like convex prism having an apex angle and having a bottom face symmetrical with respect to a line, and the width L₃ was made greater than the width L₁ of the collecting wiring line 8. Then, based on this shape, the size of the light guiding structure 11 and the thickness of the transparent substrate 1 were determined. Except the foregoing, the dye-sensitized photoelectric conversion device 10 was fabricated in a similar manner as in the working example 1-1.

An example of a designing method of the light guiding structure 11 of the dye-sensitized photoelectric conversion device 10 according to the working example 1-3 is described below.

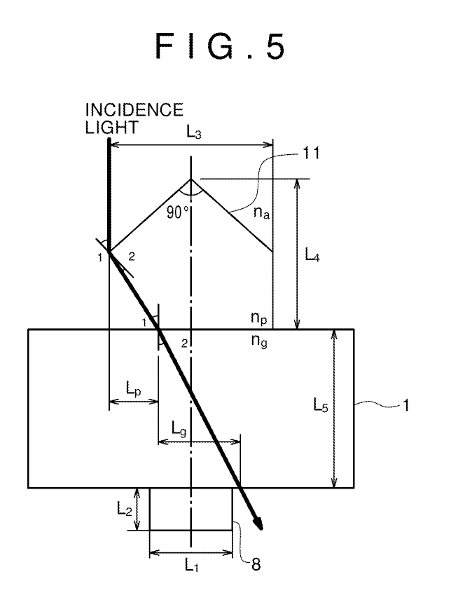

FIG. 5 shows a cross section of the light guiding structure 11 of the dye-sensitized photoelectric conversion device 10 according to the working example 1-3. A light guide path of incidence light is indicated by a thick line in FIG. 5.

Referring to FIG. 5, the light guiding structure 11 of the dye-sensitized photoelectric conversion device 10 according to the present working example is designed similarly as in the working example 1 such that it has a width L₃=0.6 mm and an apex angle θₜ=90°. The light path of light incident to the light guiding structure 11 is changed by refraction at an incidence interface between the air and the light guiding structure 11 and refraction at an incidence interface between the light guiding structure 11 and the transparent substrate 1, and the light is introduced into the porous electrode 3. At this time, the light guiding structure 11 is designed so that blocking of the light guide path by the collecting wiring line 8 provided on the transparent substrate 1 is avoided by the light path change by the refractions described above. As regards the installation position of the light guiding structure 11, since the bottom face of the light guiding structure 11 has a shape symmetrical with respect to a line, the light guiding structure 11 is installed such that the axis of symmetry of the bottom face of the light guiding structure 11 is positioned on the same straight line as the center axis of the bottom face of the collecting wiring line 8 in the widthwise direction.

Here, if it is assumed that light is introduced into the light guiding structure 11 from a left end portion of the incidence face of the light guiding structure 11 and passes through the inside of the light guiding structure 11 and the transparent substrate 1, then, for example, if the thickness L₅ of the transparent substrate 1 is L₅=1.0 mm, then the widthwise component L_{g} of the distance along the light path when the light passes through the inside of the transparent substrate 1 is L_{g}=0.28 from the expression (7) and is smaller than L₁−(L₁−L₃)/2=0.5 mm derived from the expression (4). Therefore, the thickness L₄ of the light guiding structure 11 is set. Therefore, from the expression (6), the thickness L₄ of the light guiding structure 11 which satisfies the expression (4) can be set to L₄=0.77+0.3=0.97 mm. Consequently, the widthwise component Lₚ of the distance along the light path when the light is guided by and passes through the inside of the light guiding structure 11 is Lp=0.23, and Lₚ+L_{g}=0.51 mm, which is greater than 0.5 mm. Consequently, the expression (4) is satisfied. Further, if reflection of the guided light in the light guiding structure 11 is studied, then the widthwise component Lₚ′ of the distance along the light path when the light passes through the inside of the light guiding structure 11 is Lₚ′=L₄ tan φ₁=0.29 mm<0.3, and the expression (5) is satisfied. Therefore, reflection on the vertical plane in the light guiding structure 11 never occurs.

Further, the light guiding structure 11 in the present working example is a post body having a shape symmetrical with respect to a line and having a bottom face and is installed on the transparent substrate 1 such that the center axis of the collecting wiring line 8 and the axis of symmetry is positioned on the same straight line. Therefore, if the light guiding structure 11 is configured such that the width L₃ and the apex angle θₜ of the light guiding structure 11 are L₃=0.6 mm and θₜ=90°, respectively, the thickness L₄ of the light guiding structure 11 is L₄=0.68 mm and the refractive index nₚ of the light guiding structure 11 is nₚ=1.49, then also with regard to light incident from an end portion of the incidence face on the opposite side to the end portion described above, blocking of the light guide path by the collecting wiring line 8 can be avoided similarly.

From the foregoing, if, in the light guiding structure 11 in the present working example, the thickness L₄ of the light guiding structure 11 is set to L₄=0.68 mm and the thickness L₅ of the transparent substrate 1 is set to L₅=1.1 mm or more, then with regard to all light incident in a perpendicular direction to the transparent substrate 1 to the incidence face of the light guiding structure 11, blocking of the light guide path by the collecting wiring line 8 can be avoided. Further, in the present working example, by suitably setting the width L₃, thickness L₄ and thickness L₅ which satisfy the expressions (4) and (5) after the apex angle θₜ, refractive index nₚ of the light guiding structure 11 and refractive index n_{g} of the transparent substrate 1 are set, the light guiding structure 11 is designed. However, the designing method of the light guiding structure 11 is not limited to this. For example, also it is possible to design the light guiding structure 11 by suitably setting the apex angle θₜ, refractive index nₚ and refractive index n_{g} after the width L₃, thickness L₄ and thickness L₅ are set.

Further, in the case where the value of the thickness L₅ of the transparent substrate 1 is high, for example, where L₅≧1.79 mm, blocking of the light guide path of light by the collecting wiring line can be avoided only with the widthwise component L_{g} of the distance along the light path when the light is guided by and passes through the inside of the transparent substrate 1. Therefore, the light guiding structure 11 may contribute only to the light path change. Therefore, also it is possible to form the light guiding structure 11 in such a shape as, for example, a triangle pole which has a very low value of the thickness L₄. Further, in the case where the light guiding structure 11 in the present working example is designed, also it is possible to set, by setting the thickness L₅ in advance and then obtaining a value φ₂ which satisfies the following expression (8), the incidence angle θ₁ and the apex angle θₜ with which blocking of the light guide path by the collecting wiring line 8 can be avoided without depending upon the size of the light guiding structure.

### Working Example 1-4

The light guiding structure 11 was formed as a post-like convex prism having an apex angle and having an asymmetrical bottom face, and based on this shape, the size and the installation position of the light guiding structure 11 and the thickness of the transparent substrate 1 were determined. Except the foregoing, the dye-sensitized photoelectric conversion device 10 was fabricated in a similar manner as in the working example 1-1.

An example of a designing method of the light guiding structure 11 of the dye-sensitized photoelectric conversion device 10 according to the working example 1-4 is described below.

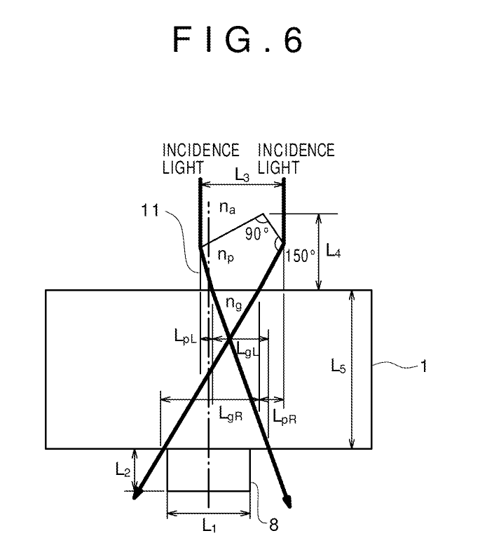

FIG. 6 shows a cross section of the light guiding structure 11 of the dye-sensitized photoelectric conversion device 10 according to the working example 1-4. A light guide path of incidence light is indicated by a thick line in FIG. 6.

Referring to FIG. 6, the light guiding structure 11 of the dye-sensitized photoelectric conversion device 10 according to the present working example is shaped such that the width L₃ and the apex angle θₜ are L₃=0.4 mm and θₜ=90°, respectively, and the apex angle θₜ is positioned such that a perpendicular to a side opposing to the apex angle θₜ divides the opposing side to 3:1. The light guide path of light incident to the light guiding structure 11 is changed by refraction at an incidence interface between the air and the light guiding structure 11 and refraction at an incidence interface between the light guiding structure 11 and the transparent substrate 1 such that the light is introduced into the porous electrode 3. At this time, the light guiding structure 11 is designed such that blocking of the light guide path by the collecting wiring line 8 is avoided by the light path change by the reflection. Further, since the light guiding structure 11 in the present working example is a post body having a leftwardly and rightwardly unsymmetrical shape, the light guiding structure 11 is designed independently with regard to light beams incident from the left and right end portions of the light incidence side face of the light guiding structure 11. Further, also the installation position of the light guiding structure 11 is set suitably since the shape of the bottom face of the light guiding structure 11 is unsymmetrical.

Here, if parallel light incident from the left end portion of the light incidence side face of the light guiding structure 11 is studied similarly as in the working example 1-1, then the incidence angle θ_{1L} on the left side of the apex portion of the light guiding structure 11 is θ_{1L}=60°, from the expression (1), the emergence angle θ_{1L}=35.5° is derived; from the expression (3), φ_{1L}=25.5° is derived; and from the expression (2), φ_{2L}=24.4° is derived. Therefore, from the expressions (6) and (7), the width L_{3L} of the light guiding structure 11 and the thickness L_{4L} of the light guiding structure 11 which satisfy the expression (4) become, for example, if the thickness L₅ of the transparent substrate 1 is L₅=1.0 mm, the widthwise component L_{gL} of the distance along the light path when light is guided by and passes through the inside of the transparent substrate 1 is L_{gL}=0.45. In the case where the light guiding structure 11 is positioned such that the center axis of the bottom face of the light guiding structure 11 and the center axis of the collecting wiring line 8 become the same, whatever size the light guiding structure 11 has, blocking of the light guide path of light incident from the left end portion of the light incidence side face of the light guiding structure 11 by the collecting wiring line 8 can be avoided.

Meanwhile, if light incident from a right end portion of the light incidence side face of the light guiding structure 11 is studied, then the incidence angle θ_{1R} on the right side of the apex portion of the light guiding structure 11 is θ_{1R}=30°, from the expression (1), the emergence angle θ_{2R}=19.6° is derived; from the expression (3), φ_{1R}=10.4° is derived; and from the expression (2), φ_{2R}=9.9° is derived. Therefore, from the expressions (6) and (7), the width L_{3R} of the light guiding structure 11 and the thickness L_{4R} of the light guiding structure 11 which satisfy the expression (4) become, for example, if the thickness L₅ of the transparent substrate 1 is L₅=1.0 mm, the widthwise component L_{gR} of the distance along the light path when light is guided by and passes through the inside of the transparent substrate 1 is L_{gR}=0.17. In the case where the light guiding structure 11 is positioned such that the center axis of the bottom face of the light guiding structure 11 and the center axis of the collecting wiring line 8 become the same, the light guide path cannot bypass the collecting wiring line 8. Therefore, the widthwise component L_{pR} is changed. If the light guiding structure 11 which can avoid blocking of the light guide path by the collecting wiring line 8 is designed from the expression (6), then the thickness L_{4R} of the light guiding structure 11 becomes L_{4R}=2.57+0.14=2.71 mm.

Now, it is studied whether or not the shape of the light guiding structure 11 according to the design described above satisfies the expression (5) and reflection of guided light in the light guiding structure 11 does not occur. If it is assumed that the widthwise component of the distance along the light path when light passes through the inside of the light guiding structure 11 is represented by L_{pL}′ and L_{pR}′ with regard to left and right incidence light beams. Thus, if the values given hereinabove are substituted into the expression (5), then L_{pL}′=L₄ tan φ_{1L}=1.27 mm and L_{pR}′=L₄ tan φ_{1R}′=0.59 mm, and since L_{pL}′=L₄ tan φ_{1L}<0.3 mm and L_{pR}′=L₄ tan φ_{1R}<0.1 mm are not satisfied from the expression (5), reflection occurs at a vertical plane in the light guiding structure 11.

Therefore, if it is assumed to set the center axis of the bottom face of the light guiding structure 11 to a position shifted by L₁−L_{gR}=0.23 mm to the right side from the center axis of the bottom face of the collecting wiring line 8, then light incident from the left end portion of the light incidence side face of the light guiding structure 11 must satisfy L_{pL}+L_{pR}>0.4+0.23=0.63 mm. Similarly, if the thickness L₅ of the transparent substrate 1 is L₅=1.0 mm, then L₄=0.40+0.14=0.54 mm is obtained from the expressions (6) and (7).

Meanwhile, light incident from a right end portion of the light incidence side face of the light guiding structure 11 must satisfy L_{pL}+L_{pR}>0.4−0.23=0.17 mm, and if L₄=0.54 mm, then L_{gL}+L_{pL}=0.24>0.17 is satisfied. Further, L_{pL}′=L₄ tan φ_{1L}=0.24 mm and L_{pR}′=L₄ tan φ_{1R}=0.095 mm, and therefore, L_{pL}′<0.3 mm and L_{pR}′<0.1 mm. Therefore, the expression (5) is satisfied. Consequently, reflection at a vertical plane in the light guiding structure 11 does not occur.

### Working Example 1-5

The light guiding structure 11 is a one-sided convex lens having a bottom face of a partially missing circular shape which is a circle part of which is cut away along a straight line and extending perpendicularly in the depthwise direction. The size and the installation position of the light guiding structure 11 and the thickness of the transparent substrate 1 were determined based on the shape just described. Except the foregoing, the dye-sensitized photoelectric conversion device 10 was fabricated in a similar manner as in the working example 1-1.

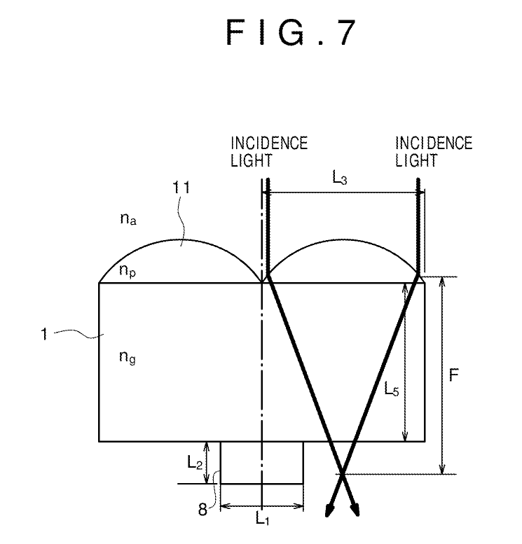

FIG. 7 shows a cross section of the light guiding structure 11 of the dye-sensitized photoelectric conversion device according to the working example 1-5, and a light guide path of incidence light is indicated by a thick line in FIG. 7.

Referring to FIG. 7, the light guiding structure 11 of the dye-sensitized photoelectric conversion device 10 according to the present working example is a straight post body lens of a one-sided type which is a straight post body having a bottom face of a partly missing circular shape which is a circle part of which is cut away along a straight line and extending perpendicularly from the bottom face.

An example of a designing method of the light guiding structures 11 of the dye-sensitized photoelectric conversion device 10 according to the present working 1-5 is described below.

Referring to FIG. 7, since each light guiding structure 11 of the dye-sensitized photoelectric conversion device 10 according to the present working example is a post body and has a bottom face of a partially missing circular shape which is a circle part of which is cut away along a straight line, light incident to the light guiding structure 11 is condensed by a lens effect. Then, the light passes through the transparent substrate 1 and enters the porous electrode 3. The light guiding structure 11 is designed such that, at this time, blocking of the light guide path by the collecting wiring line 8 is avoided by the condense of the light.

Therefore, if the refractive index of the light guiding structure 11 is represented by nₚ, the radius of the circle by R and the focal distance by F, then

$$F = \frac{R}{{n}_{p} - 1} \qquad ( 9 )$$

is satisfied.

Here, the collecting wiring line 8 is a straight post body having a rectangular bottom face of a width L₁=0.4 mm and a thickness L₂=10 μm and extending perpendicularly from the bottom face. Further, such collecting wiring lines 8 are provided at distances of 5 mm on the transparent substrate 1 and extend in parallel to the longitudinal direction of the transparent substrate 1. The light guiding structures 11 are juxtaposed without a gap left therebetween in the longitudinal direction of the transparent substrate 1 such that the end points of the light guiding structures 11 are positioned on the center axis of the bottom face of the collecting wiring line 8. By this, the length of the chord of the partly missing circle which is the width L₃ of the bottom face of the light guiding structure 11 can be made L₃=5.4 mm. Further, in order to avoid blocking of light incident to the light guiding structure 11 by the collecting wiring line 8 when the thickness of the transparent substrate 1 is set to 1.0 mm, if the thickness of the light guiding structure 11 is ignored for simplified studying, then when the focal length F of the light guiding structure 11 is 1 mm or more, the focal length F must be smaller than F which satisfies 0.4:1.0=5.4:F. On the other hand, if the focal length F is smaller than 1, then the focal length F must be greater than F which satisfies 5.2:1.01=5.4:2F. Consequently, the focal length F may be 0.53 mm≦F≦13.5 mm. For example, in the case where the focal length F is F=13.5 mm, if the refractive indexes of the transparent substrate 1 and the light guiding structure 11 are equal to each other and the value of them is nₚ=n_{g}=1.50 for simplified description, then the radium R becomes R=6.75 mm from the expression (9). Consequently, the shape of the light guiding structure 11 of the present working example is a post body having a bottom face of a partly missing circle which is a circle of the radium R=6.75 mm which is cut away with a straight line such that the chord becomes 5.4 mm and extending perpendicularly from the bottom face. The light guiding structure 11 is installed on the light incidence side face of the transparent substrate 1 such that the end points of the light guiding structure 11 in the widthwise direction are positioned on the center axis of the bottom face of the collecting wiring line 8.

### Comparative Example 1

The dye-sensitized photoelectric conversion device 10 was fabricated in a similar manner as in the working example 1-1 except that preparation of the light guiding structure 11 and the step of provision of the light guiding structure 11 were omitted.

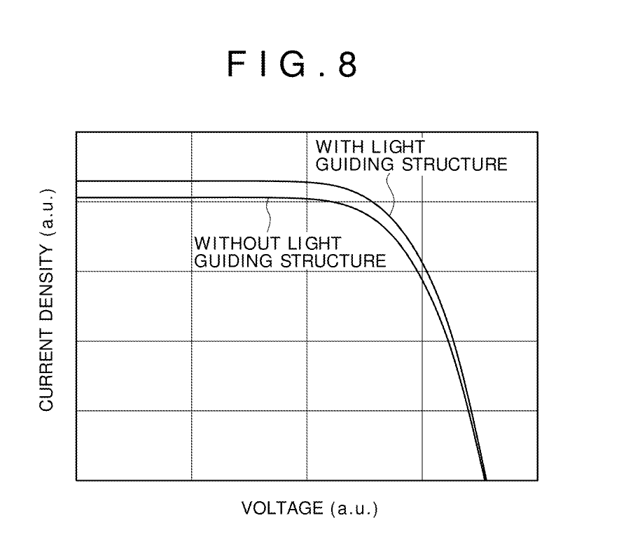

FIG. 8 illustrates a current-voltage characteristic of the dye-sensitized photoelectric conversion devices 10 according to the working example 1-1 and the comparative example 1.

Referring to FIG. 8, the current-voltage characteristic of the dye-sensitized photoelectric conversion device 10 of the working example 1-1 which includes the light guiding structures 11 is represented by “with light guiding structure” and the current-voltage characteristic of the dye-sensitized photoelectric conversion device 10 of the comparative example 1 which does not include the light guiding structures 11 is represented by “without light guiding structure.”

As seen in FIG. 8, the dye-sensitized photoelectric conversion device 10 of the working example 1-1 represented by “with light guiding structure” is improved in comparison with the dye-sensitized photoelectric conversion device 10 of the comparative example 1 represented by “without light guiding structure” in terms of both of the current characteristic and the voltage characteristic. The photoelectric conversion efficiency of the dye-sensitized photoelectric conversion device 10 of the working example 1-1 indicates an increase by 0.53% in comparison with that of the dye-sensitized photoelectric conversion device 10 of the comparative example 1. This coincides very much with a theoretical value (increase by 0.66%) when the photoelectric conversion efficiency is calculated regarding the numerical aperture of the dye-sensitized photoelectric conversion device 10 wherein the numerical aperture of the light incidence face with respect to incidence light is 93.5% as 100%. It was considered that the numeral aperture of the light incidence face of the dye-sensitized photoelectric conversion device 10 of the working example 1-1 with respect to incidence light become a value proximate to 100% owing to the light guiding structure 11, and the effect of the light guiding structure 11 in the present working example was demonstrated.

As described above, according to the present first embodiment, the collecting wiring lines 8 having the collecting wiring line protective layer 9 are provided at predetermined intervals on the transparent substrate 1 or the transparent electrode 2 of the dye-sensitized photoelectric conversion device 10, and the light guiding structures 11 are provided corresponding to the collecting wiring lines 8 on the light incidence side face of the transparent substrate 1. Therefore, energy loss when electrons generated in the porous electrode 3 are to be extracted to the outside through the collecting wiring lines 8 can be reduced. Further, since light incident from the light incidence side face of the dye-sensitized photoelectric conversion device 10 can be guided efficiently into the porous electrode 3 by the light guiding structures 11 without being blocked by the collecting wiring lines 8, the utilization efficiency of the incidence light is high. Further, the photoelectric conversion device can achieve a superior photoelectric conversion characteristic.

### Dye-Sensitized Photoelectric Conversion Device

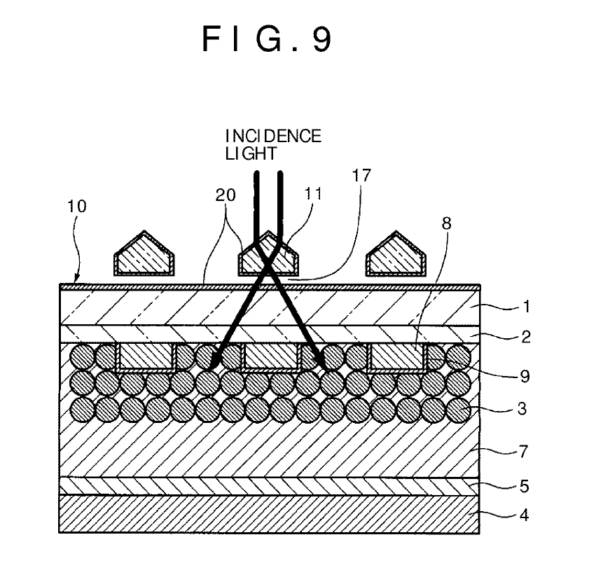

FIG. 9 shows a cross section of an essential part of a dye-sensitized photoelectric conversion device 10 according to a modification to the first embodiment, and a light guide path of incidence light is indicated by a thick line in FIG. 9.

Referring to FIG. 9, in the dye-sensitized photoelectric conversion device 10, the light guiding structures 11 are not provided on the transparent substrate 1 but provided above the light incidence side face of the transparent substrate 1. Each light guiding structure 11 is preferably provided in such a form that one principal surface of the light guiding structure 11 and one principal surface of the transparent substrate 1 are opposed in a predetermined spaced relationship from and in parallel to each other. An open space is formed between the principal surface of the light guiding structure 11 and the principal surface of the transparent substrate 1. The open space is filled with gas to form a gas layer.

While the gas layer typically is an air layer 17, it is not limited to this. Further, a multi-stage structure may be applied wherein a light guiding structure is provided above the light guiding structure 11 with a second gas layer interposed therebetween. Where the multi-stage structure is applied, basically the newly provided light guiding structure may be any light guiding structure only if it is colorless and transparent and superior in a transmitting property of light therethrough and can change the light guide path of incidence light. The newly provided light guiding structure may thus have a convex shape or a concave shape. Also as regards installation of such light guiding structures 11, the number and the installation method of the light guiding structures to be installed may be any number and any installation method only if the light guiding structures 11 can avoid blocking of the light guide path by the collecting wiring lines 8.

Further, since the principal surface of the light guiding structure 11 and the principal surface of the transparent substrate 1 are spaced from each other, the distance between them is set such that the shortest distance between the principal surfaces preferably is within the range of 1 μm to 10 mm, more preferably within the range of 1 μm to 1 mm, and most preferably within the range of 1 μm to 500 μm. However, the installation form of and the installation distance between the light guiding structures 11 are not limited to them. Also after the installation of the light guiding structures 11, the installation form and the distance can be changed suitably, and particularly can be changed through movement, rotation, removal, exchange or the like. Particularly in such a case that the angle of light to be incident to the light guiding structures 11 varies, blocking of the light path by the collecting wiring lines 8 can be avoided by rotating and/or moving the light guiding structures 11 so as to be ready for the angle of the incidence light.

Further, the light guiding structures 11a which are provided above the light guiding structures 11 when the light guiding structures 11 are formed in a multi-stage structure are preferably provided on the transparent substrate 1 such that, particularly in case where the light guiding structures 11a have a post shape and have a bottom face having a symmetrical shape with respect to a line, the center axes of the collecting wiring lines 8 in the widthwise direction, the axes of symmetry of the bottom faces of the light guiding structures 11 and the axes of symmetry of the bottom faces of the light guiding structures 11a are positioned on the same straight lines. However, the shape and the installation of the light guiding structures 11a are not limited to those described above.

Further, the shape of the light guiding structures 11 is not limited to that described hereinabove in connection with the first embodiment. However, since it is not a prerequisite that the light guiding structures 11 are installed on the transparent substrate 1, the faces of the light guiding structures 11 which oppose to the transparent substrate 1 upon installation need not be formed as flat faces. Therefore, the light guiding structures 11 may have basically any shape only if light incident to the light guiding structures 11 passes through the transparent substrate 1 and can most efficiently reach the inside of the porous electrode 3 avoiding blocking of the light guide path thereof by the collecting wiring line 8, and may have a cylindrical shape or a circular conical shape. As regards the size of the light guiding structures 11, although the width of the collecting wiring lines 8 is preferably made equal to the width of the light guiding structures 11, the shape and the size of the light guiding structures 11 are not limited to them.

Except the foregoing, the dye-sensitized photoelectric conversion device 10 according to the present modification is similar to the dye-sensitized photoelectric conversion device 10 according to the first embodiment.

### Fabrication Method of the Dye-Sensitized Photosensitive Conversion Device

Now, a fabrication method of the dye-sensitized photoelectric conversion device 10 according to the modification is described.

First, a glass material is worked and molded into a desired shape to form light guiding structures 11. For the formation of the light guiding structures 11, one of known techniques can be selectively used suitably. For example, casting, cutting, molding and injection molding are available. However, the formation method of the light guiding structures 11 is not limited to them.

Then, a transparent conductive layer is formed on one principal surface of a transparent substrate 1 by sputtering or the like to form a transparent electrode 2. Where the collecting wiring lines 8 are to be connected to each other to form an electrode, the step just described is omitted.

Then, aluminum (Al) is vacuum deposited in a desired pattern on the transparent electrode 2 to form collecting wiring lines 8. Further, the surface of the collecting wiring lines 8 is oxidized by a thermal process, an electric process or a chemical process to form a collecting wiring line protective layer 9.

Then, light guiding structures 11 are provided in a corresponding relationship to the collecting wiring lines 8 and independently of the dye-sensitized photoelectric conversion device 10 above the light incidence side face of the transparent substrate 1 which is the opposite side face of the transparent substrate 1 to the face on which the transparent electrode 2 is provided. The installation method of the light guiding structures 11 can be selected suitably from among known techniques and may be, for example, adhesion, contact bonding, sandwiching or fitting. However, the installation method is not limited to them.

Except the foregoing, the fabrication method of the dye-sensitized photoelectric conversion device 10 according to the modification is similar to the fabrication method of the dye-sensitized photoelectric conversion device 10 according to the first embodiment.

### Operation of the Dye-Sensitized Photosensitive Conversion Device

Now, operation of the dye-sensitized photosensitive conversion device according to the modification is described.

Light introduced into the dye-sensitized photoelectric conversion device 10 through the light incidence side face partly passes through the light guiding structures 11 and the air layer and then through the transparent substrate 1 and reaches the porous electrode 3.

Except the foregoing, the operation of the dye-sensitized photoelectric conversion device 10 according to the modification is similar to the operation of the dye-sensitized photoelectric conversion device 10 according to the first embodiment.

### Working Example 1-6

The light guiding structures 11 were each formed as a convex prism of a post-like shape which has a bottom face having an apex angle and symmetrical with respect to a line and are provided at a predetermined distance from the transparent substrate 1 such that the center axes of the collecting wiring lines 8 in the widthwise direction and the axes of symmetry of the bottom faces of the light guiding structures 11 were positioned on the same straight lines in such a form that side faces of the light guiding structures 11 opposing to the apex angles and the light incidence side face of the transparent substrate 1 were opposed in parallel to each other. Further, the size and the installation positions of the light guiding structures 11 and the thickness of the transparent substrate 1 were determined. Except the foregoing, the dye-sensitized photoelectric conversion device 10 according to the working example 1-6 was fabricated similarly as in the case of the working example 1-1.

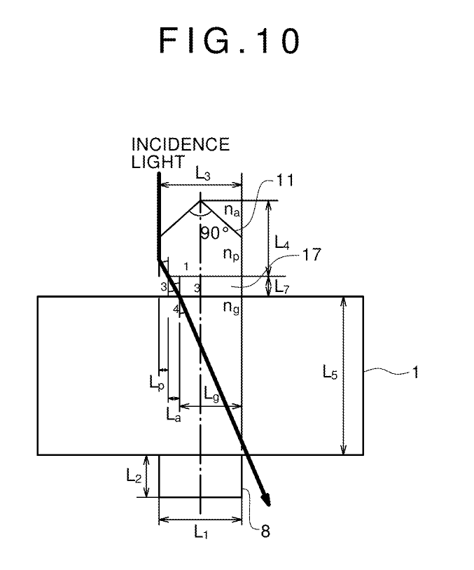

FIG. 10 shows a cross section of a light guiding structure 11 of the dye-sensitive photoelectric conversion device according to the working example 1-6, and a light guide path of incidence light is indicated by a thick line in FIG. 10.

Referring to FIG. 10, as the light guiding structure 11 provided in the dye-sensitized photoelectric conversion device 10 of the present working example, a light guiding structure similar to that designed in the working example 1-1 is used. In particular, the light guiding structure 11 is a straight post body having a bottom face of a pentagonal shape and extending perpendicularly from the bottom face. The bottom face has a shape symmetrical with respect to a line wherein three of the five angles of the pentagonal shape are 90 degrees and the remaining two angles are 135 degrees. The angle sandwiched between the two angles of 135° is the apex angle θₜ=90°. The light guiding structure 11 is provided in such a form that a side face thereof opposing to the apex angle θₜ and a face of the transparent substrate 1 on the side to which light is incident are opposed in parallel to each other and in a predetermined spaced relationship from each other. An air layer 17 is formed between the light guiding structure 11 and the transparent substrate 1.

Light incident to the light guiding structure 11 is refracted successively by an incidence interface between the light guiding structure 11 and the air, an incidence interface between the light guiding structure 11 and the air layer 17 and an incidence interface between the air layer 17 and the transparent substrate 1 thereby to change the light path thereof. Then, the light passes through the transparent substrate 1 and is introduced into the porous electrode 3. At this time, the light guiding structure 11 must be designed such that blocking of the light guide path by the collecting wiring line 8 provided on the transparent electrode 2 can be avoided by the change of the light guide path by the refractions. As regards the installation of the light guiding structure 11, since the bottom face of the light guiding structure 11 has a shape symmetrical with respect to a line, the light guiding structure 11 is installed on the transparent substrate 1 such that the center axis of the collecting wiring line 8 in the widthwise direction and the axis of symmetry of the bottom face are positioned on the same straight line.

An example of a designing method of the light guiding structure 11 of the dye-sensitized photoelectric conversion device 10 according to the working example 1-6 is described below.

The light guiding structure 11 of the dye-sensitized photoelectric conversion device 10 according to the present working example is designed similarly as in the working example 1-1, and the bottom face of the light guiding structure 11 has a shape symmetrical with respect to a line such that the width L₃ is L₃=0.4 mm, the thickness L₄ is L₄=0.5 mm and the apex angle θₜ is θₜ=90°. The light guiding structure 11 is a straight post body extending in a direction perpendicular to the bottom face.

Here, if it is assumed that parallel light is incident from a direction perpendicular to the transparent substrate 1 to a left end portion of the incidence face of the light guiding structure 11, then the light enters the transparent substrate 1 from the light guiding structure 11 through the air layer 17. Therefore, representing the thickness of the air layer 17 by L₇, also the light guide path in the air layer 17 must be taken into consideration.

Therefore, if the refractive index of the air is represented by nₐ, the refractive index of the light guiding structure 11 by nₚ, the incidence angle at the interface at which light is incident to the light guiding structure 11 from the air by θ₁, and the emergence angle by θ₂, then the expression (1) is satisfied from the Snell's law.

Further, if the incidence angle at the interface at which light is incident to the air layer 17 from the light guiding structure 11 is represented by φ₁ and the emergence angle is represented by φ₃, then the following expression:

n₉ sin φ₁=nₐ sin θ₃ (10)

is satisfied from the Snell's law.

Further, at this time, the incidence angle φ₁ satisfies the expression (3).

Further, since the light guiding structure 11 and the transparent substrate 1 are installed in parallel to each other, also the incidence face and the emergence face of the light through the air layer 17 extend in parallel to each other, and the incidence angle at the interface at which light is incident to the transparent substrate 1 from the air layer 17 is φ₃. If the emergence angle is represented by φ₄ and the refractive index of the transparent substrate 1 is represented by n_{g}, then the following expression:

nₐ sin φ₃=n_{g} sin φ₄ (11)

is satisfied from the Snell's law.

Here, in the case where the light guiding structure 11 is provided in a predetermined spaced relationship above the transparent substrate 1 such that the side face of the light guiding structure 11 opposing to the apex angle and the face of the transparent substrate 1 on the side to which light is incident are opposed in parallel to each other, if the widthwise component of the distance along the light guide path when light incident from an end face in the widthwise direction of the light guiding structure 11 passes through the inside of the light guiding structure 11 is represented by Lₚ, the widthwise component of the distance along the light path when the light passes through the inside of the air layer 17 is represented by Lₐ and the widthwise component of the distance along the light path when the light passes through the inside of the transparent substrate 1 is represented by L_{g}, then in order to avoid blocking of the light guide path of the incidence light by the collecting wiring line 8, the following expression:

$${L}_{1} - \frac{{L}_{1} - {L}_{3}}{2} < {L}_{p} + {L}_{a} + {L}_{g} \qquad ( 12 )$$

is satisfied. In particular, the width L₁ and the thickness L₂ of the collecting wiring line 8, the width L₃ and the thickness L₄ of the light guiding structure 11, the thickness L₇ of the air layer 17, the thickness L₅ of the transparent substrate 1, the refractive index nₚ of the light guiding structure 11, the refractive index n_{g} of the transparent substrate 1, the apex angle θ₁ at the interface at which light is incident to the light guiding structure 11 and the installation position of the light guiding structure 11 are determined suitably.

In the present working example, since the apex angle θₜ of the light guiding structure 11 is θₜ=90°, the incident angle θ₁ becomes θ₁=45°, and if the refractive index of the air is nₐ=1.00 and the refractive index of the light guiding structure 11 is nₚ=1.49, then from the expression (1), the emergence angle θ₂ at the interface at which light is incident to the light guiding structure 11 from the air is θ₂=28.3°.

Then, if the incidence angle at the interface at which light is incident to the air layer 17 from the light guiding structure 11 is represented by φ₁ and the emergence angle is represented by φ₃, then φ₁=16.7° is obtained from the expression (3) and φ₄=16.1° is obtained from the expression (10).

Then, if the incidence angle at the interface at which light is incident to the transparent substrate 1 from the air layer 17 is represented by φ₃ and the refractive index of the transparent substrate 1 is represented by n_{g}, then φ₄=16.1° is obtained from the expression (11).

Here, if the width and the thickness of the light guiding structure 11 are represented by L₃ and L₄, respectively, the thickness of the air layer 17 by L₇ and the thickness of the transparent plate including the transparent electrode 2 is represented by L₅, then the widthwise component Lₚ of the distance along the light guide path when the light passes through the inside of the light guiding structure 11 is derived from the expression (6). Further, the widthwise component Lₐ of the distance along the light path when the light passes through the inside of the air layer 17 and the widthwise component L_{g} of the distance along the light path when the light passes through the inside of the transparent substrate 1 are derived from the following expressions (13) and (14), respectively:

Lₐ=L₇ tan θ₃ (13)

L_{g}=L₅ tan θ₄ (14)

Here, if the thickness L₅ of the transparent substrate is set to L₅=1.0 mm, then L_{g}=0.28 mm is obtained from the expression (14), and in order to satisfy the expression (12), the widthwise component Lₐ and the widthwise component Lₚ must be set. Here, since the widthwise component Lₚ is Lₚ=0.09 mm from the expression (6), the widthwise component Lₐ is equal to or greater than 0.03 mm. The thickness L₇ of the air layer 17 which satisfies this is greater than 0.07 mm from the expression (14).

Further, if the thickness L₅ of the transparent substrate is set to L₅=0.5 mm, then the widthwise component L_{g}=0.14 mm is obtained from the expression (14). Here, since the widthwise component Lₚ is Lₚ=0.09 mm from the expression (6), in order to make the widthwise component Lₐ greater than 0.17 mm, the thickness L₇ of the air layer 17 is greater than 0.36 mm from the expression (14).

Further, while the light guiding structure 11 satisfies the expression (5), since the light guiding structure 11 similar to that in the working example 1-1 is used, it is apparent that the expression (5) is satisfied.

Further, while, in the present working example, the method of setting the shape and the size of the light guiding structure 11 and the thickness L₅ of the transparent substrate 1 in advance and determining the installation position of the light guiding structure 11 in a corresponding relationship is selected, the method is not limited to this. In particular, also it is possible to set the installation position in advance and then determine the shape and the size of the light guiding structure 11 and so forth so as to satisfy the expressions (12) and (5).

### Working Example 1-7

Each light guiding structure 11 is formed as a convex prism of a post shape which has a bottom face having an apex angle and symmetrical with respect to a line and is provided in a predetermined spaced relationship from the transparent substrate 1 such that the center axis of a collecting wiring line 8 in the widthwise direction and the axis of symmetry of the bottom face of the light guiding structure 11 are positioned on the same straight line in a state in which the apex angle of the light guiding structure 11 and the light incoming side face of the transparent substrate 1 are opposed to each other. Further, a light guiding structure 11a having a same shape as that of the light guiding structure 11 is provided above the light guiding structure 11 such that a face of the light guiding structure 11 opposing to the apex angle and a face of the light guiding structure 11a opposing to the apex angle are opposed to each other. Further, the light guiding structures 11 and 11a are provided such that the axes of symmetry of the bottom faces thereof are positioned on the same straight line on which the center axis of the bottom face of the collecting wiring line 8 in the widthwise direction and the center axis of the bottom face of the light guiding structure 11 are positioned. The size and the installation position of the light guiding structure 11 and the thickness of the transparent substrate 1 were determined based on this state. Except the foregoing, the dye-sensitized photoelectric conversion device 10 was fabricated in a similar manner as in the working example 1-1.

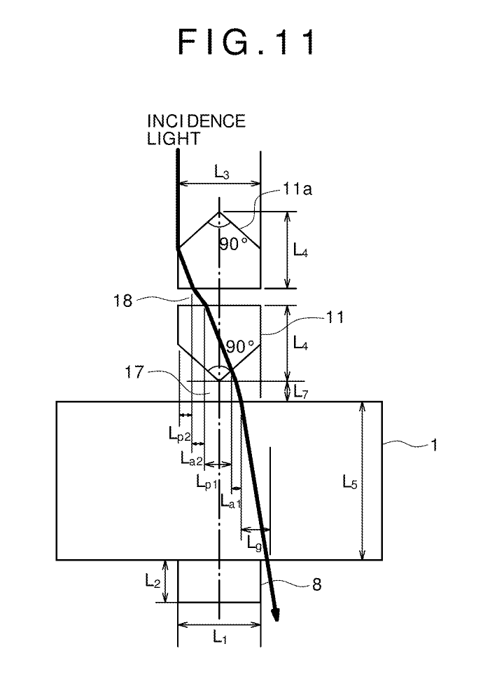

FIG. 11 shows a cross section of a light guiding structure 11 of the dye-sensitive photoelectric conversion device according to the working example 1-7, and a light guide path of incidence light is indicated by a thick line in FIG. 11.

Referring to FIG. 11, as the light guiding structure 11 provided in the dye-sensitized photoelectric conversion device 10 of the present working example, a light guiding structure similar to that used in the working example 1-1 is used. In particular, the light guiding structure 11 is a straight post body having a bottom face of a pentagonal shape and extending perpendicularly from the bottom face. The bottom face has a shape symmetrical with respect to a line wherein three of the five angles of the pentagonal shape are 90 degrees and the remaining two angles are 135 degrees. The angle sandwiched between the two angles of 135° is the apex angle θₜ=90°. The light guiding structure 11 is provided in a predetermined spaced relationship from the transparent substrate 1 in a form wherein the apex angle of the light guiding structure 11 and the face of the transparent substrate 1 to which light is incident are opposed to each other. The light guiding plate 11a provided above the light guiding plate 11 is same in shape and size with the light guiding structure 11. The light guiding structure 11a is provided such that, in a state in which the face of the light guiding structure 11 opposing to the apex angle and the face of the light guiding structure 11a opposing to the apex angle are opposed to each other, the axes of symmetry of the bottom faces of the light guiding structures 11 and 11a and the center axis of the bottom face of the collecting wiring line are common to each other.

An air layer 17 and a second air layer 18 are formed between the light guiding structure 11a and the light guiding structure 11 and between the light guiding structure 11 and the transparent substrate 1, respectively. Light incident to the light guiding structure 11a is successively refracted by an incidence interface between the light guiding structure 11a and the air, an incidence interface between the light guiding structure 11a and the second air layer 18, an incidence interface between the second air layer 18 and the light guiding structure 11, an incidence interface between the light guiding structure 11 and the air layer 17 and an incidence interface between the air layer 17 and the transparent substrate 1 such that it is guided into the porous electrode 3 through the transparent electrode 2. The light guiding structures 11 and 11a must be designed such that, at this time, blocking of the light guide path by the collecting wiring line 8 provided on the transparent electrode 2 is avoided by the change of the light path by the refractions. As regards the installation position of the light guiding structure 11, since the bottom face of the light guiding structure 11 has a shape symmetrical with respect to a line, the light guiding structure 11 is installed on the transparent substrate 1 such that the center axis of the bottom face of the collecting wiring line 8 in the widthwise direction and the axis of symmetry of the bottom face of the light guiding structure 11 are positioned on the same straight line. At this time, if at least one of the light guiding structures 11 and 11a does not have a shape symmetrical with respect to a line, the installation position in the horizontal direction must be set.

A designing method of the light guiding structure 11 of the dye-sensitized photoelectric conversion device 10 according to the present working example is determined by suitably combining the designing methods of the working examples described above.

In the working example, if the widthwise component of the distance along the light path when parallel light incident from an end face of the light guiding structure 11a in the widthwise direction passes through the inside of the light guiding structure 11 is represented by Lₚ₁, the widthwise component of the distance along the light path when the light passes through the inside of the air layer 17 by Lₐ₁, the widthwise component of the distance along the light path when the light passes through the inside of the light guiding structure 11a by Lₚ₂, the widthwise component of the distance along the light path when the light passes through the inside of the second air layer 18 by Lₐ₂, and the widthwise component of the distance along the light path when the light passes through the inside of the transparent substrate 1 by L_{g}, then in order to avoid blocking of the light guide path of the incidence light by the collecting wiring line 8, the following expression:

$${L}_{1} - \frac{{L}_{1} - {L}_{3}}{2} < {L}_{p 1} + {L}_{a 1} + {L}_{p 2} + {L}_{a 2} + {L}_{g} \qquad ( 15 )$$

is satisfied. Thus, the width L₁ and the thickness L₂ of the collecting wiring line 8, the width L₃ and the thickness L₄ of the light guiding structure 11, the thickness L₇ of the air layer 17, the widthwise component L₈ of the second air layer 18, the thickness L₅ of the transparent substrate 1, the refractive index nₚ of the light guiding structure 11, the refractive index n_{g} of the transparent substrate 1, the incidence angle θ₁ at the interface at which light is incident to the light guiding structure 11 and the installation position of the light guiding structure 11 are determined suitably so that the expression (15) and the expression (4) for avoiding reflect in the inside of the light guiding structure 11 are satisfied.

In this manner, with the modification to the first embodiment, the following advantages can be achieved in addition to advantages similar to those by the first embodiment. In particular, since the light guiding structures 11 and/or 11a are not installed fixedly on the transparent substrate 1, the installation position of each light guiding structure 11 and/or 11a can be changed readily and simply. Further, by suitably selecting the installation positions and the installation forms of the light guiding structures 11 and 11a in response to the form of the collecting wiring lines 8, the necessity to design the light guiding structures 11 newly in response to the form of the collecting wiring line 8 is eliminated.

Further, by changing the installation position of the light guiding structures 11 and/or 11a, it is possible to cope with incidence light from various angles. Further, since the light guiding structures 11 and/or 11a can be moved in response to the incidence direction or position of light, also in the case where the incidence direction or position of light varies together with time, it is possible to always keep a maximum numerical aperture of the light incidence face of the dye-sensitized photoelectric conversion device 10.

Further, since the light guiding structures 11 and/or 11a are installed in a predetermined spaced relationship from the transparent substrate 1, the air layer 17 is formed between the light guiding structure 11 and the transparent substrate 1 and the second air layer 18 is formed between the light guiding structure 11 and the light guiding structure 11a. Thus, by assuring a great distance for the light guide path in the air layer 17 and/or the second air layer 18, there is no necessity to make the thickness of the transparent substrate 1 excessively great or make the light guiding structure 11 excessively great in order to avoid blocking of the light guide path of the incidence light by the collecting wiring line 8.

Further, since the light guiding structures 11 are provided independently of the dye-sensitized photoelectric conversion device 10, even when a light guiding structure 11 is broken or damaged, only it is necessary to exchange the light guiding structure 11, and reduction of the cost can be achieved.

Further, by adopting a multi-stage structure wherein additional light guiding structures are provided above the light guiding structures 11, the light guide path can be designed suitably by combining light guiding structures of various forms. Consequently, also in a case in which the dye-sensitized photoelectric conversion device 10 is installed at a place at which lighting can be carried out only in a local region or a like place, the numerical aperture of the light incidence face of the dye-sensitized photoelectric conversion device 10 can be maintained at a high value.

### 2. Second Embodiment

### Dye-Sensitized Photoelectric Conversion Device

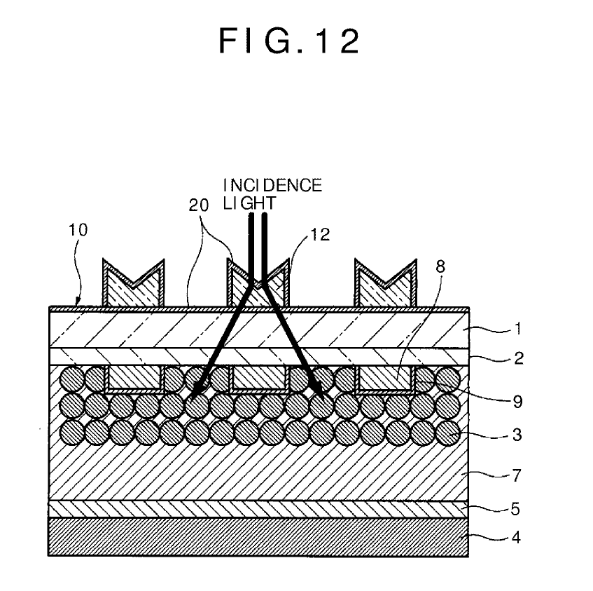

FIG. 12 shows a cross section of an essential part of a dye-sensitized photoelectric conversion device 10 according to a second embodiment and a light guide path of incidence light is indicated by a thick line in FIG. 12.

Referring to FIG. 12, a light guiding structure 12 having a concave three-dimensional shape is provided on a face of the dye-sensitized photoelectric conversion device 10 on the light incidence side.

Except the foregoing, the dye-sensitized photoelectric conversion device 10 according to the second embodiment is similar to the dye-sensitized photoelectric conversion device 10 according to the first embodiment.

The light guiding structure 12 may be basically any structure only if it has a concave three-dimensional shape, is colorless and transparent and can change the light guide path of incidence light. The light guiding structure 12 is configured by suitably selecting any of the materials mentioned hereinabove and configured as a post body having a bottom face preferably of a shape symmetrical with respect to a line. However, the shape of the light guiding structure 12 is not limited to this but may be an asymmetrical shape or may be a polyhedral shape or the like. Further, such light guiding structures 12 are provided on the light incidence side face of the transparent substrate 1 and preferably provided along collecting wiring lines 8 provided on the face of the transparent substrate 1 on the opposite side to the light incidence side face. The light guiding structures 12 are provided most preferably such that the center axes of the bottom faces of the collecting wiring lines 8 in the widthwise direction and the center axes of the bottom faces of the light guiding structures 12 in the widthwise direction are positioned on the same straight lines. However, the installation of the light guiding structures is not limited to them. In particular, the transparent substrate 1 may be worked to provide recessed faces on the transparent substrate 1 such that the transparent substrate 1 itself serves as the light guiding structures 12. Particularly in the case of a shape wherein a vertical section of the recessed faces has a shape symmetrical with respect to a line, it is preferable to configure each light guiding structure such that the center axis of the bottom face of the collecting wiring line 8 in the widthwise direction and the axis of symmetry of the concave face are positioned on the same straight line.

Further, the shape of the light guiding structure 12 is designed and selected suitably depending not only on the factors described above but also on the installation position of the light guiding structure 12, configuration of the transparent substrate 1, shape of the collecting wiring line 8 and so forth. In particular, a shape with which blocking of the light guide path of light incident to the light guiding structure 12 by the collecting wiring line 8 can be avoided and the light can be guided most efficiently through the inside of the porous electrode 3 is selected, and particularly it is preferable to set the width of the collecting wiring line 8 equal to the width of the light guiding structure 12.

The size of the light guiding structure 12 is, in the case where the light guiding structure 12 is a prism of a post shape, preferably set such that the width of the bottom face is 0.1 to 5 mm, the thickness of the bottom face is 0.1 to 5 mm and the depth of the bottom face is 10 to 500 mm, more preferably set such that the width of the bottom face is 0.1 to 0.8 mm, the thickness is 0.1 to 1 mm and the depth is 100 to 500 mm, and most preferably set such that the width of the bottom face is 0.1 to 0.4 mm, the thickness is 0.1 to 0.5 mm and the depth is 200 to 400 mm. On the other hand, in the case where the light guiding structure 12 is a concave face provided on the transparent substrate 1, the size of the light guiding structure 12 is preferably set such that the width of the concave portion is 0.1 to 5 mm, the deepness of the concave portion is 0.1 to 5 mm and the depth of the concave portion is 10 to 500 mm, more preferably set such that the width of the concave portion is 0.1 to 0.8 mm, the deepness is 0.1 to 0.5 mm and the depth is 100 to 500 mm, and most preferably set such that the width of the concave portion is 0.1 to 0.4 mm, the deepness is 0.1 to 0.4 mm and the depth is 200 to 400 mm. However, the shape and the size of the light guiding structure 12 are not limited to the shapes and the sizes described above.

The light guiding structure 12 is provided on the light incidence side face of the transparent substrate 1 on the opposite side to the collecting wiring line 8 with respect to the transparent substrate 1 and can be designed in such a manner as described below. Further, in this instance, incidence light is presumably restricted to light incident from a direction perpendicular to the transparent electrode 2. However, the light to be incident to the light guiding structure 12 is not limited to this.

If the width and the thickness of the collecting wiring line 8 provided on the transparent electrode 2 are presented by L₁ and L₂, respectively, the width and the thickness of the light guiding structure 12 by L₃ and L₄, respectively, the thickness of the transparent substrate 1 on which the transparent electrode 2 is provided is represented by L₅, the refractive index of the air by nₐ, the refractive index of the light guiding structure 12 by nₚ, the incidence angle at an interface at which light is incident to the light guiding structure 12 from the air by θ₁ and the emergence angle by θ₂, then the expression (1) is satisfied from the Snell's law.

Further, if the refractive index of the transparent substrate 1 is represented by n_{g}, the incidence angle at an interface at which light is incident to the transparent substrate 1 from the light guiding structure 12 by φ₁ and the emergence angle by φ₂, then the expression (2) is satisfied from the Snell's law. Also the expression (3) is satisfied.

Here, in the case where the light guiding structure 12 is provided on the transparent substrate 1, if the widthwise component of the distance along the light path when light incident from the most concave portion of the light guiding structure 12 which is the center in the widthwise direction passes through the inside of the light guiding structure 12 is represented by Lₚ and the widthwise component of the distance along the light path when the light passes through the inside of the transparent substrate 1 by L_{g}, then in order to avoid blocking of the light guide path of the incidence light by the collecting wiring line 8, the following expression:

$$\frac{{L}_{1}}{2} < {L}_{p} + {L}_{g} \qquad ( 16 )$$

is satisfied. Further, if incidence of the above-described parallel light to the end face of the light guiding structure 12 is considered, then since the incidence light becomes an inverted irradiation, it passes a light path which bypasses the collecting wiring line 8 by a greater amount. However, the light is reflected by a vertical plane in the inside of the light guiding structure 12 and cannot be guided efficiently to the porous electrode 3. In order to avoid this, if the width of the recessed portion provided on the light guiding structure 12 is represented by L_{pw}, then the widthwise component Lₚ′ of the distance along the light path when the light passes through the inside of the light guiding structure 12 satisfies, from Lₚ′=L₄ tan φ₁, the following expression:

$$\frac{{L}_{pw}}{2} + {L}_{4} tan {φ}_{1} < \frac{{L}_{3}}{2} \qquad ( 17 )$$

With regard to the dye-sensitized photoelectric conversion device 10 according to the present embodiment, the width L₁ and the thickness L₂ of the collecting wiring line 8, the width L₃ and the thickness L₄ of the light guiding structure 12, the thickness L₅ of the transparent substrate 1, the refractive index nₚ of the light guiding structure 12, the refractive index n_{g} of the transparent substrate 1, the apex angle θ₁ at an interface at which light is incident to the light guiding structure 12 and the installation position of the light guiding structure 12 are suitably determined such that the expressions (16) and (17) may be satisfied.

### Fabrication Method of the Dye-Sensitized Photoelectric Conversion Device

Now, a fabrication method of this dye-sensitized photoelectric conversion device 10 is described.

First, a glass material is worked and molded into a desired concave shape to form light guiding structures 12. For the formation of the light guiding structures 12, one of known techniques can be selectively used suitably. For example, casting, cutting, molding and injection molding are available. However, the formation method of the light guiding structures 12 is not limited to them.

Then, the glass plate is cut out in a desired size to obtain a transparent substrate 1.

Then, the light guiding structures 12 are joined to one principal surface of the transparent substrate 1. As the joining method, a suitable one of known methods can be selectively used. For example, although adhesion, fusion and optical welding are available, the joining method of the light guiding structures 12 is not limited to them. The joining of the light guiding structures 12 can be carried out at a later step or after the dye-sensitized photoelectric conversion device 10 is completed unless a special environment such as a high temperature or a high pressure is required for the joining.

Also it is possible, in place of the step described above, to form the light guiding structures 12 by working the transparent substrate 1 to form concave shapes. The working method in the case where the transparent substrate 1 is worked to form the light guiding structures 12 is selected suitably from among known methods, and for example, cutting or molding is applicable. However, the working method of the transparent substrate 1 is not limited to them.

Except the foregoing, the fabrication method of the dye-sensitized photoelectric conversion device 10 according to the present embodiment is similar to the fabrication method of the dye-sensitized photoelectric conversion device 10 according to the first embodiment.

### Operation of the Dye-Sensitized Photoelectric Conversion Device

Now, operation of the dye-sensitized photoelectric conversion device is described.

Light introduced into the dye-sensitized photoelectric conversion device 10 through the light incidence side face partly passes through the light guiding structures 12 and then through the transparent substrate 1 and reaches the porous electrode 3.

Except the foregoing, the operation of the dye-sensitized photoelectric conversion device 10 according to the present embodiment is similar to the operation of the dye-sensitized photoelectric conversion device 10 according to the first embodiment.

### Working Example 2-1

A light guiding structure 12 was formed as a concave prism of a post shape wherein a parallelepiped prism has provided thereon a V-shaped groove whose sectional shape perpendicular to the longitudinal direction of the parallelepiped prism is symmetrical with respect to a line. The prism has a bottom face having a shape symmetrical with respect to a line, and the angle of the groove is 90°. The side face of the prism which has the grooved portion is a light incidence face, and the light guiding structure 12 is provided on a transparent substrate 1 in such a joined form that a side face thereof opposing to the grooved portion and a flat face of the transparent substrate 1 on the side to which light is incident extend in parallel to each other. The size and the installation position of the light guiding structure 12 and the thickness of the transparent substrate 1 were determined based on the shape just described. Except the foregoing, the dye-sensitized photoelectric conversion device 10 was fabricated in a similar manner as in the working example 1-1.

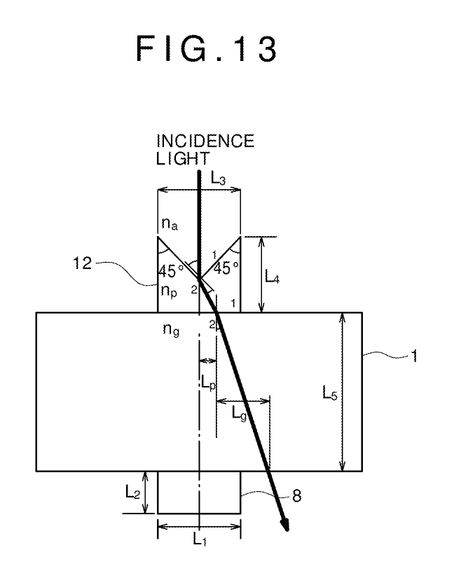

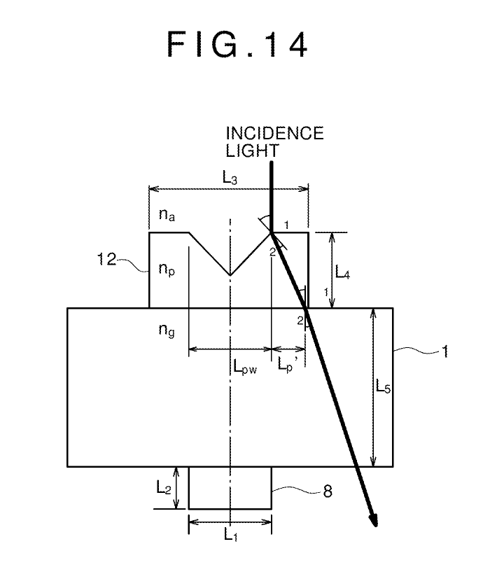

FIGS. 13 and 14 show the light guiding structure 12 of the dye-sensitized photoelectric conversion device according to the working example 2-1. A light guide path of incidence light is indicated by a thick line in FIGS. 13 and 14.

Referring to FIG. 13, the light guiding structure 12 provided on the dye-sensitized photoelectric conversion device 10 of the present working example is shaped as a straight post body which has a bottom face having two convex portions and one concave portion and symmetrical with respect to a line and extends perpendicularly from the bottom face. The bottom face has such a polygonal shape that the angle of two ones of the four convex portions is θₜ₂=45° and the groove angle of the most concave portion of the V-shaped concave portions sandwiched between the two convex portions is 90°, and the most concave portion is positioned on the center axis of the bottom face in the widthwise direction and the other angles are 90°. The light guiding structure 12 is provided on the transparent substrate 1 such that, in the state in which the face of the light guiding structure 12 opposing to the concave portion and the face of the transparent substrate 1 on the light incidence side are joined to each other, the axis of symmetry of the bottom face of the light guiding structure 12 and the center axis of the bottom face of the collecting wiring line 8 in the widthwise direction are positioned on the same straight line. Consequently, light incident to the light guiding structure 12 enters the porous electrode 3 through the transparent substrate 1 after it passes through the light guiding structure 12.

An example of a designing method of the light guiding structure 12 of the dye-sensitized photoelectric conversion device 10 according to the working example 2-1 is described below.

Referring to FIG. 13, when light which can be approximated as generally collimated parallel light is incident to one end portion except the apex angle of the light incidence side face of the light guiding structure 12 of the dye-sensitized photoelectric conversion device 10 according to the present working example perpendicularly to the transparent substrate 1, if the width L₁ of the collecting wiring line 8 formed on the transparent electrode 2 is set to L₁=0.4 mm, then in order to avoid blocking of the light wave guide of the light, incident from the incidence face on the center axis of the bottom face of the light guiding structure 12, by the collecting wiring line 8, the sum of the widthwise component Lₚ of the distance along the incidence light path in the light guiding structure 12 and the widthwise component L_{g} of the distance along the incidence light path in the transparent substrate 1 is set greater than 0.2 mm from the expression (16).

In particular, if light is incident from a center line portion of the light guiding structure 12, then the incidence angle at an interface at which light is incident to the light guiding structure 12 from the air is θ₁=90°−θₜ₂=45°. If the refractive index of the air is nₐ=1.00 and the refractive index of the light guiding structure 12 is nₚ=1.49, then the emergence angle θ₂ at an interface at which light is incident to the light guiding structure 12 from the air is θ₂=28.3° from the expression (1). Then, if the incidence angle at an interface at which light is incident to the transparent substrate 1 from the light guiding structure 12 is represented by φ₁, the emergence angle by φ₂ and the refractive index n_{g} of the transparent substrate 1 is n_{g}=1.55, then φ₁=16.7° is obtained from the expression (3) and φ₂=16.0° is obtained from the expression (2).

Here, if the width and the thickness of the light guiding structure are represented by L₃ and L₄, respectively, and the thickness of the transparent substrate including the transparent electrode 2 is represented by L₅, then the thickness L₄ and the thickness L₅ which satisfy the expression (16) can be set to L₄=0.2 mm and L₅=0.71 mm from the expressions (6) and (7), respectively. Consequently, Lₚ=0.2 mm and L_{g}=0.01 mm are obtained, then Lₚ+L_{g}=0.21 mm is obtained, which is greater than Lₚ=0.2 mm. Therefore, the expression (16) is satisfied.

Further, if reflection of light in the light guiding structure 12 is studied, then if incidence of the parallel light described hereinabove to an end face of the light guiding structure 12 is considered, then the expression (17) must be satisfied. Here, since the width of the concave portion provided on the light guiding structure 12 is L_{pw}=L₁=0.4 mm, the width L₃ which should be taken is L₃=0.8 mm from the expression (17), and the light guiding structure 12 has such a form as shown in FIG. 14.

Further, in the present working example, the method of setting the thickness L₄ of the light guiding structure 12 in advance and then determining the other dimension of the light guiding structure 12 and the thickness L₅ of the transparent substrate 1 in accordance with the set thickness L₄ was selected. However, the designing method of the light guiding structure 12 is not limited to this, but, for example, it is possible to set the thickness L₄ of the transparent substrate 1 in advance and thereafter determine the other shape, size and so forth of the light guiding structure 12 such that the expressions (16) and (17) are satisfied.

As described above, according to the present second embodiment, similar advantages to those achieved by the first embodiment can be achieved. In addition, since the light guiding structure 12 is formed as a concave prism of a post shape, the thickness of the light guiding structure 12 and the thickness of the transparent substrate 1 can be reduced, and the light guiding structure 12 can be formed thinner. Further, since light incident from the light incidence side face of the dye-sensitized photoelectric conversion device 10 can be introduced efficiently into the porous electrode 3 by the light guiding structure 12 without being blocked by the collecting wiring line 8, the photoelectric conversion device indicates a high utilization efficiency of incidence light and can achieve a superior photoelectric conversion characteristic.

### Dye-Sensitized Photoelectric Conversion Device

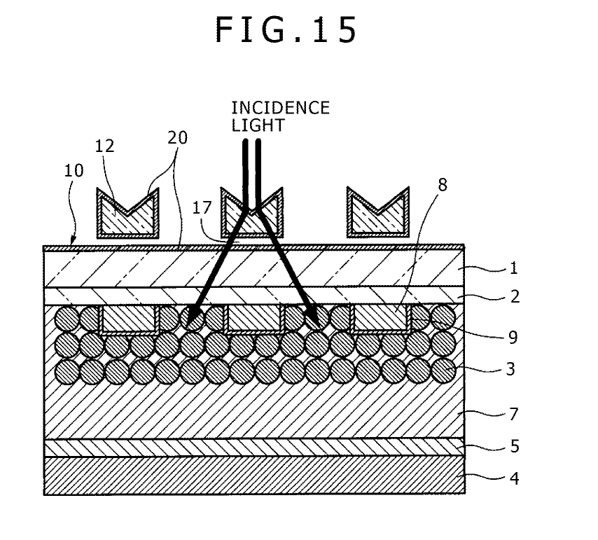

FIG. 15 shows a cross section of an essential part of a dye-sensitized photoelectric conversion device 10 according to a modification to the second embodiment. A light guide path of incidence light is indicated by a thick line in FIG. 15.

Referring to FIG. 15, in the present dye-sensitized photoelectric conversion device 10, the light guiding structure 12 is not provided on the transparent substrate 1 but is provided above the light incidence side face of the transparent substrate 1. Preferably, one principal surface of the light guiding structure 12 and one principal surface of the transparent substrate 1 are provided in a form in which they are opposed in a predetermined spaced relationship from each other and in parallel to each other. An open space is formed between the principal surface of the light guiding structure 12 and the principal surface of the transparent substrate 1 and forms an air layer filled with gas.

Although the gas layer typically is an air layer 17, it is not limited to this. Further, a multi-stage structure wherein another light guiding structure is provided above the light guiding structure 12 with an air layer interposed therebetween may be applied. The light guiding structure which is provided newly in the case where a multi-stage structure is applied is colorless and transparent and superior in penetrating power of light and can change the light guide path of incidence light. Thus, the newly provided light guiding structure may have a convex shape or a concave shape. Also with regard to the installation of the light guiding structures 12, such light guiding structures to be used for installation may be provided by any number and by any installation method only if blocking of the light guide path by the collecting wiring line 8 can be avoided.

Further, since the principal surface of the light guiding structure 12 and the principal surface of the transparent substrate 1 are spaced from each other, the distance between them is set such that the shortest distance between the principal surfaces preferably is within the range of 1 μm to 10 mm, more preferably within the range of 1 μm to 1 mm, and most preferably within the range of 1 μm to 500 μm. However, the installation form of and the installation distance between the light guiding structures 12 are not limited to them. Also after the installation of the light guiding structures 12, the installation form and the distance can be changed suitably, and particularly can be changed through movement, rotation, removal, exchange or the like. Particularly in such a case that the angle of light to be incident to the light guiding structures 12 varies, blocking of the light guide path by the collecting wiring lines 8 can be avoided by rotating and/or moving the light guiding structures 12 so as to be ready for the angle of the incidence light.

Further, the light guiding structures 11a which are provided above the light guiding structures 12 when the light guiding structures 12 are formed in a multi-stage structure are preferably provided on the transparent substrate 1 such that, particularly in the case where the light guiding structures 11a have a post shape and have a bottom face having a symmetrical shape with respect to a line, the center axes of the bottom faces of the collecting wiring lines 8 in the widthwise direction, the axes of symmetry of the bottom faces of the light guiding structures 12 and the axes of symmetry of the bottom faces of the light guiding structures 11a are positioned on the same straight lines. However, the shape and the installation of the light guiding structure 11a are not limited to those described above.

Further, the shape of the light guiding structures 12 is not limited to that described hereinabove in connection with the embodiments. However, since it is not a prerequisite that the light guiding structures 12 are installed on the transparent substrate 1, the faces of the light guiding structures 12 which oppose to the transparent substrate 1 need not be formed as flat faces. Therefore, the light guiding structures 12 may have basically any shape only if light incident to the light guiding structures 12 passes through the transparent substrate 1 and can most efficiently reach the inside of the porous electrode 3 avoiding blocking of the light guide path thereof by the collecting wiring line 8, and may have a cylindrical shape or a circular conical shape. As regards the size of the light guiding structures 12, although the width of the collecting wiring lines 8 is preferably made equal to the width of the light guiding structures 12, the shape and the size of the light guiding structures 12 are not limited to them.

Except the foregoing, the dye-sensitized photoelectric conversion device 10 according to the present modification is similar to the dye-sensitized photoelectric conversion device 10 according to the second embodiment.

### Fabrication Method of the Dye-Sensitized Photoelectric Conversion Device

Now, a fabrication method of the dye-sensitized photoelectric conversion device 10 according to the modification is described.

First, a glass material is worked and molded into a desired shape to form light guiding structures 12. For the formation of the light guiding structures 12, one of known techniques can be selectively used suitably. For example, casting, cutting, molding and injection molding are available. However, the formation method of the light guiding structures 12 is not limited to them.

Then, the glass plate is cut out in a desired size to produce a transparent substrate 1.

Then, a transparent conductive layer is formed on one principal surface of the transparent substrate 1 by sputtering or the like to form a transparent electrode 2.

Then, aluminum (Al) is vacuum deposited in a desired pattern on the transparent electrode 2 to form collecting wiring lines 8. Further, the surface of the collecting wiring lines 8 is oxidized by a thermal process, an electric process or a chemical process to form a collecting wiring line protective layer 9.

Then, light guiding structures 12 are provided in a corresponding relationship to the collecting wiring lines 8 and independently of the dye-sensitized photoelectric conversion device 10 above the face of the transparent substrate 1 which is the opposite side face of the transparent substrate 1 to the face on which the transparent electrode 2 is provided. The installation method of the light guiding structures 12 can be selected suitably from among known techniques and may be, for example, adhesion, pressure bonding, sandwiching or fitting. However, the installation method is not limited to them.

Except the foregoing, the fabrication method of the dye-sensitized photoelectric conversion device 10 according to the modification is similar to the fabrication method of the dye-sensitized photoelectric conversion device 10 according to the second embodiment.

### Operation of the Dye-Sensitized Photoelectric Conversion Device

Now, operation of the dye-sensitized photoelectric conversion device according to the modification is described.

Light introduced into the dye-sensitized photoelectric conversion device 10 through the light incidence side face partly passes through the light guiding structures 12 and the air layer and then through the transparent substrate 1 and reaches the porous electrode 3.

Except the foregoing, the operation of the dye-sensitized photoelectric conversion device 10 according to the modification is similar to the operation of the dye-sensitized photoelectric conversion device 10 according to the second embodiment.

### Working Example 2-2

The light guiding structure 12 was configured in the following manner. In particular, the light guiding structure 12 is a convex prism of a post-like shape wherein a leftwardly and rightwardly symmetrical V-shaped groove is provided on one side face of a parallelepiped prism. The prism has a bottom face symmetrical with respect to a line, and the groove angle is 90°. The light guiding structure 12 and the transparent substrate 1 are provided in a predetermined spaced relationship from each other in a state in which a flat face of the light guiding structure 12 opposing to the concave portion and a flat face of the transparent substrate 1 to which light is incident are opposed in parallel to each other. The light guiding structure 12 is provided such that the axis of symmetry of the bottom face thereof and the center axis of the bottom face of the collecting wiring line 8 in the widthwise direction are positioned on a common straight line. The size and the installation position of the light guiding structures 12 and the thickness of the transparent substrate 1 were determined based on the form described above. Except the foregoing, the dye-sensitized photoelectric conversion device 10 was fabricated similarly to the dye-sensitized photoelectric conversion device 10 according to the working example 1-1.

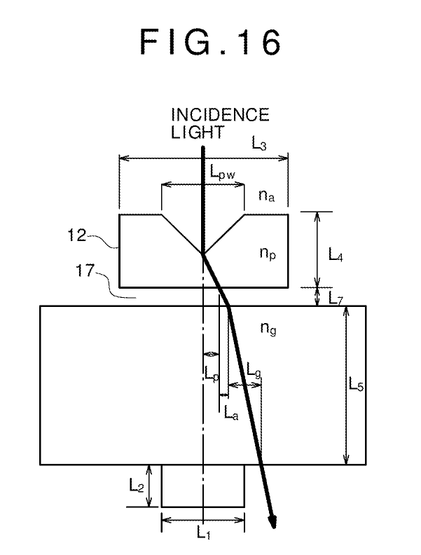

FIG. 16 shows a cross section of the light guiding structure 12 of the dye-sensitized photoelectric conversion device according to the working example 2-2. A light guide path of incidence light is indicated by a thick line in FIG. 16.

Referring to FIG. 16, for the light guiding structures 12 provided on the dye-sensitized photoelectric conversion device 10 of the present working example, a light guiding structure similar to that designed in the working example 2-1 is used. In particular, the light guiding structure 12 is a straight post body which has a bottom face of a shape symmetrical with respect to a line and having four convex portions and one concave portion and extends perpendicularly from the bottom face. The bottom face has a polygonal shape wherein two of the four convex portions have an angle θₜ₂=45° and the angle of the most concave portion of the concave portion sandwiched between the two convex portions is 270° and besides the most concave portion is positioned on the center axis of the bottom face in the widthwise direction while the other angles are 90°. The light guiding structure 12 is provided in a form wherein the face thereof opposing to the concave portion and the light incoming side face of the transparent substrate 1 are opposed in a predetermined spaced relationship from each other and in parallel to each other. An air layer 17 is formed in a space between the light guiding structure 12 and the transparent substrate 1 such that light incident to the light guiding structure 12 enters, after it passes through the light guiding structure 12, the porous electrode 3 through the air layer and the transparent substrate 1.

In the designing method of the light guiding structure 12 of the dye-sensitized photoelectric conversion device 10 according to the present working example, the shape and the size of the light guiding structure 12, the thickness of the transparent substrate and so forth are determined so as to satisfy the expressions (12) and (4) by a designing method similar to that applied to the light guiding structure 12 of the dye-sensitized photoelectric conversion device 10 according to the working example 1-7 described hereinabove.

### Working Example 2-3

The light guiding structure 12 was configured in the following manner. In particular, the light guiding structure 12 is a concave prism of a post-like shape having a bottom face of a shape symmetrical with respect to a line and having four convex portions and one concave portion. The light guiding structure 12 and the transparent substrate 1 are provided in a predetermined spaced relationship from each other in a state in which a face of the light guiding structure 12 opposing to the concave portion and a flat face on the side of the transparent substrate 1 to which light is incident are opposed in parallel to each other. Above the light guiding structure 12, a light guiding structure 12a which is a convex prism of a post-like shape having a bottom face having an apex angle and symmetrical with respect to a line is provided. The light guiding structures 12 and 12a are provided such that the axes of symmetry of the bottom faces thereof and the center axis of the bottom face of the collecting wiring line 8 in the widthwise direction are positioned on the same straight line. The size and the installation position of the light guiding structures 12 and 12a and the thickness of the transparent substrate 1 were determined based on the form described above. Except the foregoing, the dye-sensitized photoelectric conversion device 10 was fabricated similarly to the dye-sensitized photoelectric conversion device 10 according to the working example 1-1.

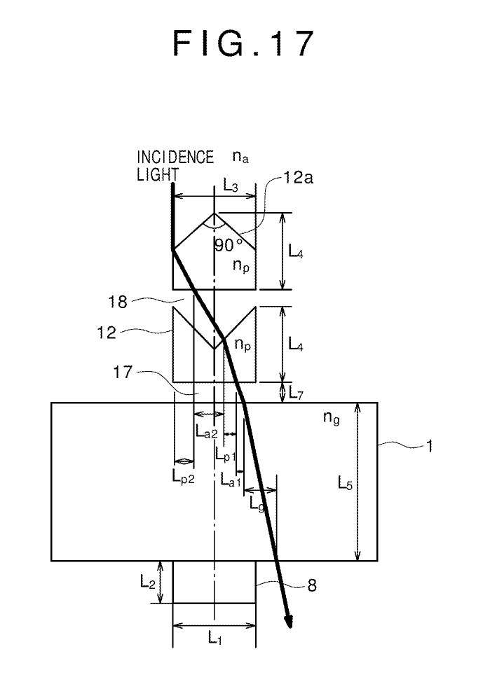

FIG. 17 shows a cross section of the light guiding structure 12 of the dye-sensitized photoelectric conversion device according to the working example 2-3. A light guide path of incidence light is indicated by a thick line in FIG. 17.

Referring to FIG. 17, the light guiding structure 12 provided on the dye-sensitized photoelectric conversion device 10 of the present working example is shaped as a straight post body which has a bottom face having four convex portions and one concave portion and symmetrical with respect to a line and extends perpendicularly from the bottom face. The bottom face has such a polygonal shape that the angle of two ones of the four convex portions is 45° and the concave portion of the light guiding structure 12 sandwiched between the two convex portions has an angle of 270° while the angle of the other convex portions is 90°. The light guiding structure 12 is provided such that, in the state in which the face of the light guiding structure 12 opposing to the concave portion and the face of the transparent substrate 1 on the light incidence side are opposed in parallel to each other and in a predetermined spaced relationship from each other. Above the light guiding structure 12, a light guiding structure 12a formed of a post shape which has a bottom face having an apex angle and symmetrical with respect to a line is provided in a state in which a face thereof opposing to the apex angle and the concave portion of the light guiding structure 12 are opposed in a predetermined spaced relationship from each other. The light guiding structures 12 and 12a are provided such that the axes of symmetry of the bottom faces and the center axis of the bottom face of the collecting wiring line 8 in the widthwise direction are positioned on the same straight line. It is to be noted that, the light guiding structure 12a is a straight post body having a bottom face of a pentagonal shape and extending perpendicularly from the bottom face. The bottom face has a shape symmetrical with respect to a line wherein three of the five angles of the pentagonal shape are 90 degrees and the remaining two angles are 135 degrees. The angle sandwiched between the two angles of 135° is the apex angle of 90°.

Air layers 18 and 17 are formed between the light guiding structure 12a and the light guiding structure 12 and between the light guiding structure 12 and the transparent substrate 1, respectively. Thus, light incident to the light guiding structure 12a passes through the inside of the light guiding structure 12a and enters the light guiding structure 12 through the second air layer 18, and the light passing through the inside of the light guiding structure 12 enters the porous electrode 3 through the air layer 17 and the transparent substrate 1.

According to the designing method of the light guiding structures 12 and 12a of the dye-sensitized photoelectric conversion device 10 according to the present working example, the shape and the size of the light guiding structure 12 and the light guiding structure 12a, the thickness of the transparent substrate and so forth are determined so that the expressions (15) and (17) are satisfied by a designing method similar to that applied to the light guiding structure 12 of the dye-sensitized photoelectric conversion device 10 according to the working example 1-7 described above. However, the designing method for the light guiding structures 12 and 12a is not limited to this.

As described above, with the modification to the second embodiment, similar advantages to those achieved by the second embodiment can be achieved. In addition, since the light guiding structures 12 and/or 12a are not secured to the transparent substrate 1, it is possible to simply and easily change the installation position of the light guiding structures 12 and/or 12a. Thus, by suitably selecting the installation position and the installation form of the light guiding structures 12 and 12a in response to the form of the collecting wiring line 8, the necessity to newly design the light guiding structure 12 in response to the form of the collecting wiring line 8 is eliminated.

Further, by changing the installation position of the light guiding structures 12 and/or 12a, it is possible to cope with incidence light from various angles. Further, since the light guiding structures 12 and/or 12a can be moved in response to the incidence direction or position of light, also in the case where the incidence direction or position of light varies together with time, it is possible to make the numerical aperture of the light incidence face of the dye-sensitized photoelectric conversion device 10 maximum.

Further, since the light guiding structures 12 and/or 12a are installed at a predetermined distance from the transparent substrate 1, the air layer 17 is formed between the light guiding structure 12 and the transparent substrate 1 and the second air layer 18 is formed between the light guiding structure 12 and the light guiding structure 12a. Further, by setting the distance of the light guide path in the air layer 17 and/or the second air layer 18 to a great distance, there is no necessity to make the transparent substrate 1 excessively thick or make the light guiding structure 12 excessively great in order to avoid blocking of the light guide path of incidence light by the collecting wiring line 8.

Further, since the light guiding structure 12 is provided independently of the dye-sensitized photoelectric conversion device 10, also when the light guiding structure 12 is broken or damaged, only it is necessary to exchange only the light guiding structure 12. Consequently, reduction in cost can be anticipated.

Further, by adopting a multi-stage structure wherein another light guiding structure is provided above the light guiding structure 12, the light guide path can be designed suitably by combining light guiding structures of various forms. Consequently, also in a case in which the dye-sensitized photoelectric conversion device 10 is installed, for example, at a place at which lighting can be carried out only in a local region, the numerical aperture of the light incidence face can be maintained at a high value.

### 3. Third Embodiment

### Dye-Sensitized Photoelectric Conversion Device

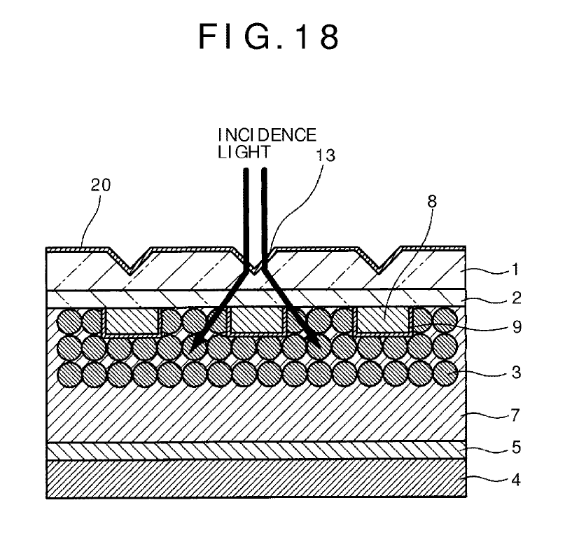

FIG. 18 shows a cross section of an essential part of a dye-sensitized photoelectric conversion device 10 according to a third embodiment. A light guide path of incidence light is indicated by a thick line in FIG. 18.

Referring to FIG. 18, the dye-sensitized photoelectric conversion device 10 shown is configured such that convex shapes or concave shapes are formed as light guiding structures by working a face of a transparent substrate 1 on the light incidence side which is one principal surface of the transparent substrate 1 as light guiding structures 13. Except the foregoing, the dye-sensitized photoelectric conversion device 10 according to the present embodiment is similar to the dye-sensitized photoelectric conversion device 10 according to the first embodiment.

Each light guiding structure 13 formed by working the one principal surface of the transparent substrate 1 may be any light guiding structure only if it can change the light guide path of light incident to the light incidence face to avoid blocking of the light guide path of incidence light by a collecting wiring line 8. It is possible to configure the light guiding structure 13 by working the light incidence side face of the transparent substrate to form the same. However, also it is possible to configure the light guiding structure 13 by forming a groove on the transparent substrate 1 to configure a concave structure. The light guiding structure 13 may be basically any light guiding structure only if it can change the light path of incidence light. Particularly, for example, the shape of a cross section of the light guiding structure 13 taken perpendicularly to the longitudinal direction may be a V shape, a U shape, a rectangular shape, a polygonal shape, a semicircular shape or the like. However, the sectional shape of the light guiding structure 13 is not limited to them.

The size of the light guiding structure 13 is, in the case where the light guiding structure 13 is a groove provided on the transparent substrate 1, preferably set such that the width of the groove portion is 0.1 to 5 mm, the deepness of the groove portion is 0.1 to 5 mm and the depth of the groove portion is 10 to 500 mm, more preferably set such that the width of the groove portion is 0.1 to 0.8 mm, the deepness is 0.1 to 0.5 mm and the depth is 100 to 500 mm, and most preferably set such that the width of the groove portion is 0.1 to 0.4 mm, the deepness is 0.1 to 0.4 mm and the depth is 200 to 400 mm. However, the shape and the size of the light guiding structure 13 are not limited to the shapes and the sizes described above.

Except the foregoing, the dye-sensitized photoelectric conversion device 10 according to the present embodiment is similar to the dye-sensitized photoelectric conversion device 10 according to the first embodiment.

### Fabrication Method of the Dye-Sensitized Photoelectric Conversion Device

Now, a fabrication method of the dye-sensitized photoelectric conversion device 10 according to the present embodiment is described.

First, a glass plate is cut out in a desired size to produce a transparent substrate 1.

Then, one principal surface of the transparent substrate 1 is worked to form grooves as the light guiding structures 13 at positions corresponding to collecting wiring lines 8 to be formed on the opposite side face of the transparent substrate 1. The working method of the transparent substrate 1 may be basically any method only if it can form grooves without degrading transmission of light through the transparent substrate 1. Particularly, machining, molding, injection molding and so forth are available. However, the working method of the transparent substrate 1 is not limited to them.

Except the foregoing, the fabrication method of the dye-sensitized photoelectric conversion device 10 according to the present embodiment is similar to the fabrication method of the dye-sensitized photoelectric conversion device 10 according to the first embodiment.

### Operation of the Dye-Sensitized Photoelectric Conversion Device

Now, operation of the dye-sensitized photoelectric conversion device according to the present embodiment is described.

Light introduced into the dye-sensitized photoelectric conversion device 10 through the light incidence side face passes through the transparent substrate 1, on which the light guiding structures 13 are formed, and reaches the porous electrode 3.

Except the foregoing, the operation of the dye-sensitized photoelectric conversion device 10 according to the present embodiment is similar to the operation of the dye-sensitized photoelectric conversion device 10 according to the first embodiment.

### Working Example 3-1

A transparent substrate 1 was worked to form grooves in the form of concave portions on the light incidence side face of the transparent substrate 1 as the light guiding structures 13.

Then, on the opposite side face to the light incidence side face of the transparent substrate 1, a FTO film which is a transparent conducive layer was formed by sputtering to form the transparent electrode 2. Except this, a similar process to that used in the working example 1-1 was applied to fabricate a dye-sensitized photoelectric conversion device 10.

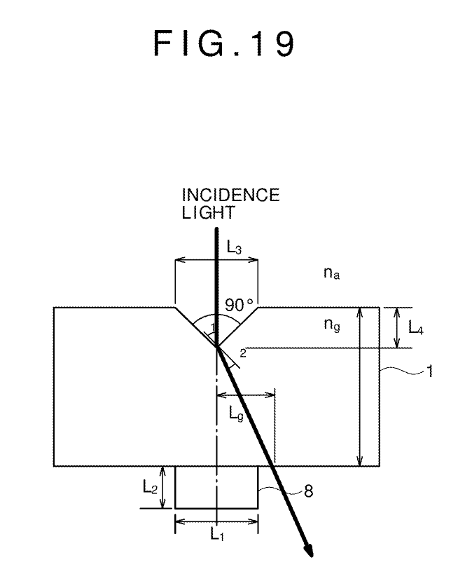

FIG. 19 shows a cross section of the transparent substrate 1 of the dye-sensitized photoelectric conversion device 10 according to the working example 3-1. A light guide path of incidence light is indicated by a thick line in FIG. 19.

Referring to FIG. 19, a groove train including grooves having a V-shaped cross section perpendicular to the longitudinal direction is formed on the light incidence side face of the transparent substrate 1 provided in the dye-sensitized photoelectric conversion device 10 such that the grooves are formed at distances of 5 mm. The grooves serve as the light guiding structures 13.

Each of the light guiding structures 13 is configured by forming a groove having a V-shaped cross section perpendicular to the longitudinal direction on the light incidence side face of the transparent substrate 1. The vertical cross section of the groove has an angle of 90° at the deepest portion of the groove and has a shape symmetrical with respect to a line. Part of light incident to the transparent substrate 1 passes through the light guiding structure 13 in the form of the V-shaped groove and then is introduced into the porous electrode 3 through the transparent substrate 1.

The light guiding structure 13 is provided on the light incidence side face of the transparent substrate 1 such that the center axis of the vertical section of the light guiding structure 13 and the center axis of the vertical section of an collecting wiring line 8 formed on the transparent electrode 2 may be positioned on the same line.

An example of a designing method of the light guiding structure 13 of the dye-sensitized photoelectric conversion device 10 according to the working example 3-1 is described below.

In the case where light which can be approximated to generally collimated parallel light is incident perpendicularly to one end portion except the apex angle of the light incidence side face of the light guiding structure 13 of the dye-sensitized photoelectric conversion device 10 according to the present working example, if the width L₁ of the collecting wiring line 8 to be formed on the transparent electrode 2 is set to L₁=0.4 mm, then in order to avoid blocking of the light guide path of the light incident from a central axis portion of the V-shaped groove of the transparent substrate 1 which is the light guiding structure 13 by the collecting wiring line 8, the widthwise component L_{g} of the distance along the incidence light path in the transparent substrate 1 is made greater than 0.2 mm from the expression (16). Thus, the size of the light guiding structure 13 which satisfies this condition is determined suitably.

Further, in the present working example, after the width L₃ of the groove provided on the transparent substrate 1 and serving as the light guiding structure 13 is set in advance, the other dimensions of the light guiding structure 13 and the thickness L₅ of the transparent substrate 1 may be determined in accordance with the set width L₃. Or, after the thickness of the transparent substrate 1 is set in advance, the shape, size and so forth of the light guiding structure 13 may be determined such that the expression (16) is satisfied. However, the designing method of the light guiding structure 13 is not limited to them.

As described above, with the dye-sensitized photoelectric conversion device 10 according to the present third embodiment, similar advantages to those achieved by the first and second embodiments can be achieved. Further, the transparent substrate 1 itself is worked to configure the light guiding structures, the necessity for such light guiding structures as prisms is eliminated, and since also the fabrication process can be simplified, reduction in cost can be achieved. Further, since the light guiding structures 13 and the transparent substrate 1 are made of the same material, the dye-sensitized photoelectric conversion device 10 suffers from no loss by reflection of incidence light at the interface between the light guiding structures 13 and the transparent substrate 1. Further, particularly since the light guiding structures 13 have a concave shape, a protruding element such as a prism is not provided on the transparent substrate 1, and consequently, the dye-sensitized photoelectric conversion device 10 can be formed in a reduced thickness.

### 4. Fourth Embodiment

### Dye-Sensitized Photoelectric Conversion Device

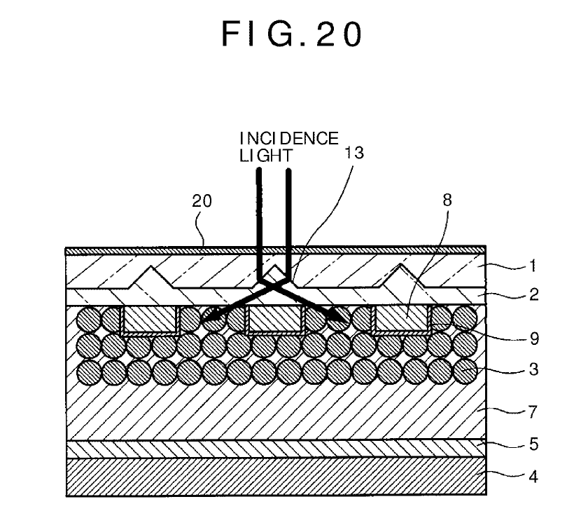

FIG. 20 shows a cross section of an essential part of a dye-sensitized photoelectric conversion device 10 according to a fourth embodiment, and a light guide path of incidence light is indicated by a thick line in FIG. 20.

Referring to FIG. 20, the dye-sensitized photoelectric conversion device 10 is configured such that a face of a transparent substrate 1 on the opposite side to a face on the light incidence side which is one principal surface of the transparent substrate 1 is worked to form convex shapes or concave shapes as light guiding structures 13, and a transparent electrode 2 is formed on the light guiding structures 13 and the transparent substrate 1 on the side on which the light guiding structures 13 are formed. Except the foregoing, the dye-sensitized photoelectric conversion device 10 according to the present embodiment is similar to the dye-sensitized photoelectric conversion device 10 according to the first embodiment.

The light guiding structures 13 formed by working one principal surface of the transparent substrate 1 may be basically any light guiding structure only if it can change the light path of incidence light. For example, the light guiding structure 13 can be configured by working a transparent substrate 1 itself to form the shape of the light guiding structures described above on the one principal surface of the transparent substrate 1. The light guiding structures 13 can be configured also by forming grooves on the transparent substrate 1 to configure the concave structures. The shape of the grooves may be, for example, as a sectional shape perpendicular to the longitudinal direction, a V shape, a U shape, a rectangular shape, a semicircular shape or the like. However, the shape is not limited to them.

Except the foregoing, the dye-sensitized photoelectric conversion device 10 according to the present embodiment is similar to the dye-sensitized photoelectric conversion device 10 according to the first embodiment.

### Fabrication Method of the Dye-Sensitized Photoelectric Conversion Device

Now, a fabrication method of the dye-sensitized photoelectric conversion device 10 according to the present embodiment is described.

First, a glass plate is cut out in a desired size to produce a transparent substrate 1.

Then, one principal surface of the transparent substrate 1 is worked to form light guiding structures 13 of a concave shape or a convex shape at positions corresponding to collecting wiring lines 8 to be formed on the same side face of the transparent substrate 1 with a transparent electrode 2. The working method of the transparent substrate 1 may be basically any method only if it can form concave shapes or convex shapes without degrading transmission of light through the transparent substrate 1. Particularly, machining, molding, injection molding and so forth are available. However, the working method of the transparent substrate 1 is not limited to them.

Then, a transparent conductive layer as a transparent electrode 2 is formed on the face of the transparent substrate 1 on the side on which the light guiding structures 13 are provided by sputtering or the like. Although the transparent electrode 2 is preferably formed such that the face thereof which contacts with the collecting wiring lines 8 and the porous electrode 3 is a flat face, the form of the transparent electrode 2 is not limited to this.

Except the foregoing, the fabrication method of the dye-sensitized photoelectric conversion device 10 according to the present embodiment is similar to the fabrication method of the dye-sensitized photoelectric conversion device 10 according to the first embodiment.

### Operation of the Dye-Sensitized Photoelectric Conversion Device

Now, operation of the dye-sensitized photoelectric conversion device according to the present embodiment is described.

Light introduced into the dye-sensitized photoelectric conversion device 10 through the light incidence side face passes through the transparent substrate 1, on which the light guiding structures 13 are formed, and reaches the porous electrode 3.

Except the foregoing, the operation of the dye-sensitized photoelectric conversion device 10 according to the present embodiment is similar to the operation of the dye-sensitized photoelectric conversion device 10 according to the first embodiment.

As described above, with the dye-sensitized photoelectric conversion device 10 according to the present fourth embodiment, similar advantages to those achieved by the embodiments described hereinabove can be achieved. Further, the transparent substrate 1 itself is worked to configure the light guiding structures, the necessity for such light guiding structures as prisms is eliminated, and since also the fabrication process can be simplified, reduction in cost can be achieved. Further, since the light guiding structures 13 and the transparent substrate 1 are made of the same material, the dye-sensitized photoelectric conversion device 10 suffers from no loss by reflection of incidence light at the interface between the light guiding structures 13 and the transparent substrate 1. Further, particularly since the light guiding structures 13 have a concave shape, a protruding element such as a prism is not provided on the transparent substrate 1, and consequently, the dye-sensitized photoelectric conversion device 10 can be formed in a reduced thickness.

### 5. Fifth Embodiment

### Dye-Sensitized Photoelectric Conversion Device

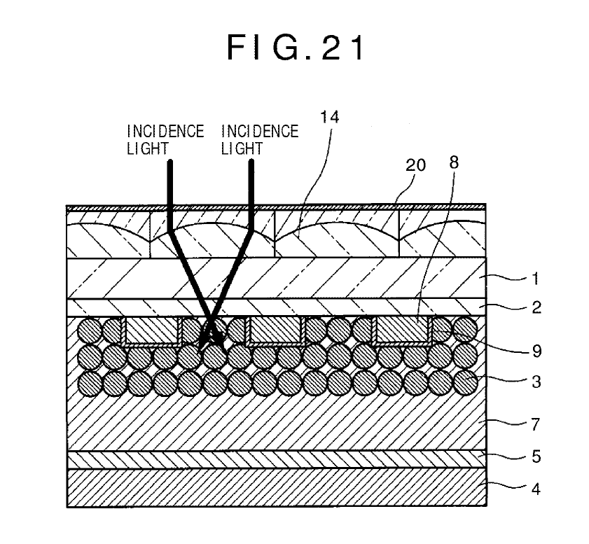

FIG. 21 shows a cross section of an essential part of a dye-sensitized photoelectric conversion device 10 according to a fifth embodiment, and a light guide path of incidence light is indicated by a thick line in FIG. 21.

Referring to FIG. 21, the dye-sensitized photoelectric conversion device 10 is configured such that light guiding structures 14 are provided on a face of a transparent substrate 1 on the light incidence side which is a face on the opposite side to a face on which a transparent electrode 2 is provided. The light guiding structures 14 are formed from a liquid lens which is an optical element which utilizes an electrowetting or electrocapillarity phenomenon.

Except the foregoing, the dye-sensitized photoelectric conversion device 10 according to the present embodiment is similar to the dye-sensitized photoelectric conversion device 10 according to the first embodiment.

Each light guiding structure 14 in the form of a liquid lens can be applied to the light guiding structures in the embodiments described hereinabove, and is preferably applied particularly to the light guiding structures of prisms which are the light guiding structures described hereinabove. In the form of the light guiding structure 14 at this time, the form of a lens portion can be suitably selected as a form of the prisms described hereinabove. Further, the liquid lens can vary the incidence angle of incidence light with a voltage making use of an electrowetting effect which is a phenomenon that, when a voltage is applied between liquid having conductivity and an electrode with insulator interposed between, the liquid is charged and the surface free energy decreases, whereupon the shape, that is, the curvature, of the air-liquid interface or the liquid-liquid interface varies. Therefore, the light guide path which passes the inside of the light guiding structure 14 can be controlled to avoid blocking of the light guide path by the collecting wiring line 8.

### Fabrication Method of the Dye-Sensitized Photoelectric Conversion Device

Now, a fabrication method of the dye-sensitized photoelectric conversion device 10 according to the fifth embodiment is described.

First, a glass plate is cut out in a desired size to produce a transparent substrate 1.

Then, liquid lenses which are the light guiding structures 14 are installed on one principal surface of the transparent substrate 1. The installation method may be suitably selected from among known installation methods. The light guiding structures 14 may otherwise be joined at a later step or after the dye-sensitized photoelectric conversion device 10 is completed.

Except the foregoing, the fabrication method of the dye-sensitized photoelectric conversion device 10 according to the present embodiment is similar to the fabrication method of the dye-sensitized photoelectric conversion device 10 according to the first embodiment.

### Operation of the Dye-Sensitized Photoelectric Conversion Device

Now, operation of the dye-sensitized photoelectric conversion device according to the present embodiment is described.

Light introduced into the dye-sensitized photoelectric conversion device 10 through the light incidence side face passes through the light guiding structures 14 or the transparent substrate 1 and reaches the porous electrode 3.

Since the light guiding structures 14 are configured from a liquid lens, if a voltage is applied between the liquid having conductivity and the electrode through the insulator, then the liquid is charged and the surface free energy decreases. Consequently, an electrowetting effect which is a phenomenon that the shape, that is, the curvature, of the air-liquid interface or the liquid-liquid interface varies occurs, and the incidence angle of the incidence light can be varied by the voltage. Consequently, the light guide path which passes the inside of the light guiding structure 14 can be controlled to avoid blocking of the light guide path by the collecting wiring line 8.

Except the foregoing, the operation of the dye-sensitized photoelectric conversion device 10 according to the present embodiment is similar to the operation of the dye-sensitized photoelectric conversion device 10 according to the first embodiment.

As described above, with the dye-sensitized photoelectric conversion device 10 according to the present fifth embodiment, similar advantages to those achieved by the above-described embodiments can be achieved. In addition, since the light guiding structures 14 are configured from a liquid lens, the light path of light to pass through the inside of the light guiding structure 14 can be controlled by varying the incidence angle of incidence light with a voltage utilizing the electrowetting. Consequently, since the lens curvature of the light guiding structures 14 can be changed in response to the shape of the collecting wiring lines 8, the necessity to design the light guiding structures individually in response to the shape of the collecting wiring lines 8 is eliminated. Further, also in the case where the incidence angle of incidence light which enters the incidence face of the dye-sensitized photoelectric conversion device 10 varies, since the lens curvature of the light guiding structures 14 can be changed in response to the incidence angle of the incidence light, the dye-sensitized photoelectric conversion device 10 can cope with the change of the incidence angle of the incidence light without the necessity to provide a new light guiding structure or move the light guiding structures.

### 6. Sixth Embodiment

### Dye-Sensitized Photoelectric Conversion Device

Collecting wiring lines 8 which divide a porous electrode 3 into belts and are provided on a transparent electrode 2 are formed in an optimum shape, that is, in an optimum disposition, thickness and number, derived from resistance value calculation in accordance with a power generation amount of a dye-sensitized photoelectric conversion device 10, and light guiding structures 15 are provided on a transparent substrate 1 in accordance with the shape of the collecting wiring lines 8.

Except the foregoing, the dye-sensitized photoelectric conversion device 10 according to the present embodiment is similar to the dye-sensitized photoelectric conversion device 10 according to the first embodiment.

While the shape of the collecting wiring lines 8 is not limited to a linear shape, it may be set to a curved shape, a grating shape, a vortex shape, a wedge shape, a wave shape or a combination between or among the shapes, the shape of the collecting wiring lines 8 is not limited to them. Further, the width of the collecting wiring line 8 can be made variable.

The light guiding structures 15 can be suitably applied to the light guiding structures in the embodiments described above.

### Fabrication Method of the Dye-Sensitized Photoelectric Conversion Device

Now, a fabrication method of the dye-sensitized photoelectric conversion device 10 is described.

First, a glass plate is cut out in a desired size to obtain a transparent substrate 1.

Then, a transparent conductive layer is formed by a spattering method or the like on one principal surface of the transparent substrate 1 to form a transparent electrode 2.

Then, aluminum (Al) is vapor deposited in a desired pattern on the transparent electrode 2 to form collecting wiring lines 8. Further, the surface of the collecting wiring lines 8 is oxidized by a thermal process, an electrical process or a chemical process to form a collecting wiring line protection layer 9.

Then, light guiding structures 15 are provided on the transparent substrate 1 in accordance with the shape of the collecting wiring lines 8.

The fabrication method described above may be modified such that the step at which a transparent electrode 2 is formed on a transparent substrate 1 after the step at which light guiding structures 15 are formed on the transparent substrate 1 is carried out.

Except the foregoing, the fabrication method of the dye-sensitized photoelectric conversion device 10 in the present sixth embodiment is similar to the fabrication method of the dye-sensitized photoelectric conversion device 10 according to the first embodiment.

### Operation of the Dye-Sensitized Photoelectric Conversion Device

Now, operation of the dye-sensitized photoelectric conversion device is described.

Light incident from a face of the dye-sensitized photoelectric conversion device 10 on the light incidence side passes through the transparent substrate 1 on which the light guiding structure 15 is formed, and reaches the porous electrode 3.

Except the foregoing, operation of the dye-sensitized photoelectric conversion device 10 according to the present embodiment is similar to the operation of the dye-sensitized photoelectric conversion device 10 according to the first embodiment.

### Working Example 6-1

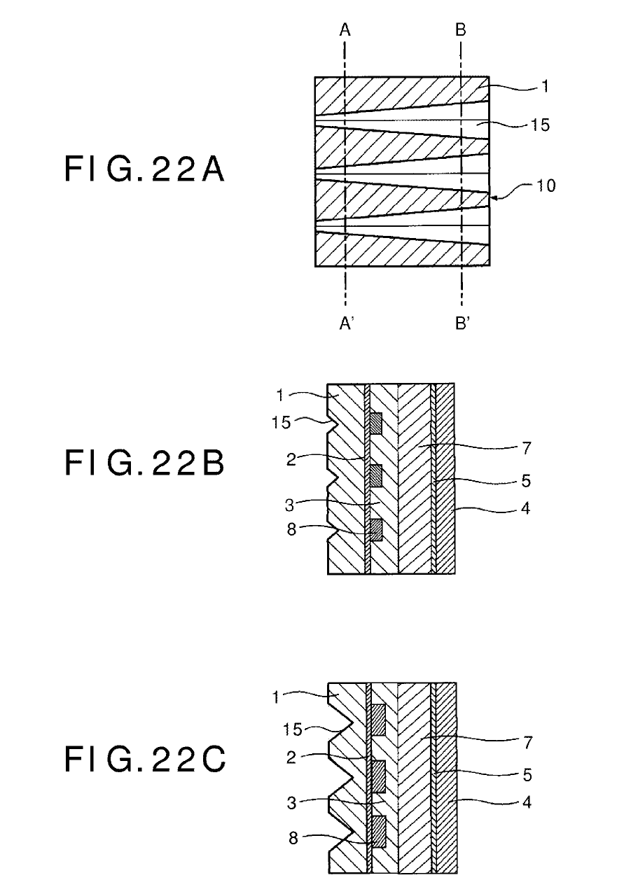

FIGS. 22A, 22B and 22C show part of the transparent substrate 1 of the dye-sensitized photoelectric conversion device 10 according to a working example 6-1. In particular, FIG. 22A shows the face of the dye-sensitized photoelectric conversion device 10 on the light incidence side as viewed from above, and FIG. 22B shows part of the transparent substrate 1 of the dye-sensitized photoelectric conversion device 10 taken along line A-A′ of FIG. 22A and FIG. 22C shows part of the transparent substrate 1 of the dye-sensitized photoelectric conversion device 10 taken along line B-B′ of FIG. 22A.

Referring FIGS. 22A to 22C, in the dye-sensitized photoelectric conversion device 10, the thickness and width of the collecting wiring lines 8 provided on the transparent electrode 2 is made variable in an extending direction of the collecting wiring lines 8 and the depth and width of grooves which are provided as light guiding structures 15 on the transparent substrate 1 in a corresponding relationship to the collecting wiring lines 8 and whose sectional shape perpendicular to a longitudinal direction is a V shape is made variable regarding an extending direction of the V-shaped groove. In the case where the light guiding structures 15 are designed in accordance with the collecting wiring lines 8, the form of the light guiding structures 15 is suitably determined so as to satisfy the expression (4) given in the embodiments described above.

### Working Example 6-2

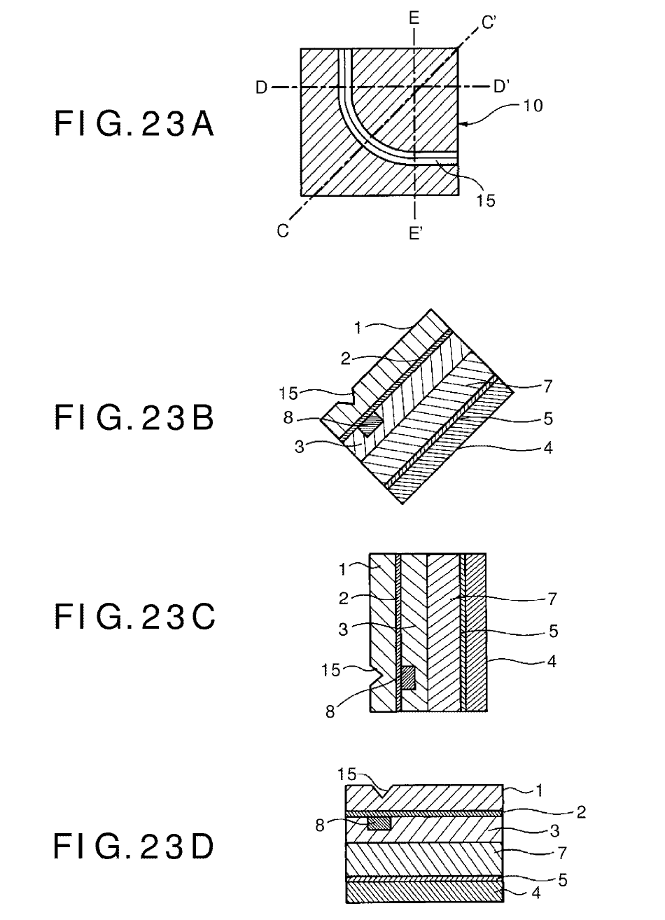

FIGS. 23A, 23B, 23C and 23D show part of the dye-sensitized photoelectric conversion device 10 according to a working example 6-2. In particular, FIG. 23A shows a face of the dye-sensitized photoelectric conversion device 10 on the light incidence side as viewed from above and FIG. 23B shows part of the dye-sensitized photoelectric conversion device 10 taken along line C-C′ of FIG. 23A. FIGS. 23C and 23D show part of the dye-sensitized photoelectric conversion device 10 taken along line D-D′ of FIG. 23A.

Referring to FIGS. 23A to 23D, in the dye-sensitized photoelectric conversion device 10, the shape of the collecting wiring lines 8 provided on the transparent electrode 2 is set to a bent or curved shape which is a combination of linear lines and a curved line in the longitudinal direction. Further, a groove having a V-shaped sectional shape perpendicular to the longitudinal direction is provided on the transparent substrate 1 as the light guiding structure 15 which can avoid blocking of the light guide path of incidence light by the collecting wiring line 8. Further, the V-shaped groove of the light guiding structure 15 in the longitudinal direction is set to a bent or curved shape similarly to the collecting wiring line 8.

As described above, with the dye-sensitized photoelectric conversion device 10 according to the sixth embodiment, similar advantages to those achieved by the embodiments described above can be achieved. In addition, since the collecting wiring lines 8 provided on the transparent electrode 2 are formed in an optimum shape, that is, in an optimum disposition, thickness and number, derived from the resistance value calculation in accordance with the power generation amount of the dye-sensitized photoelectric conversion device 10 and the light guiding structures 15 are provided on the transparent substrate 1 in accordance with the shape of the collecting wiring lines 8, the power collection efficiency of the collecting wiring lines 8 can be enhance and the resistance value described above can be decreased. Further, since the light guiding structures 15 are designed and provided corresponding to the collecting wiring lines 8, the numerical aperture of the light incidence face of the dye-sensitized photoelectric conversion device 10 can be increased and the photoelectric conversion efficiency can be increased by a multiplier effect of those effects described above.

### 7. Seventh Embodiment

### Dye-Sensitized Photoelectric Conversion Device Array

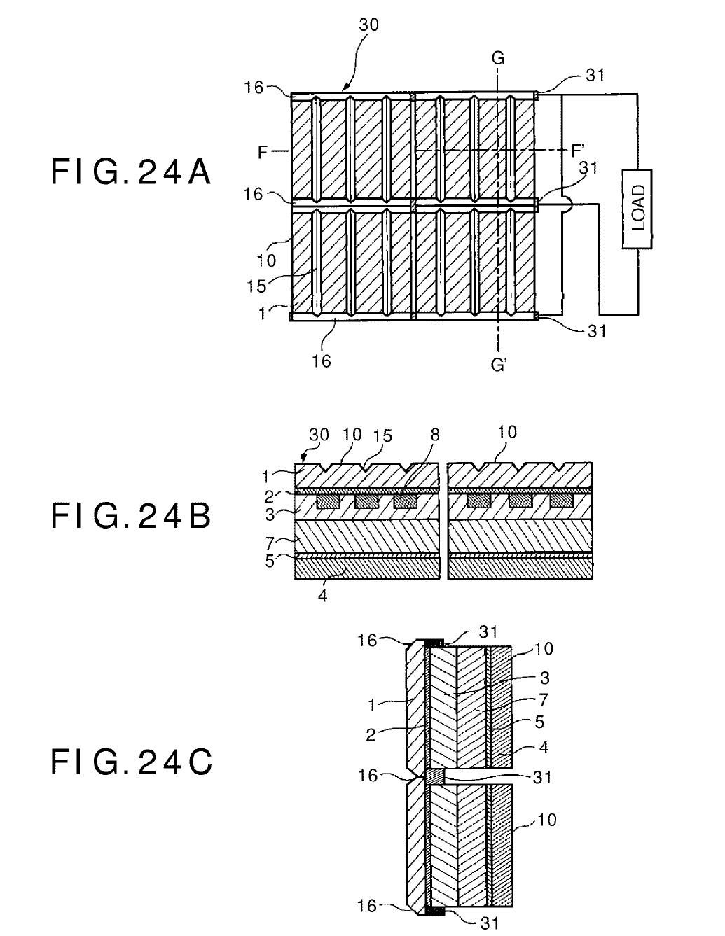

FIGS. 24A, 24B and 24C show part of a dye-sensitized photoelectric conversion device array 30 according to a seventh embodiment. In particular, FIG. 24A shows a face of the dye-sensitized photoelectric conversion device array 30 on the light incidence side as viewed from above and FIG. 24B shows part of the dye-sensitized photoelectric conversion device array 30 taken along line F-F′ of FIG. 24A. Further, FIG. 24C shows part of the dye-sensitized photoelectric conversion device array 30 taken along line G-G′ of FIG. 24A.

Referring to FIGS. 24A to 24C, in the dye-sensitized photoelectric conversion device array 30, a device array configured by disposing a plurality of the dye-sensitized photoelectric conversion devices 10 and combining and connecting the collecting wiring lines 8 of the dye-sensitized photoelectric conversion devices 10 with and to each other by aggregation wiring lines 31 so as to be integrated (tiling) is applied so that the area of the face of the dye-sensitized photoelectric conversion devices on the light incidence side is increased to increase the photoelectric conversion efficiency. The connection form of the aggregation wiring lines 31 for connecting the collecting wiring lines 8 can be arbitrarily determined as the dye-sensitized photoelectric conversion device array 30 in accordance with a desired voltage and current. In particular, a series connection form, a parallel connection form or a connection form in which the series connection and the parallel connection are combined may be applied. Further, while a load 22 is connected to the aggregation wiring lines 31 through wiring lines, the connection of the load 22 is not limited to this. Further, the negative electrode of the dye-sensitized photoelectric conversion device array 30 can be configured also by combining and connecting the collecting wiring lines 8 of the dye-sensitized photoelectric conversion devices 10 with and to each other by the aggregation wiring lines 31.

Further, the collecting wiring lines 8 are provided on the transparent electrode 2 of the dye-sensitized photoelectric conversion device 10 so that the porous electrode 3 is divided into belts and grooves which serve as the light guiding structures 15 are provided on the transparent substrate 1 so that blocking of the light guide path of the incidence light by the collecting wiring lines 8 can be avoided. However, the form of the collecting wiring lines 8 and the light guiding structures 15 is not limited to this, and the collecting wiring lines and the light guiding structures in the embodiments described above can be used suitably.

Further, the dye-sensitized photoelectric conversion device array 30 is configured, for example, by juxtaposing the four dye-sensitized photoelectric conversion devices 10 having the same configuration. Further, the dye-sensitized photoelectric conversion devices 10 are disposed standing in two lines and two rows in a predetermined spaced relationship in the same direction. While the aggregation wiring lines 31 are provided for connection of the collecting wiring lines 8 to each other individually on the side face in a direction orthogonal to the collecting wiring lines 8 of the dye-sensitized photoelectric conversion devices 10, the configuration of the dye-sensitized photoelectric conversion devices 10 and the configuration of the dye-sensitized photoelectric conversion device array 30 are not limited to them. For example, the dye-sensitized photoelectric conversion device array 30 can be configured from at least two or more dye-sensitized photoelectric conversion devices 10 or can be configured also by combining dye-sensitized photoelectric conversion devices 10 having configurations different from each other.

Here, where the dye-sensitized photoelectric conversion devices 10 are connected to each other by the aggregation wiring lines 31 to configure the dye-sensitized photoelectric conversion device array 30, since light incident to the aggregation wiring lines 31 is reflected by the aggregation wiring lines 31 and is not introduced to the porous electrode 3, contribution to power generation cannot be achieved.

Therefore, in order to solve the problem just described, the light guide path of light to be incident to the aggregation wiring lines 31 may be changed so that the light guide path of the incidence light can reach the porous electrode 3.

In particular, as shown in FIG. 24C, a light guiding structure 16 which is a second light guiding structure is provided for each of the aggregation wiring lines 31. The light guiding structure 16 is configured by providing a groove on the transparent substrate 1 along a longitudinal direction of the aggregation wiring line 31. By changing the light guide path of the light to be inputted to the transparent substrate 1 by refraction by the light guiding structure 16, the light guide path of the incidence light blocked by the aggregation wiring line 31 avoids light path blocking by the aggregation wiring line 31 and is introduced into the porous electrode 3. As a result, the numerical aperture of the light incidence face of the dye-sensitized photoelectric conversion device array 30 can be increased. In particular, as shown in FIGS. 24A and 24C, the transparent substrate 1 is provided so as to extend to cover the face of the aggregation wiring lines 31 on the light incidence face and the light guiding structures 16 are provided on the transparent substrate 1 at an upper portion of the aggregation wiring lines 31 so that the light guide path of the light to be incident to the transparent substrate 1 at the upper portion of the aggregation wiring line 31 can avoid light path blocking by the aggregation wiring line 31 and can reach the porous electrode 3.

While, for the light guiding structures 16, such a groove whose sectional shape perpendicular to the longitudinal direction is V as shown in FIGS. 24A to 24C is suitable and it is most preferable that the V shape is symmetric with respect to a line, the light guiding structures 16 are not limited to this and the light guiding structures in the embodiments and the working examples described above can be suitably selected.

Regarding the provision of the light guiding structures 16 on the aggregation wiring lines 31, the transparent substrate 1 in the dye-sensitized photoelectric conversion devices 10 may be extended in a depthwise direction of the collecting wiring lines 8 such that the light guiding structures 16 are configured so as to protrude from the layers other than the transparent substrate 1 and the light guiding structures 16 are provided on the protruding portions. Further, after the aggregation wiring lines 31 are provided on the dye-sensitized photoelectric conversion devices 10, the light guiding structures 16 may be further provided on the aggregation wiring lines 31 independently to configure the transparent substrate 1. However, the provision of the transparent substrate 1 on the aggregation wiring lines 31 is not limited to them. Further, the light guiding structures 16 may be provided in a contacting relationship with the aggregation wiring lines 31 or may be provided in a spaced relationship above the aggregation wiring lines 31.

Where a V-formed groove whose sectional face perpendicular to the longitudinal direction is symmetric with respect to a line is provided as a light guiding structure 16 on the transparent substrate 1, the numerical aperture of the light incidence face of the dye-sensitized photoelectric conversion device array 30 increases by 5%. However, the form and the disposition of the light guiding structures 16 are not limited to this, and can be suitably selected and applied from the embodiments described above.

### Fabrication Method of the Dye-Sensitized Photoelectric Conversion Device Array

Now, a fabrication method of the dye-sensitized photoelectric conversion device array 30 is described.

First, at least two or more dye-sensitized photoelectric conversion devices 10 are produced in accordance with the fabrication method of the dye-sensitized photoelectric conversion device 10 described above.

Then, the plural produced dye-sensitized photoelectric conversion devices 10 are disposed so that they can be connected to each other through an aggregation wiring line 31.

Then, the collecting wiring lines 8 of the dye-sensitized photoelectric conversion devices 10 are connected to each other through the aggregation wiring lines 31 so that the collecting wiring lines 8 are integrated on the aggregation wiring lines 31. As the connection form, parallel connection, series connection or a form in which the connection forms are combined may be applied.

Then, a transparent substrate 1 is provided on a face of the aggregation wiring line 31 on the light incidence side.

Then, light guiding structures 16 are formed on the transparent substrate 1 such that the light guide path of light to be inputted to the transparent substrate 1 at an upper portion of the aggregation wiring line 31 can avoid optical path blocking by the aggregation wiring lines 31 and can reach the porous electrodes 3.

Also it is possible to directly provide the light guiding structures 16 on or above the aggregation wiring line 31 without the intervention of the transparent substrate 1.

Then, a load is connected to the aggregation wiring lines 31 through wiring lines as occasion demands.

The dye-sensitized photoelectric conversion device array 30 is completed thereby.

### Operation of the Dye-Sensitized Photoelectric Conversion Device Array

Now, operation of the dye-sensitized photoelectric conversion device array 30 is described.

Light incident from the light incidence side face of the dye-sensitized photoelectric conversion devices 10 which configures the dye-sensitized photoelectric conversion device array 30 passes the transparent substrate 1 on which the light guiding structures 15 are formed and then reaches the porous electrodes 3.

Further, part of the light incident to the aggregation wiring lines 31 passes the light guiding structures 16 provided on the transparent substrate 1 and then is introduced to the porous electrodes 3.

Operation other than operation described above is similar to that of the dye-sensitized photoelectric conversion device 10 according to the first embodiment, and power is collected from the dye-sensitized photoelectric conversion devices 10 by the aggregation wiring lines 31 and electrons are extracted to the outside.

As described above, with the dye-sensitized photoelectric conversion device array 30 according to the seventh embodiment, the light guiding structures 16 are provided on the aggregation wiring lines 31 which connect the plural dye-sensitized photoelectric conversion devices 10 which configure the dye-sensitized photoelectric conversion device array 30 to each other. Therefore, the light guide path of light which does not originally contribute to power generation and is incident to the aggregation wiring lines 31 is changed by the light guiding structures 16 so that the incidence light can reach the porous electrodes 3. Further, in the case where the dye-sensitized photoelectric conversion device array 30 is configured by increasing the area of the dye-sensitized photoelectric conversion devices 10 by tiling or the like, the numerical aperture of the dye-sensitized photoelectric conversion device array 30 on the light incidence face can be increased and also the photoelectric conversion efficiency of the dye-sensitized photoelectric conversion device array 30 can be increased.

While the embodiments and the working examples of the disclosed technology are described particularly, the disclosed technology is not limited to the embodiments and working examples described above and various modifications can be made based on the technical idea of the technique.

For example, the values, structures, configurations, shapes, materials and so forth described in connection with the embodiments and the working examples above are mere examples to the end, and values, configurations, shapes, materials and so forth different from those described hereinabove may be used as occasion demands.

The present technology contains subject matter related to that disclosed in Japanese Priority Patent Application JP 2011-068511 filed in the Japan Patent Office on Mar. 25, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A photoelectric conversion device, comprising:
a porous electrode and a counter electrode provided on a substrate;
an electrolyte layer provided between said porous electrode and said counter electrode;
a collecting wiring line provided on a face of said substrate on which said porous electrode is provided; and
a light guiding structure provided on the light incidence side of said substrate.

2. The photoelectric conversion device according to claim 1, wherein said light guiding structure is provided so as to avoid blocking of a light guide path of the incidence light by said collecting wiring line so that the incidence light can be guided into said porous electrode.

3. The photoelectric conversion device according to claim 2, wherein said light guiding structure is a convex prism having a post shape.

4. The photoelectric conversion device according to claim 3, wherein the bottom face of said light guiding structure has a shape symmetrical with respect to a line.

5. The photoelectric conversion device according to claim 4, wherein said collecting wiring line is a post body having a rectangular bottom face and has a collecting wiring line protective layer provided thereon for protecting said collecting wiring line from electrolytic solution in said electrolyte layer.

6. The photoelectric conversion device according to claim 5, wherein said substrate is a transparent substrate and said light guiding structure is provided on the light incidence side face of said transparent substrate.

7. The photoelectric conversion device according to claim 6, further comprising
a transparent electrode provided between said substrate and said porous electrode.

8. The photoelectric conversion device according to claim 7, further comprising
a light anti-reflection layer provided on the surface of said light guiding structure.

9. The photoelectric conversion device according to claim 8, wherein said light anti-reflection layer is configured by forming a multilayer film or a nano-size structure body on the surface of said light guiding structure.

10. The photoelectric conversion device according to claim 2, wherein said light guiding structure is a liquid lens.

11. The photoelectric conversion device according to claim 2, wherein said light guiding structure has a convex face or a concave face formed on the light incidence side face of said substrate.

12. The photoelectric conversion device according to claim 2, wherein said light guiding structure is a groove provided on the light incidence side face of said substrate.

13. The photoelectric conversion device according to claim 12, wherein said groove has a V-shaped cross section perpendicular to a longitudinal direction thereof and having a shape symmetrical with respect to a line.

14. The photoelectric conversion device according to claim 7, wherein said photoelectric conversion device is a die-sensitized solar cell.

15. A photoelectric conversion device array, comprising:
a plurality of photoelectric conversion devices connected at collecting wiring lines thereof to each other by a tiling wiring line so as to be integrated;
at least one of said photoelectric conversion devices including a porous electrode and a counter electrode provided on a substrate and an electrolyte layer provided between said porous electrode and said counter electrode;
a collecting wiring line provided on a face of said substrate on which said porous electrode is provided;
a light guiding structure provided on the light incidence side of said substrate; and
a light guiding structure provided on the light incidence side of said tiling wiring line.

16. The photoelectric conversion device array according to claim 15, wherein said light guiding structure has a V-shaped cross section perpendicular to a longitudinal direction thereof.

17. The photoelectric conversion device array according to claim 16, wherein said photoelectric conversion device is a dye-sensitized solar battery.

18. A fabrication method for a photoelectric conversion device, comprising:
providing a light guiding structure on a face of a substrate on the light incidence side;
forming a collecting wiring line on a face opposite to the light incidence side face of said substrate and further forming a porous electrode in lamination on the collecting wiring line; and
forming a structure in which an electrolyte layer is filled between the porous electrode and a counter electrode.

19. The fabrication method for a photoelectric conversion device according to claim 18, wherein the light guiding structure is formed by a flow method or a nano-imprint method by transparent photo-setting resin dispensing.

20. An electronic apparatus, comprising:
at least one photoelectric conversion device including a porous electrode and a counter electrode provided on a substrate and an electrolyte layer provided between said porous electrode and said counter electrode;
a collecting wiring line provided on a face of said substrate on which said porous electrode is provided; and
a light guiding structure provided on the light incidence side of said substrate.
